(19) United States
(12) Patent Application Publication
(10) Pub. No.: US 2007/0262976 A1
(43) Pub. Date: Nov. 15, 2007

(54) Level Shifter Circuit, Driving Circuit, and Display Device

(76) Inventors: Eiji Matsuda, Chuo-cho Matsusaka-shi Mie (JP); Makoto Yokoyama, Maenoheta-cho Matsusaka-shi Mie (JP); Yuhichirou Murakami, Chuo-cho Matsusaka-shi Mie (JP)

Correspondence Address: HARNESS, DICKEY & PIERCE, P.L.C., P.O. BOX 8910, RESTON, VA, 20195, US

(21) Appl. No.: 11/665,207

(22) PCT Filed: Sep. 16, 2005
(86) PCT No.: PCT/JP05/17141

§ 371 Date: Apr. 12, 2007

(30) Foreign Application Priority Data
Oct. 14, 2004 (JP) 2004-300586

(51) Int. Cl. G09G 5/00; H03L 5/00

(52) U.S. Cl. 345/208; 327/333

(57) ABSTRACT

In one embodiment, in accordance with a timing at which each of output signals of a source shift register is inputted, a level shifter control circuit generates a control signal for controlling a level shift operation of a level shifter. An input interval between the output signals of the source shift register is shorter than an active period of a clock signal. In case of stopping the level shift operation, the level shifter keeps an output signal at a state before stoppage of the level shift operation. As a result, it is possible to reduce power consumption of the level shifter circuit.

### TECHNICAL FIELD

The present invention relates to (i) a level shifter circuit favorably used in a low voltage interface, (ii) a driving circuit having the level shifter circuit, and (iii) a display device including them.

### BACKGROUND ART

Recently, a liquid crystal display device has been widely used as a display device of a compact portable terminal or a mobile phone. In order to enrich the function as a portable device, these devices are greatly required to realize lower power consumption. Thus, a driving circuit for driving the liquid crystal display device is required to have lower power consumption.

In a scanning signal line driving circuit for driving scanning signal lines of the liquid crystal display device, a level shifter circuit is widely used to boost a voltage of a clock signal to a power source voltage of the scanning signal line driving circuit in case where the voltage of the clock signal used in the driving is lower than the power source voltage. Recently, a low temperature polysilicon driver monolithic panel obtained by providing pixels and the driving circuit on a glass substrate at once has been developed.

However, the performance (threshold voltage value Vth, electron mobility μ) of a transistor made of low temperature polysilicon is lower than the performance of a circuit formed on the silicon substrate, that is, lower than the performance of a circuit generally referred to as “IC”. Particularly, the threshold voltage value Vth becomes high.

In case of manufacturing the level shifter by using such a transistor, the following arrangement was conventionally adopted. FIG. 38 is a circuit diagram illustrating a conventional level shifter for boosting two kinds of clock signals whose voltages are lower than a driving voltage so as to attain the driving voltage. FIG. 39 is a timing chart thereof.

FIG. 39 illustrates clock signals CKa and CKb serving as the aforementioned two kinds of clock signals. The clock signals CKa and CKb are in an active period when they are in high level periods and in a non-active period when they are in low level periods, and they have such phases that their high level periods do not overlap each other.

Further, Vdd0 indicates a potential difference between a high level voltage of the clock signal which voltage is lower than the driving voltage and a low level voltage of the clock signal. Vdd1 indicates a potential difference between a high level voltage of a signal OUTa obtained by boosting the voltage of the clock signal CKa which is lower than the driving voltage to the driving voltage and a low level voltage of the output signal OUTa, and also indicates a potential difference a potential difference between a high level voltage of a signal OUTb obtained by boosting the voltage of the clock signal CKb which is lower than the driving voltage to the driving voltage and a low level voltage of the output signal OUTb.

The level shifter circuit of FIG. 38 includes: a first level shifter LSa for level-shifting the clock signal CKa; and a second level shifter LSb for level-shifting the clock signal CKb. Each of the first level shifter LSa and the second level shifter LSb includes an offsetter section 151 and a level shift section 152.

The offsetter section 151 of each of the first level shifter LSa and the second level shifter LSb illustrated in FIG. 38 includes: a constant current source transistor P1 constituted of a P-channel MOS transistor; and an N-channel MOS transistor N1 (hereinafter, referred to as “transistor N1”).

A source of the constant current source transistor P1 is connected to a driving power source Vdd, and a gate of the constant current source transistor P1 is connected to a power source Vss (low level of the clock signal CKa/CKb). A drain of the constant current source transistor P1 is connected to a drain and a gate of the transistor N1 and is connected to a gate of an N-channel MOS transistor N2 of the level shifter section 152. A source of the transistor N1 is connected to a power source Vss.

The level shifter section 152 of each of the first level shifter LSa and the second level shifter LSb illustrated in FIG. 38 includes: a constant current source transistor P2 constituted of a P-channel MOS transistor; an N-channel MOS transistor N2 (hereinafter, referred to as “transistor N2”); and inverters I1 and I2.

A gate of the constant current source transistor P2 is connected to a power source Vss, and a drain of the constant current source transistor P2 is connected to a drain of the transistor N2 and an input terminal of the inverter I1, and a source of the constant current source transistor P2 is connected to a driving power source Vdd.

Out of the two kinds of clock signals CKa and CKb whose voltages are lower than a voltage of the driving power source Vdd (hereinafter, referred to as “driving voltage Vdd”), the clock signal CKa is inputted to a first level shifter LSa and the clock signal CKb is inputted to a second level shifter LSb.

An output terminal of the inverter I1 is connected to an input terminal of the inverter I2, and the output signal OUTa in the first level shifter LSa and the output signal OUTb in the second level shifter LSb are respectively outputted via output terminals of the inverters I2.

Next, an operation of the level shifter circuit is described as follows. Each offsetter section 151 causes each of the first level shifter LSa and the second level shifter LSb to apply to the gate of each transistor N2 an intermediate voltage between the driving voltage Vdd and a voltage of the power source Vss (hereinafter, referred to as “power source voltage Vss”) as a level shift operation voltage. This voltage is referred to also as “offset voltage”. The offset voltage is equal to or slightly higher than the threshold voltage value Vth of the transistor N1 under a normal condition.

In the level shift section 152 of each of the first level shifter LSa and the second level shifter LSb, a constant current ia flowing through the constant current source transistor P2 flows toward a junction between the drain of the constant current source transistor P2 and the input terminal of the inverter I1, and a current flowing in this direction is regarded as “positive”.

In each of the first level shifter LSa and the second level shifter LSb, a current ib flowing through the transistor N2 flows toward an input terminal receiving each of the clock signals CKa and CKb, and a current flowing in this direction is regarded as “positive”. A current flowing from a junction between the drain of the constant current source transistor P2 and the input terminal of the inverter I1 into the inverter I1 is referred to as a “current ic”, and a current flowing in this direction is regarded as “positive”.

The offset voltage applied by the offsetter section 151 is applied to the gate of the transistor N2 exhibiting substantially the same performance as the transistor N1, so that a voltage equal to or slightly higher than the threshold voltage value Vth is applied to the gate of the transistor N2. It is possible to control the current flowing through the transistor N2 according to slight variation of a voltage of the clock signal CKa or CKb inputted to the source of the transistor N2.

In case where the voltage of the clock signal CKa or CKb is a low level, a potential difference between voltages respectively applied to the gate and the source of the transistor N2 becomes equal to or slightly higher than the threshold voltage value Vth of the transistor N2, so that the transistor N2 becomes conductive. Under a conductive condition of the transistor N2, the constant current ia flows toward the terminal via which the clock signal CKa or CKb is inputted to the source of the transistor N2 (this constant current is referred to as “through current”).

Further, the current ic positively flowing from the junction between the drain of the constant current source transistor P2 and the input terminal of the inverter I1 into the inverter I1 becomes a pull-in current flowing toward the terminal via which the clock signal CKa or CKb is inputted to the source of the transistor N2, so that this current is regarded as “negative”.

Thus, electric charge with which the gate of the MOS transistor in the inverter I1 has been charged is discharged, so that its potential drops. When a logical inversion voltage of the inverter I1 causes the voltage to drop, a voltage equal to the driving voltage Vdd is outputted to the input terminal of the inverter I2. As a result, a voltage of the output signal OUTa or OUTb of the inverter I2 becomes equal to the power source voltage Vss (low level of the clock signal CKa or CKb).

Next, in case where a voltage of the clock signal CKa or CKb is a high level, the potential difference between voltages respectively applied to the gate and the source of the transistor N2 is lower than the threshold voltage value Vth of the transistor N2, so that no current ib or substantially no current ib flows through the transistor N2.

Thus, most of the constant current ia flowing to the junction between the drain of the constant current source transistor P2 and the input terminal of the inverter I1 flows into the input terminal of the inverter I1, so that the current ic becomes a positive current. As a result, the gate of the MOS transistor in the inverter I1 is charged with positive electric charge, so that a voltage of the gate of the MOS transistor is boosted.

If the voltage of the gate of the MOS transistor exceeds the logical inversion voltage of the inverter I1, the power source voltage Vss is outputted to the input terminal of the inverter I2, so that the inverter I2 outputs the driving voltage Vdd.

In this manner, a high level of the clock signal CKa or CKb lower than the driving voltage Vdd is boosted to the driving voltage Vdd, and the boosted voltage is outputted as the output voltage OUTa or OUTb.

With use of the clock signal whose voltage has been boosted, a shift register described in, for example, Japanese Unexamined Patent Publication No. 135093/2001 (Tokukai 2001-135093) (Publication date: May 18, 2001) is operated, thereby driving a scanning signal line driving circuit of a liquid crystal display device.

However, in case of arranging the shift register described in Tokukai 2001-135093 with use of the level shifter of FIG. 38, a plurality of level shifters constituting the level shifter circuit, such as the first level shifter LSa and the second level shifter LSb, operate while respectively flowing currents to transistors such as the constant current source transistor P1 and the transistor N1 of the offsetter section 151 and the constant current source transistor P2 and the transistor N2 of the level shift section 152 all the time.

In this case, even in a period which requires no clock signal, that is, even in a period in which the clock signal is not active, the plurality of level shifters consume power, so that the level shifter circuit prevents reduction of power consumption. As a result, the liquid crystal display device consumes more power, so that power of buttery or the like of a compact portable terminal or a mobile phone is more consumed. Thus, such a device cannot be used for a long time.

As a technique for solving such a problem, Japanese Unexamined Patent Publication No. 46085/2004 (Tokukai 2004-46085) (Publication date: Feb. 12, 2004) describes a technique in which: in two level shifters for respectively receiving two kinds of clock signals whose high level periods do not overlap each other, when one of the clock signals is in an active period, an operation of a level shifter receiving the other clock signal is stopped so as to reduce power consumption in a specific period of an inactive period of the one clock signal which specific period corresponds to an active period of the other clock signal.

That is, according to the technique of Tokukai 2004-46085, a control transistor and a control wiring are provided on each of two level shifters receiving two kinds of clock signals whose high level periods do not overlap each other, and a through current flowing to an offsetter section and a level shift section of one level shifter is stopped when an output signal of the other level shifter is a high level, so that a level shift operation of the one level shifter is stopped. As a result, it is possible to reduce power consumption caused by the level shift operation in a specific period of a non-active period of the one clock signal which specific period corresponds to an active period of the other clock signal.

However, according to the technique of Tokukai 2004-46085, when one clock signal is in an active period, it is possible to stop an operation of the level shifter receiving the other clock signal, but the level shifter receiving the clock signal which is in the active period remains operating. That is, during a period in which a clock signal inputted to a level shifter is active, the level shifter continues to operate.

In this case, the level shifter receiving the clock signal which is in the active period continues to flow a current to the constant current source transistor P1 and the transistor N1 of the offsetter section 151 and the constant current source transistor P2 and the transistor N2 of the level shift section 152 all the time.

Thus, during a period in which the clock signal is in the active period, a level shifter receiving the clock signal consumes power, so that this accordingly prevents reduction of power consumption. As a result, the liquid crystal display device or the like including the aforementioned level shifter circuit more greatly consumes power. Further, in a compact portable terminal or a mobile phone for example, power of a buttery or the like is greatly consumed, so that such a device cannot be used for a long time.

Further, the technique of Tokukai 2004-46085 is bade on such an arrangement that two kinds of clock signals whose high level periods do not overlap each other are respectively inputted to two level shifters. However, it may be inappropriate to use the two kinds of clock signals as a signal for determining a timing at which an operation of the level shifter is stopped.

### DISCLOSURE OF INVENTION

The present invention was made in view of the foregoing conventional problems, and an object of the present invention is to provide (i) a level shifter circuit which can reduce power consumption thereof, (ii) a driving circuit having the level shifter circuit, and (iii) a display device including them.

In order to solve the foregoing problems, a level shifter circuit of the present invention includes a level shifter which carries out a level shift operation in which a high level of an inputted clock signal is converted into one of a high level and a low level of a predetermined power source voltage and a low level of the clock signal is converted into the other of the high level and the low level of the power source voltage and which outputs an output signal obtained by carrying out the level shift operation, said level shifter circuit being characterized by comprising: level shifter control means for stopping a level shift operation, during a specific period after carrying out a level shift operation, corresponding to an operation for switching the clock signal from a non-active state to an active state, and until the level shifter carries out a level shift operation, corresponding to an operation for switching the clock signal from the active state to the non-active state; and output control means for allowing a level of the output signal in stopping the level shift operation to be kept at a level before stoppage of the level shift operation. Note that, the active period of the clock signal may be a high level period or may be a low level period.

According to the arrangement, the level shifter control circuit stops a level shift operation during a specific period after carrying out a level shift operation, corresponding to an operation for switching the clock signal from a non-active state to an active state, and until the level shifter carries out a level shift operation, corresponding to an operation for switching the clock signal from the active state to the non-active state. Further, the output control means allows a level of the output signal in stopping the level shift operation to be kept at a level before stoppage of the level shift operation, that is, at a level of an output signal corresponding to the active of the clock signal.

As a result, it is possible to stop the level shift operation during a period in which the output signal of the level shifter is active, so that it is possible to reduce power consumption of the level shifter circuit. Further, the output signal of the level shifter can be kept at a state before stoppage of the level shift operation also during a period in which the level shift operation is stopped, so that it is possible to appropriately and stably drive a circuit connected to the stage following to the level shifter.

Further, a level shifter circuit of the present invention includes level shifters each of which carries out a level shift operation in which a high level of each of clock signals having either phases whose high level periods do not overlap each other or phases whose low level periods do not overlap each other is converted into one of a high level and a low level of a predetermined power source voltage and a low level of the clock signal is converted into the other of the high level and the low level of the power source voltage and each of which level shifters outputs an output signal obtained by carrying out the level shift operation, said level shifters respectively corresponding to the clock signals, said level shifter circuit comprising: active period detection means for detecting whether the clock signal inputted to each of the level shifters is in an active period or in a non-active period; level shifter control means for controlling a level shifter receiving the clock signal which is in the active period so as to stop a level shift operation, during a specific period after carrying out a level shift operation, corresponding to an operation for switching the clock signal from a non-active state to an active state, and until the level shifter carries out a level shift operation, corresponding to an operation for switching the clock signal from the active state to the non-active state; and output control means for allowing a level of the output signal in stopping the level shift operation to be kept at a level before stoppage of the level shift operation. Note that, the active period of the clock signal may be a high level period or may be a low level period.

According to the arrangement, the level shifter control means controls a level shifter receiving the clock signal which is in the active period so as to stop a level shift operation, during a specific period after carrying out a level shift operation, corresponding to an operation for switching the clock signal from a non-active state to an active state, and until the level shifter carries out a level shift operation, corresponding to an operation for switching the clock signal from the active state to the non-active state. Further, the output control means allows a level of the output signal in stopping the level shift operation to be kept at a level before stoppage of the level shift operation, that is, at a level of an output signal corresponding to the active of the clock signal.

As a result, it is possible to stop the level shift operation during a period in which the output signal of the level shifter is active, so that it is possible to reduce power consumption of the level shifter circuit. Further, the output signal of the level shifter can be kept at a state before stoppage of the level shift operation also during a period in which the level shift operation is stopped, so that it is possible to appropriately and stably drive a circuit connected to the stage following to the level shifter.

A driving circuit of the present invention is provided on a display device having a plurality of scanning signal lines, a plurality of data signal lines, and a plurality of pixels, said driving circuit serving as a scanning signal line driving circuit for outputting a scanning signal to each of the scanning signal lines in synchronization with a first clock signal having a predetermined cycle or serving as a data signal line driving circuit for extracting, from a video signal indicative of a display state of each pixel which is inputted in synchronization with a second clock signal having a predetermined cycle, a data signal applied to each pixel connected to the scanning signal line receiving the scanning signal, so as to output the data signal to each of the data signal lines, said driving circuit comprising any one of the aforementioned the level shifter circuits, wherein the level shifter circuit level-shifts the first clock signal or the second clock signal.

According to the arrangement, it is possible to reduce power consumption of the level shift circuit for level-shifting the first clock signal or the second clock signal, so that it is possible to reduce power consumption of the driving circuit.

A display device of the present invention includes any one of the aforementioned driving circuits. As a result, it is possible to realize a display device which less consumes power.

### BRIEF DESCRIPTION OF DRAWINGS

FIG. 1 is a block diagram illustrating an arrangement of a level shifter circuit according to one embodiment of the present invention.

FIG. 2 is a block diagram illustrating an arrangement of a display device according to one embodiment of the present invention.

FIG. 3 is a block diagram illustrating an arrangement of a level shifter group which includes the level shifter circuit according to one embodiment of the present invention.

FIG. 4 is a block diagram illustrating an arrangement of a pixel of the display device according to one embodiment of the present invention.

FIG. 5 is a timing chart of the level shifter circuit according to one embodiment of the present invention.

FIG. 6 is a block diagram illustrating an arrangement of a source shift register provided on the display device according to one embodiment of the present invention.

FIG. 7 is a block diagram illustrating an arrangement of a level shifter control circuit provided on the level shifter circuit according to one embodiment of the present invention.

FIG. 8 is a circuit diagram illustrating an arrangement of a set/reset flip flop provided on the level shifter circuit according to one embodiment of the present invention.

FIG. 9 is a circuit diagram illustrating an arrangement of a level shifter provided on the level shifter circuit according to one embodiment of the present invention.

FIG. 10 is a circuit diagram illustrating another arrangement of the level shifter provided on the level shifter circuit according to one embodiment of the present invention.

FIG. 11 is a timing chart indicative of a case where the level shifter of FIG. 10 is provided on the level shifter circuit according to one embodiment of the present invention.

FIG. 12 is a block diagram illustrating an arrangement of a level shifter circuit according to another embodiment of the present invention.

FIG. 13 is a timing chart of a level shifter according to another embodiment of the present invention.

FIG. 14 is a block diagram illustrating an example of an arrangement of a level shifter control circuit provided on the level shifter circuit according to another embodiment of the present invention.

FIG. 15 is a block diagram illustrating another example of the arrangement of the level shifter control circuit provided on the level shifter circuit according to another embodiment of the present invention.

FIG. 16 is a timing chart indicative of a case where the level shifter of FIG. 15 is provided in the level shifter circuit according to another embodiment of the present invention.

FIG. 17 is a block diagram illustrating still another example of the arrangement of the level shifter control circuit provided on the level shifter circuit according to another embodiment of the present invention.

FIG. 18 is a timing chart indicative of a case where the level shifter of FIG. 17 is provided on the level shifter according to another embodiment of the present invention.

FIG. 19 is a block diagram illustrating further another example of the arrangement of the level shifter control circuit provided on the level shifter circuit according to another embodiment of the present invention.

FIG. 20 is a timing chart indicative of a case where the level shifter of FIG. 19 is provided on the level shifter circuit according to another embodiment of the present invention.

FIG. 21 is a block diagram illustrating an arrangement of a level shifter circuit according to still another embodiment of the present invention.

FIG. 22 is a block diagram illustrating an example of an arrangement of a level shifter provided on the level shifter circuit according to still another embodiment of the present invention.

FIG. 23 is a timing chart of the level shifter circuit according to still another embodiment of the present invention.

FIG. 24 is a block diagram illustrating another example of the arrangement of the level shifter control circuit provided on the level shifter circuit according to still another embodiment of the present invention.

FIG. 25 is a timing chart indicative of a case where the level shifter of FIG. 24 is provided on the level shifter circuit according to still another embodiment of the present invention.

FIG. 26 is a block diagram illustrating still another example of the arrangement of the level shifter control circuit provided on the level shifter according to still another embodiment of the present invention.

FIG. 27 is a timing chart indicative of a case where the level shifter of FIG. 26 is provided on the level shifter circuit according to still another embodiment of the present invention.

FIG. 28 is a block diagram illustrating still another example of the arrangement of the level shifter control circuit provided on the level shifter circuit according to still another embodiment of the present invention.

FIG. 29 is a timing chart indicative of a case where the level shifter of FIG. 28 is provided on the level shifter circuit according to still another embodiment of the present invention.

FIG. 30 is a block diagram illustrating an arrangement of a display device according to still another embodiment of the present invention.

FIG. 31 is a block diagram illustrating an arrangement of a two-way source shift register provided on the display device according to still another embodiment of the present invention.

FIG. 32 is a block diagram illustrating an arrangement of a level shifter circuit according to further another embodiment of the present invention.

FIG. 33 is a block diagram illustrating an arrangement of a display device according to still further another embodiment of the present invention.

FIG. 34 is a block diagram illustrating an SSD (source shared driving) circuit provided on the display device according to still further another embodiment of the present invention.

FIG. 35 is a timing chart of the SSD circuit provided on the display device according to still further another embodiment of the present invention.

FIG. 36 is a block diagram illustrating an arrangement of a level shifter control circuit provided on the level shifter circuit according to still further another embodiment of the present invention.

FIG. 37 is a timing chart of the level shifter circuit according to still further another embodiment of the present invention.

FIG. 38 is a circuit diagram illustrating an arrangement of a conventional level shifter circuit.

FIG. 39 is a timing chart of the level shifter circuit of FIG. 38.

### BEST MODE FOR CARRYING OUT THE INVENTION

### Embodiment 1

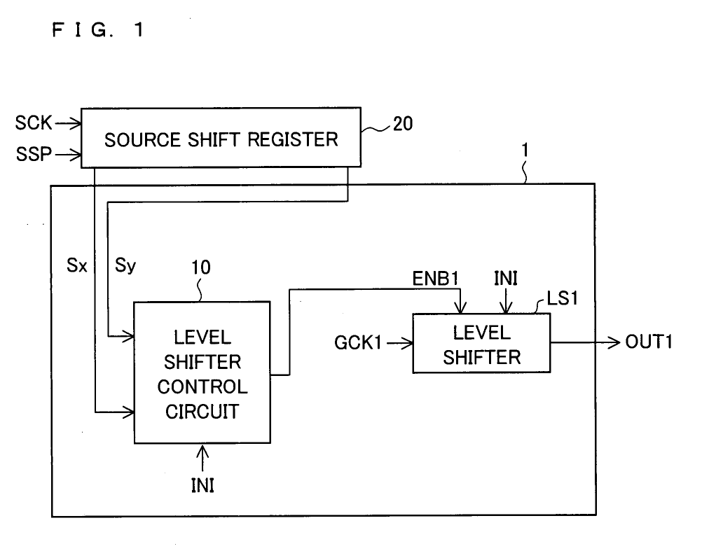

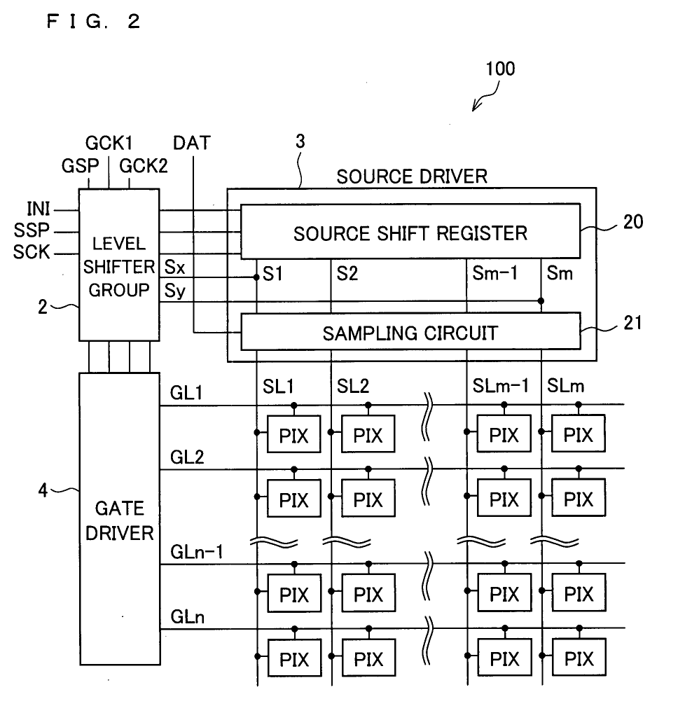

The following description explains a level shifter circuit according to one embodiment of the present invention. FIG. 1 is a circuit block diagram schematically illustrating an arrangement of a level shifter circuit 1 according to the present embodiment. Note that, the level shifter circuit 1 is provided on a matrix type liquid crystal display device such as a matrix type liquid crystal display device (display device) 100 of FIG. 2, and functions as a part of a gate driver for driving a scanning signal line (scanning signal line driving circuit, driving circuit).

(Display Device 100)

As illustrated in FIG. 2, the display device 100 includes: a large number of pixels PIX disposed in a matrix manner; a level shifter group 2; and a source driver (data signal line driving circuit) 3 and a gate driver 4 each of which drives the pixels PIX. Note that, the pixels PIX and peripheral circuits such as the source driver 3 and the gate driver 4 are monolithically formed on the same substrate into a monolithic circuit so as to reduce trouble at the time of production and a wiring capacitance.

The level shifter group (level shifter circuit group) 2 is required for the following reason. Signals SCK, SSP, INI, GSP, GCK1, GCK2, and INI inputted to the display device 100 are generated by an external IC (integrated circuit) of the display device 100, so that these input signals are required to have the same voltage as an operation voltage of the IC.

The operation voltage required in the IC becomes lower year by year, and such low voltage fails to cause the source driver 3 and the gate driver 4 of the display device 100 to operate. Thus, it is necessary to provide the level shifter group 2 in order to boost a voltage of each input signal (in order to carry out level shift) so that the voltage is equal to the operation voltage of the source driver 3 or the gate driver 4.

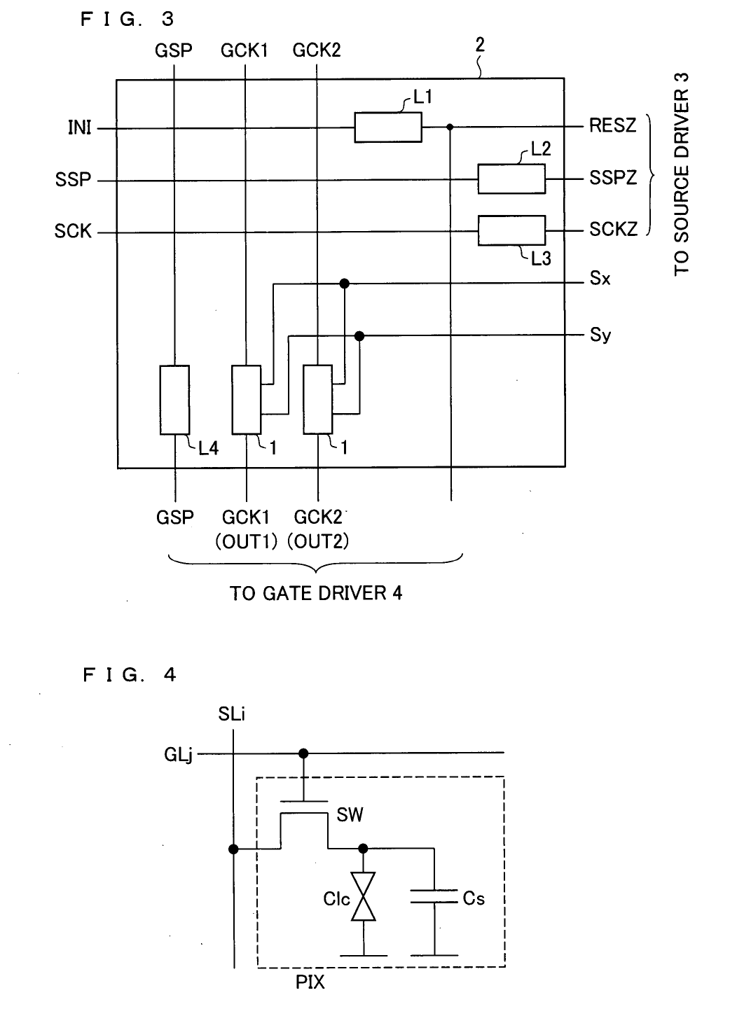

FIG. 3 is a block diagram illustrating an arrangement of the level shifter group 2. In FIG. 3, level shifters L1, L2, L3, and L4 are provided so as to respectively correspond to signals whose levels are to be shifted. Note that, the level shifter circuit 1 of the present embodiment shifts levels of the clock signals GCK1 and GCK2 respectively. In the present embodiment, the case of shifting the level of the clock signal GCK1 is described as follows.

Note that, in the present embodiment, the level shifter circuit 1 is provided outside the gate driver 4 (provided in the level shifter group 2), but the arrangement is not limited to this. The level shifter circuit 1 may be provided in the gate driver 4. Further, the level shifter circuit 1 will be detailed later.

The source driver 3 includes a source shift register 20 and a sampling circuit 21.

Each pixel PIX is disposed in each of areas sectioned in a matrix manner by n-number of scanning signal lines GL1 to GLn and m-number of data signal lines SL1 to SLm which intersect with each other. Further, the source driver 3 and the gate driver 4 sequentially apply image signals DAT, inputted from the outside of the display device 100 via the scanning signal lines GL1 to GLn and the data signal lines SL1 to SLm, to the pixels PIX, thereby displaying an image.

FIG. 4 illustrates each pixel PIX disposed in an each of areas sectioned by a j-th scanning signal line GLj and an i-th data signal line SLj.

As illustrated in FIG. 4, the pixel PIX includes a switching transistor (field effect transistor) SW and a pixel capacitor Cp. The pixel capacitor Cp is provided with a liquid crystal capacitor CLc and, if necessary, with an auxiliary capacitor Cs.

A gate of the switching transistor SW is connected to the scanning signal line GL, and a source of the switching transistor SW is connected to the data signal line SL, and a drain of the switching transistor SW is connected to the pixel capacitor Cp (the liquid crystal capacitor CLc and the auxiliary capacitor Cs). Note that, the other electrode of the pixel capacitor Cp is connected to a common electrode line shared by all the pixels PIX.

Thus, when the scanning signal line GL is selected, the switching transistor SW becomes conductive, so that a voltage applied to the data signal line SL is applied to the pixel capacitor Cp. While, during a period in which the switching transistor SW is kept off after a selection period of the scanning signal line GL ends, the voltage at the time of turning off is kept by the pixel capacitor Cp. Here, a transmittance or a reflectance of the liquid crystal is changed depending on a voltage applied to the liquid crystal capacitor CLc. Thus, the scanning signal line GL is selected and a voltage corresponding to the image signal DAT is applied to the data signal line SL, so that it is possible to change a display condition of each pixel PIX in accordance with the image signal DAT.

Here, the image signal DAT for each pixel PIX is transmitted to the source driver 3 in a time sharing manner. Further, the source driver 3 extracts video data for each pixel PIX from the image signal DAT at a timing based on (i) the clock signal SCK whose duty ratio at a predetermined cycle is 50% (50% or less) and (ii) the start pulse SSP. Specifically, the source shift register 20 sequentially shifts the start pulse SSP in synchronization with a timing of the clock signal SCK so as to generate output signals S1 to Sm whose timings are different from each other by half cycle of the clock signal SCK. The sampling circuit 21 samples the video signal DAT at timings indicated by the output signals S1 to Sm so as to output the sampled video signal DAT to the data signal lines SL1 to SLm.

While, in the gate driver 4, the level shifter circuit 1 provided on the level shifter group 2 boosts voltages of the clock signals GCK1 and GCK2 so that each of the voltages is equal to the driving voltage of the gate driver 4.

Further, the gate driver 4 sequentially shifts the start pulse GSP in synchronization with the clock signal GCK so as to output scanning signals whose timings are different from each other to the scanning signal lines GL1 to GLn so that the difference corresponds to each of predetermined intervals. As a result, video signals DAT are sequentially applied to the pixels PIX, thereby displaying an image.

As illustrated in FIG. 1, the level shifter circuit 1 includes the level shifter control circuit 10 and the level shifter LS1.

The level shifter LS1 level-shifts a high level of the inputted clock signal GCK1 to a driving voltage Vdd of a circuit (not shown) connected to a stage following to the level shifter LS1 so as to boost the voltage of the clock signal GCK1, and outputs the resultant as an output signal OUT1. Note that, the high level of the clock signal GCK1 is lower than the driving voltage Vdd of the circuit connected to the following stage. Further, the high level period of the signal GCK1 is an active period in which the circuit connected to the following stage is operated, and the low level of the clock signal GCK1 is a non-active period in which the circuit connected to the stage following to the level shifter LS1 is not operated.

The level shifter control circuit 10 generates a control signal ENB1 for controlling an operation of the level shifter LS1 in accordance with output signals Sx and Sy of the source shift register 20 provided in the source driver 3. Note that, in the level shifter LS1, a level shift operation of the level shifter LS1 is stopped when the control signal ENB1 is in a high level, and the level shift operation of the level shifter LS1 is allowed when the control signal ENB1 is in a low level.

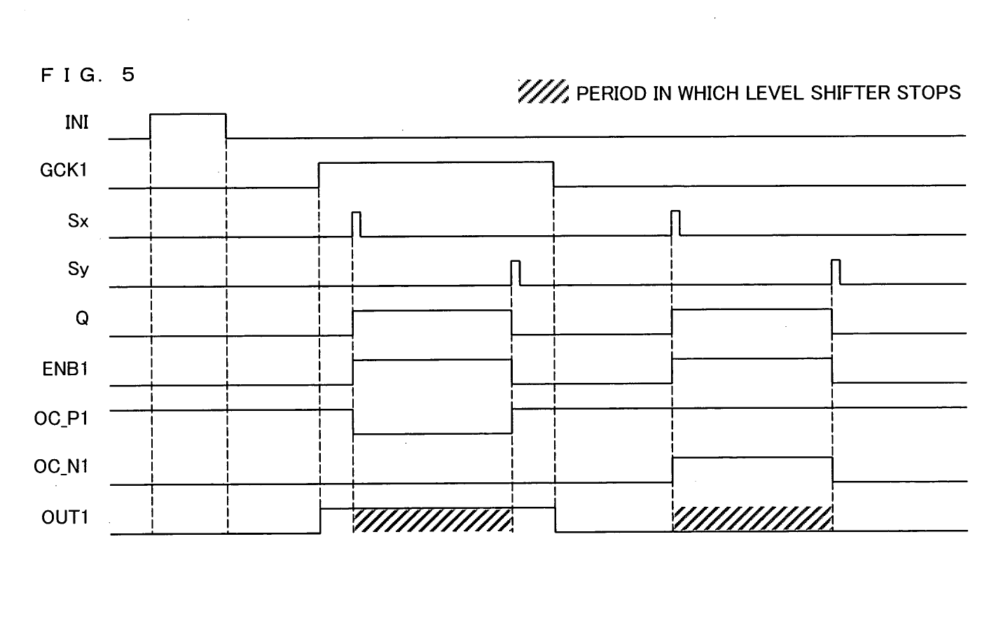

FIG. 5 is a timing chart of the level shifter circuit 1, and each shaded portion of the timing chart indicates a state in which the level shifter LS1 stops its level shift operation. As illustrated in FIG. 5, in the level shifter circuit 1, the level shift operation of the level shifter LS1 is stopped during a period after an output signal Sx of the source shift register 20 becomes a high level until an output signal Sy of the source shift register 20 becomes a high level (during a specific period). Here, during the foregoing period, the level shifter circuit 1 stops the level shift operation even during a period in which the clock signal GCK1 inputted to the level shifter LS1 is a high level (active).

Note that, during a period in which the level shift operation is stopped, the level shifter circuit 1 keeps (stabilizes) the output signal OUT1 of the level shifter LS1 at a state before stoppage of the level shift operation. That is, in case of stopping the level shift operation of the level shifter LS1 during a period in which the clock signal GCK1 inputted to the level shifter LS1 is active, the output signal OUT1 of the level shifter LS1 is kept active. Further, in case of stopping the level shift operation of the level shifter LS1 during a period in which the clock signal GCK1 inputted to the level shifter LS1 is not active, the output signal OUT1 of the level shifter LS1 is kept non-active.

(Source Shift Register 20)

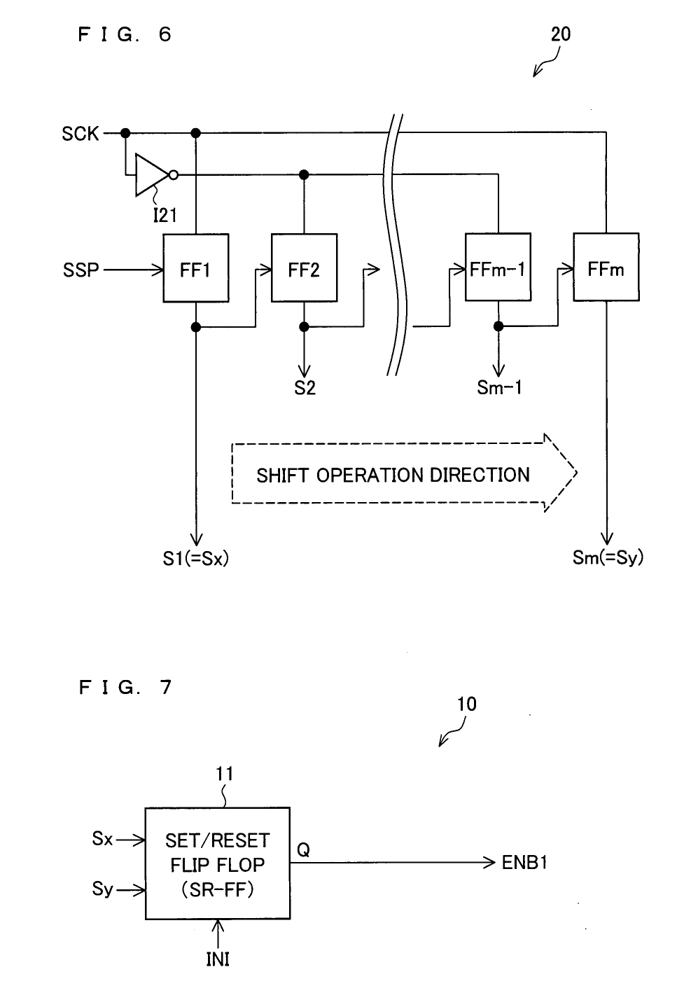

FIG. 6 is a block diagram illustrating an arrangement of the source shift register 20. As illustrated in FIG. 6, the source shift register 20 includes an inverter I21 and a plurality of flip flops FF1, FF2, . . . FFm-1, and FFm.

A standard clock signal SCK is inputted to each of odd-numbered flip flops, and a signal obtained by inverting the standard clock signal SCK with the inverter I21 is inputted to each of even-numbered flip flops. Further, a start pulse signal SSP is inputted to the first flip flop FF1, and output signals are respectively inputted to second and further flip flops so that each flip flop receives an output signal outputted from a pervious flip flop.

As a result, the standard clock signal SCK and the start pulse signal SSP cause the source shift register 20 to start its shift operation, so that output signals S1 to Sm are sequentially outputted from the respective flip flops FF1 to FFm. Further, the output signals S1 to Sm sequentially outputted from the respective flip flops are used to apply voltages to the plurality of data signal lines SL1 to SLm of the display device 100 so that the voltages respectively correspond to the video signals DAT.

Further, out of the output signals, output signals of intended two flip flops are inputted to the level shifter control circuit 10 as the output signals Sx and Sy of the source shift register 20. An output timing of the output signal Sx (timing at which the output signal Sx becomes a high level) is earlier than an output timing of the output signal Sy (timing at which the output signal Sy becomes a high level). That is, in a shift operation direction of the source shift register 20, the output signal Sx is closer to a shift starting side than the output signal Sy, and the output signal Sy is closer to a shift ending side than the output signal Sx.

Note that, as described above, the level shifter circuit 1 stops the level shift operation of the level shifter LS1 during a period after the high level of the output signal Sx of the source shift register 20 is inputted and until the high level of the output signal Sy of the source shift register 20 is inputted. Thus, an interval between Sx and Sy (a period from a time when the output signal Sx becomes a high level to a time when the output signal Sy becomes a high level) is made as long as possible, so that the period in which the level shifter is stopped can be made longer, thereby greatly reducing power consumption. Thus, it is preferable that: an output S1 of the first stage (flip flop FF1) at which the shift operation is started is outputted to the level shifter control circuit 10 as the output signal Sx, and an output Sm of the last stage (flip flop FFm) at which the shift operation is ended is outputted to the level shifter control circuit 10 as the output signal Sy.

(Level Shifter Control Circuit 10)

FIG. 7 is a block diagram illustrating an arrangement of the level shifter control circuit 10. As illustrated in FIG. 7, the level shifter control circuit 10 includes a set/reset flip flop (SR-FF) 11, and the output signal Sx of the source shift register 20 is inputted to a set terminal of the SR-FF 11 as a set signal, and the output signal Sy of the source shift register 20 is inputted to a reset terminal of the SR-FF 11 as a reset signal. Further, an initialization signal INI is inputted to the SR-FF11. An output signal Q of the SR-FF 11 is outputted to the level shifter LS1 as a control signal ENB1 for controlling the level shift operation of the level shifter LS1.

(Set/Reset Flip Flop 11)

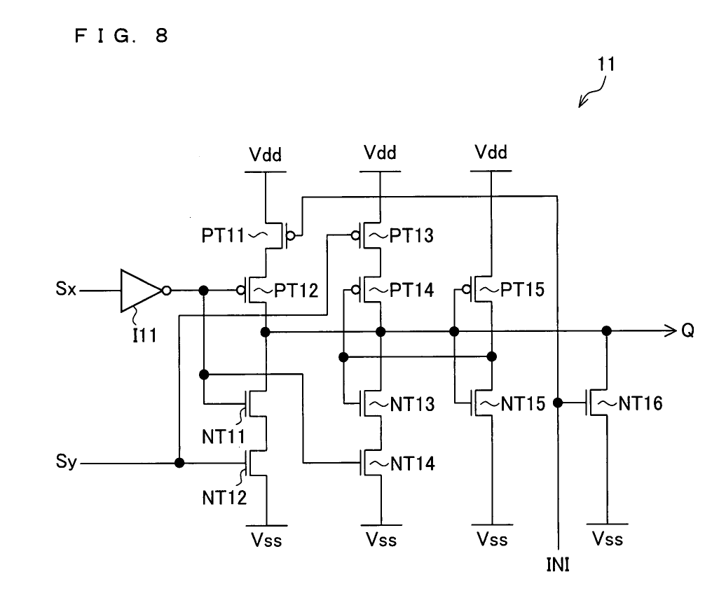

FIG. 8 is a circuit diagram of the SR-FF 11. As illustrated in FIG. 8, the SR-FF11 includes an inverter I11, P-channel MOS transistors PT11 to PT15 (hereinafter, referred to as “transistors PT11 to PT15”), and N-channel MOS transistors NT11 to NT16 (hereinafter, referred to as “transistors NT11 to NT16”).

An input terminal of the inverter I11 is connected to an input terminal receiving the output signal Sx of the source shift register 20. Further, an output terminal of the inverter I11 is connected to a gate of the transistor PT12, a gate of the transistor NT11, and a gate of the transistor NT14. A signal obtained by inverting the output signal Sx is inputted to each of these transistors.

An input terminal receiving the output signal Sy of the source shift register 20 is connected to a gate of the transistor NT12 and a gate of the transistor PT13.

An input terminal receiving the initialization signal INI is connected to a gate of the transistor PT11 and a gate of the transistor NT16.

A source of the transistor PT11 is connected to a power source line receiving the driving voltage Vdd and a drain of the transistor PT11 is connected to a source of the transistor PT12.

A drain of the transistor PT12 is connected to an output terminal from which the output signal Q of the SR-FF 11 is outputted. Note that, in addition to the drain of the transistor PT12, a drain of the transistor NT11, a drain of the transistor PT14, a drain of the transistor NT13, a gate of the transistor PT15, a gate of the transistor NT15, and a drain of the transistor NT16 are connected to the output terminal.

A source of the transistor NT11 is connected to a drain of the transistor NT12. Further, a source of the transistor NT12 is connected to a power source line receiving the power source voltage Vss.

A source of the transistor PT13 is connected to a power source line receiving the driving voltage Vdd and a drain of the transistor PT13 is connected to a source of the transistor PT14.

A gate of the transistor PT14 is connected to a gate of the transistor NT13, a drain of the transistor PT15, and a drain of the transistor NT15.

A source of the transistor NT13 is connected to a drain of the transistor NT14. Further, a source of the transistor NT14 is connected to a power source line receiving the power source voltage Vss.

A source of the transistor PT15 is connected to a power source line of the power source voltage Vss. Also, a source of the transistor NT15 is connected to a power source line receiving the power source voltage Vss. Further, a source of the transistor NT16 is connected to a power source line receiving the power source voltage Vss.

In case where the SR-FF 11 arranged in this manner causes the initialization signal INI to be a high level, the transistor NT16 becomes conductive, so that it is possible to stabilize the output signal Q at a low level. Thereafter, the transistor NT16 is turned off and the transistor PT11 is made conductive by causing the initialization signal INI to be a low level. This results in an operation standby state.

Further, in case where the high level of the output signal Sx of the source shift register 20 is inputted as a set signal in the operation standby state (state in which the initialization signal INI is a low level), the transistor PT12 becomes conductive, and the transistors NT11 and NT14 are turned off, so that it is possible to set the output signal Q at a high level. Note that, the output signal Sy of the source shift register 20 becomes a high level later than the output signal Sx, so that the output signal Sy is a low level at this time.

Further, even when the output signal Sx changes from a high level to a low level, the output signal Sy of the source shift register 20 is a low level, so that the transistor PT13 is conductive. Further, since the immediately preceding output signal Q is a high level, the transistor NT15 is conductive, so that the transistor PT14 is conductive. Thus, the output signal Q is kept at a high level as illustrated in FIG. 5.

Further, when the high level of the output signal Sy of the source shift register 20 is inputted, the transistor PT13 is turned off and the transistor NT12 becomes conductive, so that the output signal Q is reset so as to be a low level.

Thereafter, even when the low level of the output signal Sy of the source shift register 20 is inputted, the output signal Sx of the source shift register 20 is a low level, so that the transistor NT14 is conductive. The immediately preceding output signal Q is a low level, so that the transistor NT13 is conductive. As a result, the output signal Q is kept at a high level as illustrated in FIG. 5.

Thus, the output signal Q of the SR-FF 11 is a high level during a period after the high level of the output signal Sx of the source shift register 20 is inputted and until the high level of the output signal Sy of the source shift register 20 is inputted, so that the control signal ENB1 becomes a high level. That is, the control signal ENB1 becomes a high level regardless of whether the clock signal GCK1 inputted to the level shifter LS1 is in an active period or in a non-active period, so that it is possible to stop the level shift operation of the level shifter LS1. Further, even after stopping the level shift operation, the output signal OUT1 of the level shifter LS1 is kept at a state before stoppage of the level shift operation.

(Level Shifter Ls1)

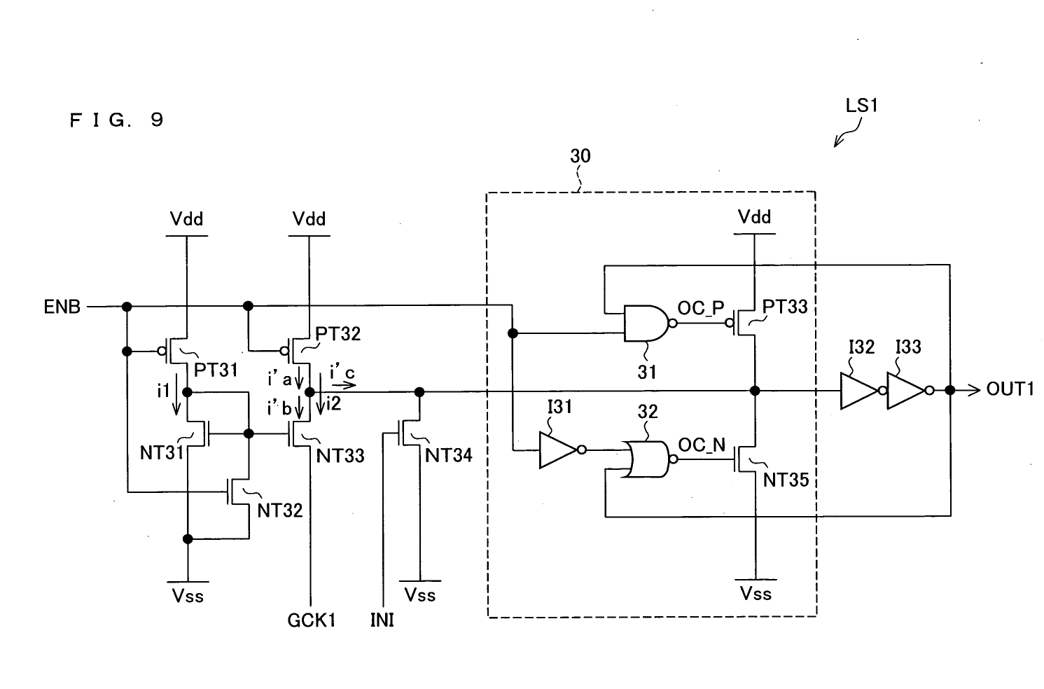

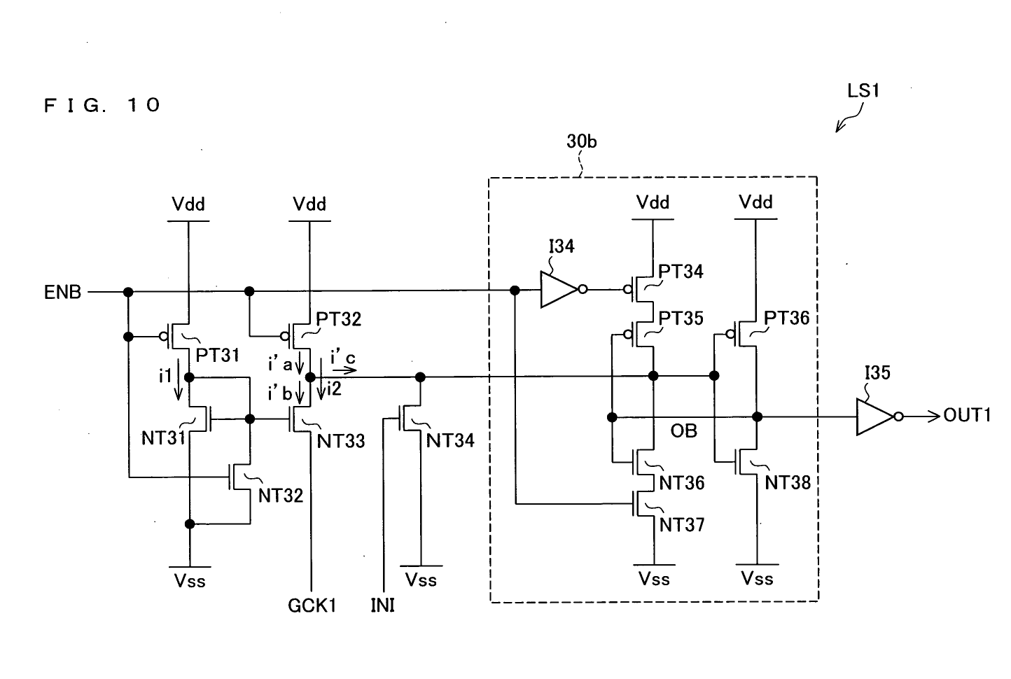

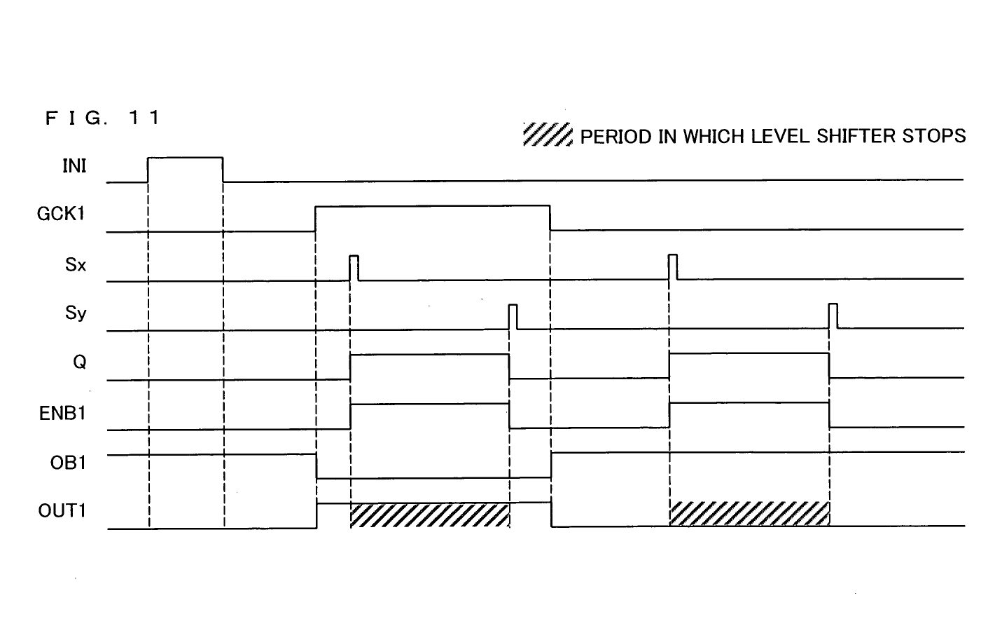

FIG. 9 is a circuit diagram illustrating an arrangement of the level shifter LS1. As illustrated in FIG. 9, the level shifter LS1 includes P-channel MOS transistors PT31 to PT33 (hereinafter, referred to as “transistors PT31 to PT33”), N-channel MOS transistors NT31 to NT35 (hereinafter, referred to as “transistors NT31 to NT35”), inverters I31 to I33, a NAND circuit 31, and a NOR circuit 32. Note that, an output control section 30 is constituted of the transistor PT33, the transistor NT35, the inverter I31, the NAND circuit 31, and the NOR circuit 32.

In the level shifter LS1, the control signal ENB1 from the level shifter control circuit 10 is inputted to a gate of the transistor PT31, a gate of the transistor PT32, a gate of the transistor NT32, one of input terminals of the NAND circuit 31, and an input terminal of the inverter I31.

A source of the transistor PT31 is connected to a power source line receiving the driving voltage Vdd, and a drain of the transistor PT31 is connected to a drain and a gate of the transistor NT31, a drain of the transistor NT32, and a gate of the transistor NT33.

The source of the transistor NT31 is connected to a power source line of the driving voltage Vss and a source of the transistor NT32, and a gate of the transistor NT31 is connected to a drain of the transistor NT31 itself.

A source of the transistor NT32 is connected to a power source line receiving the power source voltage Vss and a drain of the transistor NT32 is connected to gates of the transistors NT31 and NT33.

Note that, the driving voltage Vdd is a high level voltage whose level has been shifted, and the power source voltage Vss is a low level voltage whose level has been shifted. Herein, explanation is given on the assumption that: only boosting of the clock signal GCK1 up to the high level driving voltage Vdd is carried out, and the power source voltage Vss is equal to a low level voltage of the clock signal GCK1.

A source of the transistor PT32 is connected to a power source line receiving the driving voltage Vdd, and a drain of the transistor PT32 is connected to a drain of the transistor NT33 and an input terminal of the inverter I32.

A source of the transistor NT33 is connected to an input terminal receiving the clock signal GCK1, and a gate of the transistor NT33 is connected to a gate of the transistor NT31, and a drain of the transistor NT33 is connected to an input terminal of the inverter I32.

A gate of the transistor NT34 is connected to an input terminal receiving the initialization signal INI, and a source of the transistor NT34 is connected to a power source line receiving the power source voltage Vss, and a drain of the transistor NT34 is connected to an input terminal of the inverter I32.

One of input terminals of the NAND circuit 31 is connected to a control signal line receiving the control signal ENB1, and the other of the input terminals is connected to an output terminal of the inverter I33.

Further, an output terminal of the NAND circuit 31 is connected to a gate of the transistor PT33. As a result, an output signal OC_P of the NAND circuit 31 is inputted to a gate of the transistor PT33.

A source of the transistor PT33 is connected to a power source line of the driving voltage Vdd, and a drain of the transistor PT33 is connected to an input terminal of the inverter I32.

An input terminal of the inverter I31 is connected to a control signal line receiving the control signal ENB1, and an output terminal of the inverter I31 is connected to one of input terminals of the NOR circuit 32.

The other of the input terminals of the NOR circuit 32 is connected to an output terminal of the inverter I33. Further, an output terminal of the NOR circuit 32 is connected to a gate of the transistor NT35, so that an output signal OC_N of the NOR circuit 32 is inputted to a gate of the transistor NT35.

A source of the transistor NT35 is connected to a power source line receiving the driving voltage Vss, and a drain of the transistor NT35 is connected to an input terminal of the inverter I32.

An output terminal of the inverter I32 is connected to an input terminal of the inverter I33. Further, an output terminal of the inverter I33 is connected to a circuit connected to a stage following to the level shifter LS1 so as to output the output signal OUT1 of the level shifter LS1.

Next, an operation of the level shifter LS1 is described as follows.

First, an initialization operation of the level shifter LS1 is described. In an initial state in which the level shifter LS1 is not stable, a high level (driving voltage Vdd) initialization signal INI is inputted to a gate of the transistor (initialization transistor) NT34 in order to stabilize the level shifter LS1.

The initialization signal INI is brought into a high level, so that the transistor NT34 becomes conductive. Thus, when an input voltage of the inverter I32 becomes equal to the power source voltage Vss and the input voltage becomes lower than a logical inversion voltage of the inverter I32, a voltage equal to the driving voltage Vdd is outputted to the input terminal of the inverter I33. As a result, an output voltage of the inverter I33 becomes equal to the power source voltage Vss (low level of the clock signal GCK1), so that the inverter I33 outputs the output signal OUT1 having the power source voltage Vss.

The high level initialization signal INI is inputted until the output signal OUT1 of the level shifter LS1 becomes equal to the power source voltage Vss, and then an initialization signal INI having a low level (power source voltage Vss) is inputted to a gate of the transistor NT34 all the time in a normal state.

Thus, the transistor NT34 is non-conductive in a normal state. In this case, when the control signal ENB1 is a low level, an output signal OC_P of the NAND circuit 31 becomes a high level, so that the transistor PT33 is turned off, and an output signal OC_N of the NOR circuit 32 becomes a low level, so that the transistor NT35 is turned off. As a result, the output control section 30 does not operate. Thus, the level shifter LS1 shifts from the unstable initial state to a stable state, which results in a level shift operation state (active state).

Note that, during a period in which the initialization signal INI is a high level, a low level signal is inputted to the input terminal receiving the clock signal GCK1. This is based on the following reason: when a high level signal is inputted to the input terminal of the clock signal GCK1 during a period in which the initialization signal INI is a high level, the transistor NT33 becomes non-conductive, and a current i′c flows from a junction between (i) a drain of the transistor PT32 and (ii) the input terminal of the inverter I32 into the inverter I32, so that the transistor NT34 may prevent the power source voltage Vss from being applied to a gate of the MOS transistor of the inverter I32.

Next, the level shift operation of the level shifter LS1 is described as follows. In a level shift operation state, the control signal ENB1 is a low level, so that the transistor (constant current source transistor) PT31 becomes conductive and the transistor NT32 is turned off. As a result, the transistor PT31 serves as a constant current source. Thus, an intermediate voltage between the driving voltage Vdd and the power source voltage Vss is outputted to a gate of the transistor NT31 as a level shift operation voltage. This voltage is referred to as “offset voltage”.

In a normal state, the offset voltage is equal to or slightly higher than the threshold voltage Vth of the transistor NT31. Thus, also the transistor NT31 becomes conductive. At this time, a voltage of the control signal ENB1 is a low level, so that the transistor (control transistor) NT32 is non-conductive.

Further, in case where the control signal ENB1 is a low level, the transistor (constant current source transistor) PT32 becomes conductive so as to serve as a constant current source.

A constant current i′a flowing through the transistor PT32 flows toward a junction between (i) a drain of the transistor PT32 and (ii) an input terminal of the inverter I32 (current flowing in this direction is regarded as “positive”). A constant current i′b flowing through the transistor NT33 flows toward an input terminal receiving the clock signal GCK1 (current flowing in this direction is regarded as “positive”). Further, a current flowing from the junction between (i) the drain of the transistor PT32 and (ii) the input terminal of the inverter I32 into the inverter I32 is a constant current i′c, and a current flowing in this direction is regarded as “positive”.

The offset voltage inputted to the gate of the transistor NT31 is inputted also to the gate of the transistor NT33 whose performance is substantially equal to the transistor NT31, so that a voltage equal to or slightly higher than the threshold voltage value Vth of the transistor NT33 is applied to the gate of the transistor NT33.

A voltage equal to the clock signal GCK1 is applied to the source of the transistor NT33, so that it is possible to control a current flowing through the transistor NT33 in accordance with slight variation of the voltage of the clock signal GCK1.

In case where the clock signal GCK1 is a low level, a potential difference between voltages applied to the gate and the source of the transistor NT33 is equal to or slightly higher than the threshold voltage value Vth, so that the transistor NT33 becomes conductive. When the transistor NT33 is conductive, the constant current i′a flows toward the input terminal of the clock signal GCK1 (the constant current is referred to as “through current”).

Further, the current i′c regarded as being positive in flowing from the junction between (i) the drain of the transistor PT32 and (ii) the input terminal of the inverter 132 into the inverter I32 becomes a pull-in current which flows toward the input terminal of the clock signal GCK1, so that the current i′c becomes negative.

Thus, electric charge with which the gate of the MOS transistor provided in the inverter I32 is discharged, so that the potential drops. When the voltage drops due to the logical inversion voltage of the inverter I32, a voltage of the driving voltage Vdd is outputted to the input terminal of the inverter I33. As a result, the output signal OUT1 of the inverter I33 becomes equal to the power source voltage Vss (low level of the clock signal GCK1).

Such level shift operation causes the level shifter LS1 to convert the low level of the clock signal GCK1 into the power source voltage Vss which is a low level of a predetermined power source voltage. That is, the level shift operation during a low level period of the clock signal GCK1, i.e., the level shift operation during a non-active period is as follows. When a through current i1 (see FIG. 9) which is a stationary current flows through a series circuit (offsetter section) constituted of the transistor PT31 and the transistor NT31, and when a through current i2 (see FIG. 9) which is a stationary current flows through a series circuit (level shift section) constituted of the transistor PT32 and the transistor NT33, a voltage is generated in the junction between (i) the drain of the transistor PT32 and (ii) the drain of the transistor NT33, and this voltage is used to carry out the level shift operation.

While, in case where the clock signal GCK1 is a high level, a potential difference between voltages applied to the gate and the source of the transistor NT33 becomes lower than the threshold voltage value Vth, so that the current i′b flowing through the transistor NT33 is zero or the current i′b hardly flows.

Thus, most of the current i′a flowing through the junction between (i) the drain of the transistor PT32 and (ii) the input terminal of the inverter I32 flows to the input terminal of the inverter I32, so that the current i′c becomes a positive current. As a result, the gate of the MOS transistor provided in the inverter I32 is charged with positive electric charge, so that a voltage of the gate of the MOS transistor is boosted.

When the voltage of the gate of the MOS transistor exceeds the logical inversion voltage of the inverter I32, a voltage equal to Vss is outputted to the input terminal of the inverter I33, so that the inverter I33 outputs a voltage equal to the driving voltage Vdd. Thus, a high level voltage of the clock signal GCK1 is boosted from a voltage lower than the driving voltage Vdd to a voltage equal to the driving voltage Vdd, and the boosted voltage is outputted as the output signal OUT1.

Such level shift operation causes the level shifter LS1 to convert the high level of the clock signal GCK1 into the driving voltage Vdd which is a high level of a predetermined power source voltage.

Next, the following description explains the case where the control signal ENB1 inputted to the level shifter LS1 is a high level, that is, the case of stopping the level shift operation of the level shifter LS1.

In this case, a high level is inputted to the gate of the transistor PT31, so that the transistor PT31 becomes non-conductive. As a result, the transistor PT31 does not serve as a constant current source. Likewise, the transistor PT32 becomes non-conductive, so that the constant current source transistor P4 does not serve as the constant current source.

While, a signal inputted to the gate of the transistor NT32 becomes a high level, so that the transistor NT32 becomes conductive. As a result, the power source voltage Vss is inputted to the gate of the transistor NT31 and the gate of the transistor NT33. Thus, the transistor NT31 and the transistor NT33 become non-conductive.

As a result, the level shift function (level shift operation) of the level shifter LS1 stops. At this time, both the transistor PT31 and the transistor NT31 are non-conductive, so that there is no through current i1 in a series circuit constituted of both the transistors. Further, both the transistor PT32 and the transistor NT33 are non-conductive, so that there is substantially no current i′b. As a result, there is no through current i2 also in the series circuit constituted of the transistor PT32 and the transistor PT33. Thus, the level shifter LS1 is stopped, so that neither current i1 nor current i2 flow, thereby reducing power consumption.

Further, in the level shifter LS1, when each control signal ENB1 becomes a high level and the level shifter LS1 stops its level shift function, a high level of the control signal ENB1 is inputted to one of the input terminals of the NAND circuit 31 of the output control section 30. Further, the control signal ENB1 is inputted to one of the input terminals of the NOR circuit 32 of the output control section 30 via the inverter I31, so that the low level is inputted.

In case where the output signal OUT1 of the inverter I33 before stoppage of the level shift operation (before the control signal ENB1 changes from the low level to the high level) is a high level, a high level of the control signal ENB1 and a high level of the output signal OUT1 of the inverter I33 are respectively inputted to both the input terminals of the NAND circuit 31. Thus, an output signal OC_P outputted from the NAND circuit 31 to the gate of the transistor PT33 becomes a low level, so that the transistor PT33 becomes conductive.

Further, in this case, a low level signal outputted from the inverter I31 and a high level of the output signal OUT1 of the inverter I33 are respectively inputted to both the input terminals of the NOR circuit 32. Thus, an output signal OC_N outputted from the NOR circuit 32 to the gate of the transistor NT35 becomes a low level, so that the transistor NT35 becomes non-conductive.

As a result, an input voltage of the inverter I32 becomes equal to the driving voltage Vdd, so that a voltage equal to the power source voltage Vss is outputted to the input terminal of the inverter I33. thus, the output voltage of the inverter I33 becomes equal to the power source voltage Vdd, so that the inverter I33 outputs the output signal OUT1 having the driving voltage Vdd. Thus, the output signal OUT1 of the level shifter LS1 is kept at a high level which is a state before stoppage of the level shift operation.

While, in case where the output signal OUT1 of the inverter I33 before stoppage of the level shift operation is a low level, a high level of the control signal ENB1 and a low level of the output signal OUT1 of the inverter I33 are respectively inputted to both the input terminals of the NAND circuit 31. Thus, an output signal OC_P outputted from the NAND circuit 31 to the gate of the transistor PT33 becomes a high level, so that the transistor PT33 becomes non-conductive.

In this case, a low level signal outputted from the inverter I31 and a low level of the output signal OUT1 of the inverter I33 are respectively inputted to both the input terminals of the NOR circuit 32. Thus, an output signal OC_N outputted from the NOR circuit 32 to the gate of the transistor NT35 becomes a high level, so that the transistor NT35 becomes conductive.

As a result, an input voltage of the inverter I32 becomes equal to the power source voltage Vss, so that a voltage equal to the driving voltage Vdd is outputted to the input terminal of the inverter I33. Thus, the output voltage of the inverter I33 becomes equal to the power source voltage Vss (low level of the clock signal GCK1), so that the inverter I33 outputs the output signal OUT1 having the power source voltage Vss. Thus, the output signal OUT1 of the level shifter LS1 is kept at a low level which is a state before stoppage of the level shift operation.

As described above, the level shifter circuit 1 according to the present embodiment stops the level shift operation of the level shifter LS1 during a period after the output signal Sx of the source shift register 20 which is inputted to the level shift control circuit 10 becomes a high level and until the output signal Sy of the source shift register 20 becomes a high level.

Thus, it is possible to reduce power consumption in a channel resistance and a wiring resistance of the MOS transistor which occupy an extremely large part of power consumption and which are caused by a through current of the offsetter section and the level shift section.

Note that, not only in the case where the clock signal inputted to the level shifter LS1 is a low level (non-active), but also in the case where the clock signal is a high level, the level shift operation of the level shifter LS1 is stopped during a period after the output signal Sx of the source shift register 20 becomes a high level and until the output signal Sy of the source shift register 20 becomes a high level.

Further, the level shifter circuit 1 includes an output control section 30 for keeping the output signal OUT1 of the level shifter LS1 at a state before stoppage of the level shift operation. That is, in case where the level shift operation is stopped, the output signal OUT1 of the level shifter LS1 is kept at a state before stoppage of the level shift operation regardless of whether the clock signal inputted to the level shifter LS1 is a low level or a high level.

Thus, the level shifter circuit 1 can greatly reduce power consumption and can suitably and stably drive a circuit connected to a stage following to the level shifter LS1.

### MODIFICATION EXAMPLE

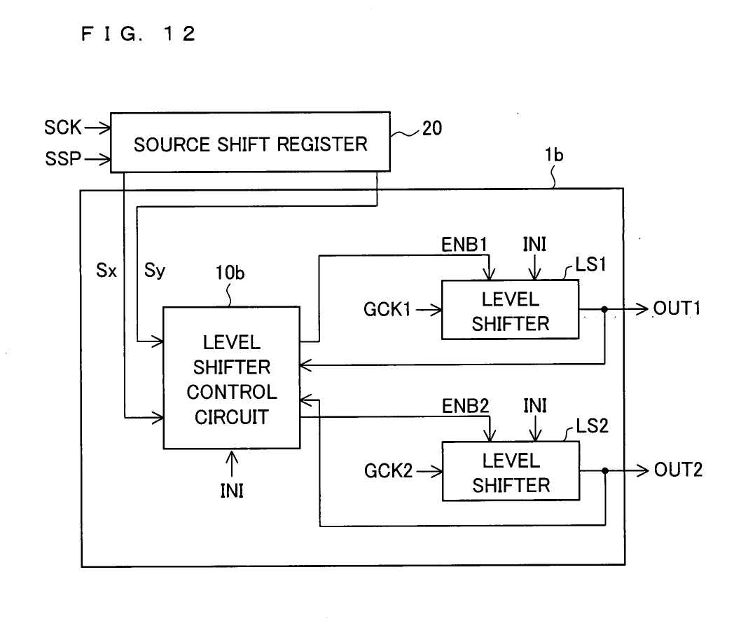

Further, the arrangement of the level shifter LS1 is not limited to the aforementioned arrangement. For example, the level shifter LS1 may be arranged as illustrated in FIG. 10. Note that, in FIG. 10, the same reference signs are given to members having the same functions as those of the members illustrated in FIG. 9, and descriptions thereof are omitted.

A level shifter LS1 of FIG. 10 includes an output control section 30b and an inverter I35 instead of the output control section 30 and the inverters I32 and I33 of FIG. 9.

The level shifter LS1 of FIG. 10 includes P-channel MOS transistors PT31, PT32, PT34 to PT36 (hereinafter, referred to as “transistors PT31, PT32, PT34 to PT36”), N-channel MOS transistors NT31 to NT34, NT36 to NT38 (hereinafter, referred to as “transistors NT31 to NT34, NT36 to NT38), and inverters I34 and I35. Note that, the output control section 30b is constituted of the inverter I34, the transistors PT34 to PT36, and the transistors NT36 to NT38.

In the level shifter LS1, a control signal ENB1 from the level shifter control circuit 10 is inputted to a gate of the transistor PT31, a gate of the transistor PT32, a gate of the transistor NT32, an input terminal of the inverter I34, and a gate of the transistor NT37.

A source of the transistor PT31 is connected to a power source line receiving the driving voltage Vdd, and a drain of the transistor PT31 is connected to a drain and a gate of the transistor NT31, a drain of the transistor NT32, and a gate of the transistor NT33.

A source of the transistor NT31 is connected to a power source line receiving the power source voltage Vss and a source of the transistor NT32, and a gate of the transistor NT31 is connected to a drain of the transistor NT31 itself.

A source of the transistor NT 32 is connected to a power source line receiving the power source voltage Vss, and a drain of the transistor NT32 is connected to gates of the transistors NT31 and NT33.

A source of the transistor PT32 is connected to a power source line receiving the driving voltage Vdd, and a drain of the transistor PT32 is connected to a drain of the transistor NT33, a drain of the transistor NT34, a drain of the transistor PT35, a drain of the transistor NT36, a gate of the transistor PT36, and a gate of the transistor NT38.

A source of the transistor NT33 is connected to an input terminal receiving the clock signal GCK1, and a gate of the transistor NT33 is connected to a gate of the transistor NT31, and a drain of the transistor NT33 is connected to a drain of the transistor NT34, a drain of the transistor PT35, a drain of the transistor NT36, a gate of the transistor PT36, and a gate of the transistor NT38.

A gate of the transistor NT34 is connected to an input terminal receiving the initialization signal INI, and a source of the transistor NT34 is connected to a power source line of the power source voltage Vss, and a drain of the transistor NT34 is connected to a drain of the transistor PT35, a drain of the transistor NT36, a gate of the transistor PT36, and a gate of the transistor NT38.

An output terminal of the inverter I34 is connected to a gate of the transistor PT34.

A source of the transistor PT34 is connected to a power source line receiving the driving voltage Vdd, and a drain of the transistor PT34 is connected to a source of the transistor PT35.

A drain of the transistor PT35 is connected to a drain of the transistor NT36, a gate of the transistor PT36, and a gate of the transistor NT38. Further, a gate of the transistor PT35 is connected to a gate of the transistor NT36, a drain of the transistor PT36, a drain of the transistor NT38, and an input terminal of the inverter I35.

A source of the transistor NT36 is connected to a drain of the transistor NT37, and a source of the transistor NT37 is connected to a power source line receiving the power source voltage Vss.

A source of the transistor PT36 is connected to a power source line receiving the driving voltage Vdd, and a drain of the transistor PT36 is connected to a drain of the transistor NT38 and an input terminal of the inverter I35.

A source of the transistor NT38 is connected to a power source line receiving the power source voltage Vss.

An output terminal of the inverter I35 is connected to a circuit connected to a next stage following to the level shifter LS1 and outputs an output signal OUT1 of the level shifter LS1.

Next, an operation of the level shifter LS1 is described as follows.

First, an initialization operation of the level shifter LS1 is described. In an initial state in which the level shifter LS1 is not stable, a high level (driving voltage Vdd) initialization signal INI is inputted to the gate of the transistor NT34 in order to stabilize the level shifter LS1.

The initialization signal INI is brought into a high level, so that the transistor NT34 becomes conductive. Thus, the transistor PT36 becomes conductive and the transistor NT38 is turned off, so that an input voltage of the inverter I35 becomes equal to the driving voltage Vdd. As a result, the output signal OUT1 having the power source voltage Vss is outputted.

The high level initialization signal INI is inputted during a period until the output signal OUT1 of the level shifter LS1 becomes equal to the power source voltage Vss, and then an initialization signal INI always having a low level (power source voltage Vss) in a normal state is inputted to the gate of the transistor NT34.

Therefore, the transistor NT34 is non-conductive in a normal state. In this case, when the control signal ENB1 is a low level, the transistors PT34 and NT37 are turned off. As a result, the level shifter LS1 becomes in a level shift operation state (active state).

Such initialization causes the level shifter LS1 to shift from the unstable initialization state to a stable state, so that the level shifter LS1 becomes active.

Note that, during a period in which the initialization signal INI is a high level, a low level signal is inputted to the input terminal receiving the clock signal GCK1. This is based on the following reason: when a high level signal is inputted to the input terminal receiving the clock signal GCK1 during a period in which the initialization signal INI is a high level, the transistor NT33 becomes non-conductive, and a current i′c flows from the transistor PT32 into the gates of the transistors PT36 and NT38, so that the transistor NT34 may prevent the power source voltage Vss from being applied to the gates of the transistors PT36 and NT38.

Next, the level shift operation of the level shifter LS1 is described. The control signal ENB1 is a low level in the level shift operation state, so that the transistor PT31 becomes conductive and the transistor NT32 is turned off. As a result, the transistor PT31 serves as a constant current source. Thus, an intermediate voltage (offset voltage) between the driving voltage Vdd and the power source voltage Vss is outputted to the gate of the transistor NT31 as a level shift operation voltage.

In a normal state, the offset voltage is equal to or slightly higher than the threshold voltage Vth of the transistor NT31. Thus, also the transistor NT31 becomes conductive. At this time, a voltage of the control signal ENB1 is a low level, so that the transistor (control transistor) NT32 is non-conductive.

Further, in case where the control signal ENB1 is a low level, the transistor (constant current source transistor) PT32 becomes conductive so as to serve as a constant current source.

A constant current i′a flowing through the transistor PT32 flows toward a junction between (i) a drain of the transistor PT32 and (ii) gates of the transistors PT36 and NT38 (current flowing in this direction is regarded as “positive”). A constant current i′b flowing through the transistor NT33 flows toward an input terminal receiving the clock signal GCK1 (current flowing in this direction is regarded as “positive”). Further, a current flowing from the junction A between (i) the drain of the transistor PT32 and (ii) the gates of the transistors PT36 and NT38 into the gates of the transistors PT36 and NT38 is a constant current i′c, and a current flowing in this direction is regarded as “positive”.

The offset voltage inputted to the gate of the transistor NT31 is inputted also to the gate of the transistor NT33 whose performance is substantially equal to the transistor NT31, so that a voltage equal to or slightly higher than the threshold voltage value Vth of the transistor NT33 is applied to the gate of the transistor NT33.

A voltage of the clock signal GCK1 is applied to the source of the transistor NT33, so that it is possible to control a current flowing through the transistor NT33 in accordance with slight variation of the voltage of the clock signal GCK1.

In case where the clock signal GCK1 is a low level, a potential difference between voltages applied to the gate and the source of the transistor NT33 is equal to or slightly higher than the threshold voltage value Vth, so that the transistor NT33 becomes conductive. When the transistor NT33 is conductive, the constant current i′a flows toward the input terminal of the clock signal GCK1 (through current).

Further, the current i′c flowing from the junction A between (i) the drain of the transistor PT32 and (ii) the gates of the transistors PT36 and NT38 into the gates of the transistors PT36 and NT38 becomes a pull-in current which flows toward the input terminal receiving the clock signal GCK1, so that the current i′c becomes negative.

Thus, the transistor PT36 becomes conductive and the transistor NT38 is turned off, so that the driving voltage Vdd is inputted to the input terminal of the inverter I35. As a result, the output signal OUT1 of the inverter I35 becomes equal to the power source voltage Vss (low level of the clock signal GCK1).

Such level shift operation causes the level shifter LS1 to convert the low level of the clock signal GCK1 into the power source voltage Vss which is a low level of a predetermined power source voltage. That is, the level shift operation during a low level period of the clock signal GCK1, i.e., the level shift operation during a non-active period is as follows. When a through current i1 (see FIG. 10) which is a stationary current flows through a series circuit (offsetter section) constituted of the transistor PT31 and the transistor NT31, and when a through current i2 (see FIG. 10) which is a stationary current flows through a series circuit (level shift section) constituted of the transistor PT32 and the transistor NT33, a voltage is generated in the junction between (i) the drain of the transistor PT32 and (ii) the drain of the transistor NT33, and this voltage is used to carry out the level shift operation.

While, in case where the clock signal GCK1 is a high level, a potential difference between voltages applied to the gate and the source of the transistor NT33 becomes lower than the threshold voltage value Vth, so that there is no current i′b flowing through the transistor NT33 or the current i′b hardly flows.

Thus, most of the current i′a flowing through the junction A of (i) the drain of the transistor PT32 and (ii) the gates of the transistors PT36 and NT38 flows to the gates of the transistors PT36 and NT38, so that the current i′c becomes a positive current. As a result, the transistor PT36 is turned off and the transistor NT38 becomes conductive, so that the power source voltage Vss is inputted to the input terminal of the inverter I35. As a result, the inverter I35 outputs a voltage equal to the driving voltage Vdd. Thus, a high level voltage of the clock signal GCK1 is boosted from a voltage lower than the driving voltage Vdd to the driving voltage Vdd, and the boosted voltage is outputted as the output signal OUT1.

Such level shift operation causes the level shifter LS1 to convert a high level of the clock signal GCK1 into the driving voltage Vdd which is a high level of a predetermined power source voltage.

Next, the following description explains the case where the control signal ENB1 inputted to the level shifter LS1 is a high level, that is, the case of stopping the level shift operation of the level shifter LS1.

In this case, a high level is inputted to the gate of the transistor PT31, so that the transistor PT31 becomes non-conductive. As a result, the transistor PT31 does not serve as the constant current source. Likewise, also the transistor PT32 becomes non-conductive, so that the constant current source transistor PT32 does not serve as the constant current source.

Meanwhile, a signal inputted to the gate of the transistor NT32 becomes a high level, so that the transistor NT32 becomes conductive. As a result, the power source voltage Vss is inputted to the gates of the transistors NT31 and NT33. Thus, the transistors NT31 and NT33 become non-conductive.

As a result, the level shift function (level shift operation) of the level shifter LS1 stops. At this time, both the transistor PT31 and the transistor NT31 are non-conductive, so that there is no through current i1 in a series circuit constituted of both the transistors. Further, both the transistor PT32 and the transistor NT33 are non-conductive, so that there is substantially no current i′b. As a result, there is no through current i2 also in the series circuit constituted of the transistor PT32 and the transistor NT33. Thus, the level shifter LS1 is stopped, so that neither the current i1 nor the current i2 flow, thereby reducing power consumption.

Further, in the level shifter LS1, when each control signal ENB1 becomes a high level and the level shifter LS1 stops its level shift function, the inverter I34 of the output control section 30b outputs a low level signal to the gate of the transistor PT34. As a result, the transistor PT34 becomes conductive. Further, a high level signal is inputted to the gate of the transistor NT37, so that the transistor NT37 becomes conductive.

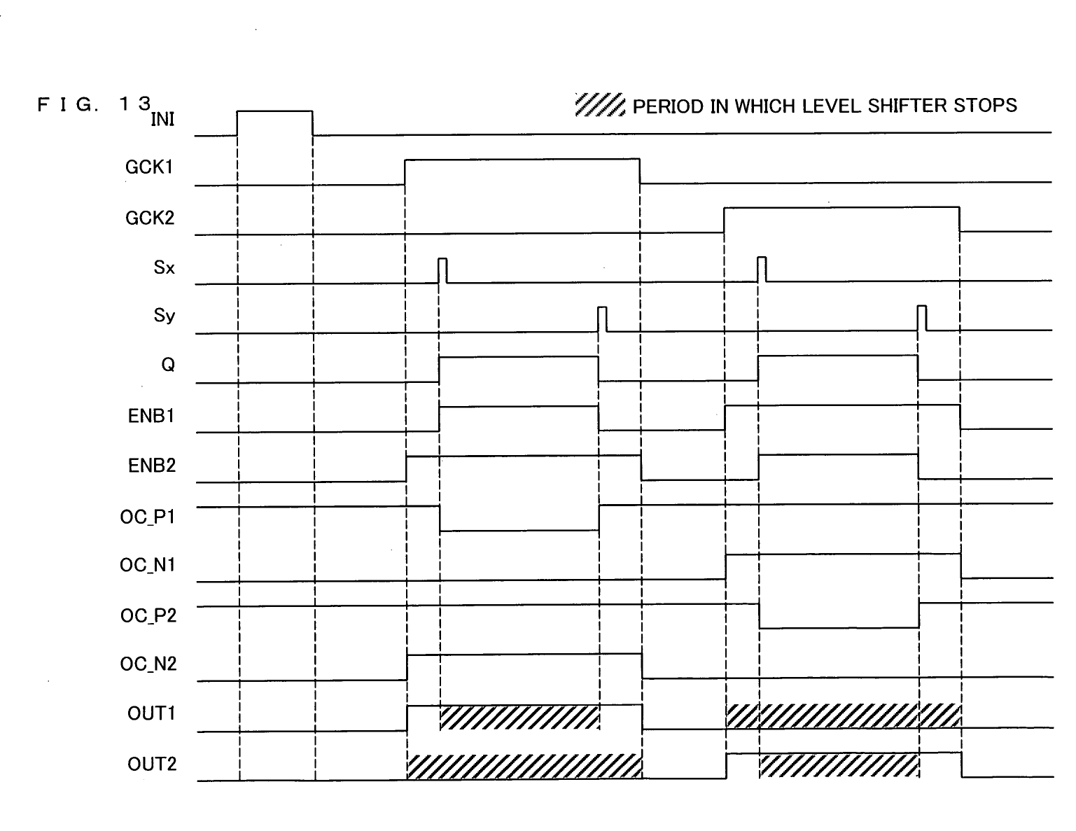

In case where the output signal OUT1 of the inverter I35 before stoppage of the level shift operation (before the control signal ENB1 changes from a low level to a high level) is a high level, a signal OB inputted to the input terminal of the inverter I35 is a low level (see FIG. 11). Thus, the transistor PT35 becomes conductive and the transistor NT36 is turned off. As a result, the transistors PT34 and PT35 become conductive, so that the driving voltage Vdd is inputted to the gates of the transistors PT36 and NT38. Thus, the transistor PT36 is turned off and the transistor NT38 becomes conductive, so that the power source voltage Vss is inputted to the input terminal of the inverter I35. As a result, the inverter I35 outputs the output signal OUT1 having the driving voltage Vdd. Thus, the output signal OUT1 of the level shifter LS1 is kept at a high level which is a state before stoppage of the level shift operation.

While, in case where the output signal OUT1 of the inverter I35 before stoppage of the level shift operation is a low level, a signal OB inputted to the input terminal of the inverter I35 is a high level (see FIG. 11). Thus, the transistor PT35 is turned off and the transistor NT36 becomes conductive. As a result, the transistors NT36 and NT37 become conductive, so that the power source voltage Vss is inputted to the gates of the transistors PT36 and NT38. Thus, the transistor PT36 becomes conductive and the transistor NT38 is turned off, so that the driving voltage Vdd is inputted to the input terminal of the inverter I35. As a result, the inverter I35 outputs the output signal OUT1 having the power source voltage Vss. Thus, the output signal OUT1 of the level shifter LS1 is kept at a low level which is a state before stoppage of the level shift operation.

Thus, in the level shift circuit 1, even in case of using the level shifter LS1 of FIG. 10, it is possible to carry out the same operation as the level shifter LS1 of FIG. 9.

Further, in the present embodiment, the level shift operation of the level shifter LS1 is stopped during a period after a time when the output signal Sx of the source shift register 20 becomes a high level until the output signal Sy of the source shift register 20 becomes a high level, but the present invention is not limited to this. For example, the level shift operation may be carried out at a timing at which one or both of the signals become low levels. It may be so arranged that: the level shift operation is stopped during a period after the output signal Sx of the source shift register 20 becomes a high level and then the output signal Sy of the source shift register 20 becomes a high level and until the output signal Sy further becomes a low level.

Further, in the present embodiment, the control signal ENB1 for controlling the level shift operation of the level shifter LS1 is generated in accordance with the output signals Sx and Sy of the source shift register 20, but the present invention is not limited to this. It is possible to use a signal which can be appropriately set during a period after a level shift operation corresponding an operation for switching the clock signal GCK1 from a non-active state to an active state is carried out until a level shift operation corresponding to an operation for switching the clock signal GCK1 from the active state to the non-active state. A preferable example thereof is a signal whose frequency is equal to or higher than a frequency of the clock signal GCK1.

For example, the control signal ENB1 may be generated by using two kinds of signals which are inputted during the active period of the clock signal GCK1 and whose input order (or order in which signal levels thereof are switched (low level and high level)) is determined. As an example of such a signal, it is possible to use a start pulse SSP inputted to the source shift register 20.

Alternatively, it is possible to generate the control signal ENB1 by using one kind of a signal which is inputted plural time during the active period of the clock signal GCK1 (signal levels thereof are switched plural times). In this case, the control signal ENB1 is generated in accordance with the number of times the one kind of the signal is inputted (or the number of times the signal levels are switched).

Further, in the present embodiment, the clock signal GCK1 is not inverted but is subjected to level shift so as to be outputted from the level shifter LS1. However, there is a case that a clock signal which has been subjected to level shift and has been inverted may be outputted from the level shifter. Also in this case, of course, a high level or a low level of the clock signal corresponds to a state in which a level of the power source voltage is shifted to a high level or a low level, so that the technical concept of the present invention is applicable.

Thus, generally, the level shifter may be arranged in any manner as long as: the level shifter is provided for each clock signal, and a high level of the clock signal is converted into either a high level or a low level of a predetermined power source voltage, and a low level of the clock signal is converted into either a high level or a low level of the power source voltage as the level shift operation. This is applicable also to the following embodiment.

Further, according to the level shifter circuit 1, in case of stopping the level shift operation when the clock signal GCK1 is a low level, the level shifter LS1 uses an alternative voltage generated by actively pulling down the output voltage into the power source voltage Vss instead of using a voltage generated by flowing a through current to the offsetter section and the level shift section, so that a non-active level (power source voltage Vss) which can be used instead of the power source voltage Vss serving as a converted level of the clock signal GCK1 due to the level shift operation is generated and outputted.

In the present embodiment, the non-active level is the power source voltage Vss, but the non-active level may be any level as long as the circuit connected to the stage following to the level shifter circuit 1 does not operate. Further, even in case where the alternative voltage is generated by actively pulling up the output voltage into the driving voltage Vdd, merely the number of inverter stages is changed, thereby obtaining the non-active level.

According to the arrangement, instead of the through current, a charge/discharge current with which a gate of an input stage MOS transistor of the inverter I32 is charged/discharged flows through the transistor NT35, so that merely a charge/discharge current of each gate at the time of switching of each MOS transistor accordingly flows. As a result, it is possible to obtain a non-active period level all the time while reducing power consumption.

Further, in the present embodiment, an active element such as the transistor NT35 is used to actively pulling up or actively pulling down the output voltage, but the present invention is not limited to this. If a resistor having a great resistance value is used instead of the active element so as to pull up the output voltage into the driving voltage Vdd or pull down the output voltage into the power source voltage Vss, it is possible to obtain the same effect.

Further, according to the level shifter circuit 1, the level shifter LS1 includes, as a circuit in which a through current of the level shift section flows, a boosting section arranged as a switching MOS transistor including a transistor NT33 serving as a MOS transistor whose source receives the clock signal GCK1.

The boosting section is a current driving type which electrifies the level shifter LS1 all the time during the level shift operation, and boosts a high level of the clock signal CK1 to the driving voltage Vdd which is a high level of a higher power source voltage.

Even though the MOS transistor has such unfavorable property that the threshold value of the transistor NT33 is higher than an amplitude of the inputted clock signal GCK1, installation of the boosting section allows the MOS transistor to shift a level of the clock signal GCK1 whose amplitude is smaller than a potential difference between a high level (driving voltage Vdd) of the power source voltage and a low level (power source voltage Vss) of the power source voltage during only an active period of the clock signal GCK1.

Note that, this is applicable not only to the case of the boosting section, but also to a case where there is provided a dropping section for dropping a low level of the clock signal GCK1 to a low level of lower power source voltage and a case where there are provided both the boosting section and the dropping section.

Further, the present embodiment described the arrangement in which there is provided the boosting section arranged as a switching MOS transistor and including the transistor NT33 serving as a MOS transistor whose source receives the clock signal GCK1, but the present invention is not limited to this. For example, it may be so arranged that: in a switching MOS transistor including a MOS transistor whose gate receives the clock signal GCK1, there is provided at least either (i) a boosting section which is a current driving type for electrifying the level shifter LS1 all the time during the level shift operation so as to boost one of a high level and a low level of the clock signal GCK1 to a high level of a power source voltage higher than the clock signal GCK1 or (ii) a dropping section for dropping the other of the high level and the low level of the clock signal GCK1 to a low level of the power source voltage lower than a low level of the clock signal GCK1.

According to the arrangement, even though the MOS transistor has such unfavorable property that the threshold value of the MOS transistor is higher than an amplitude of the inputted clock signal, at least either the current driving type boosting section or the current driving type dropping section allows a level of the clock signal whose amplitude is smaller than a potential difference between the high level and the low level of the power source voltage to be shifted only during an active period.

Further, the input signal is inputted to the gate of the transistor, so that it is possible to prevent an unnecessary current from entering into and outgoing from the input terminal for receiving the input signal.

### Embodiment 2

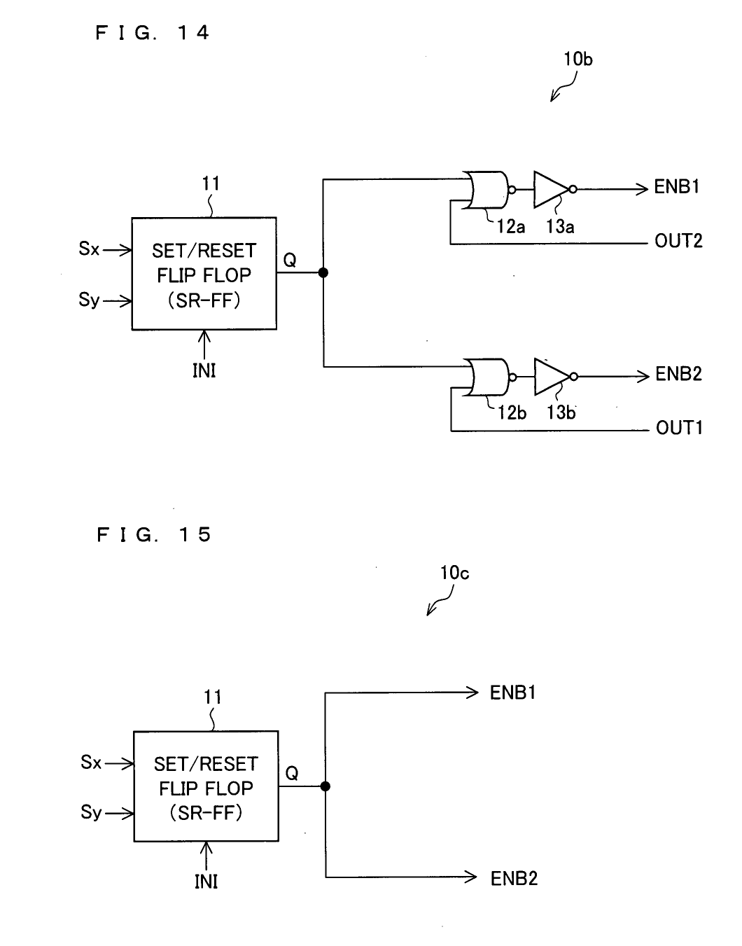

The following description explains a level shifter circuit according to another embodiment of the present invention. FIG. 12 is a block diagram schematically illustrating an arrangement of a level shifter circuit 1b according to the present embodiment. The level shifter circuit 1b is provided on the level shifter group 2 of the display device 100 illustrated in FIG. 2 of Embodiment 1, and shifts levels of clock signals GCK1 and GCK2 outputted to the gate driver 4. Further, FIG. 13 is a timing chart of the level shifter circuit 1b. Note that, unless particularly mentioned, the same reference signs given to the same members and the same signals as in Embodiment 1 represent members and signs which have the same functions as in Embodiment 1 and can be modified in the same manner (same arrangement modification), and descriptions thereof are omitted.

As in the level shifter circuit 1 according to Embodiment 1, the level shifter circuit 1b according to the present embodiment functions as a part of the gate driver which is provided on the display device 100 so as to drive the scanning signal line. Note that, a position in which the level shifter circuit 1b is provided may be outside the gate driver 4 or inside the gate driver 4 as in the level shifter circuit 1 of Embodiment 1.

As illustrated in FIG. 12, the level shifter circuit 1b includes a level shifter control circuit 10b, a level shifter LS1, and a level shifter LS2. Note that, the level shifter LS2 is arranged in the same manner as in the level shifter LS1, and carries out level shift so as to boost a high level of an inputted clock signal GCK2 to a driving voltage Vdd of a circuit (not shown) connected to a stage following to the level shifter LS2, and outputs the boosted high level as an output signal OUT2. Here, the high level of the clock signal GCK2 is lower than the driving voltage of the circuit connected to the following stage. Further, the level shifters LS1 and LS2 may be arranged as illustrated in FIG. 9 of Embodiment 1, or may be arranged as illustrated in FIG. 10 of Embodiment 1.

Note that, in the present embodiment, the clock signals GCK1 and GCK2 are two kinds of clock signals having phases whose high level periods do not overlap each other, and a duty of the clock signals GCK1 and GCK2 in terms of a high level period is less than (100×0.5) %. Further, the high level period of the clock signal GCK1 is an active period in which a circuit connected to the stage following to the level shifter LS1 is operated, and the high level period of the clock signal GCK2 is an active period in which a circuit connected to the stage following to the level shifter LS2 is operated. The low level period of the clock signal GCK1 is a non-active periods in which the circuit connected to the stage following to the level shifter LS1 is not operated, and the low level period of the clock signal GCK2 is a non-active period in which the circuit connected to the stage following to the level shifter LS2 is not operated.

In accordance with output signals Sx and Sy of the source shift register 20 provided in the source driver 3 and output signals OUT1 and OUT2 of the level shifters LS1 and LS2, the level shifter circuit 10b generates control signals ENB1 and ENB2 for controlling operations of the level shifters LS1 and LS2.

Note that, when the control signals ENB1 and ENB2 are high levels, the level shifter circuit 1b stops level shift operations of the level shifters LS1 and LS2 corresponding to the control signals. When the control signals ENB1 and ENB2 are low levels, the level shifter circuit 1b allows the level shifters LS1 and LS2 corresponding to the control signals to carry out the level shift operations.

Each shaded portion of the timing chart of FIG. 13 indicates a state in which the level shifter LS1 or the level shifter LS2 stops its level shift operation. Note that, each shaded portion in a waveform of the output signal OUT1 of the level shifter LS1 indicates a period in which the level shift operation of the level shifter LS1 is stopped. Further, each shaded portion in a waveform of the output signal OUT2 of the level shifter LS2 indicates a period in which the level shift operation of the level shifter LS2 is stopped.

As illustrated in FIG. 13, when a clock signal inputted to one of the level shifters is active, the level shifter circuit 1b stops the level shift operation of the other level shifter.

Further, also in the level shifter receiving the active clock signal, its level shift operation is stopped during a period after the output signal Sx of the source shift register 20 becomes a high level and until the output signal Sy of the source shift register 20 becomes a high level. Note that, in case of stopping the level shift operation, an output signal of the level shifter is kept at an output state before stoppage of the level shift operation.

The source shift register 20 and the output signals Sx and Sy of the source shift register 20 are arranged in the same manner as in Embodiment 1.

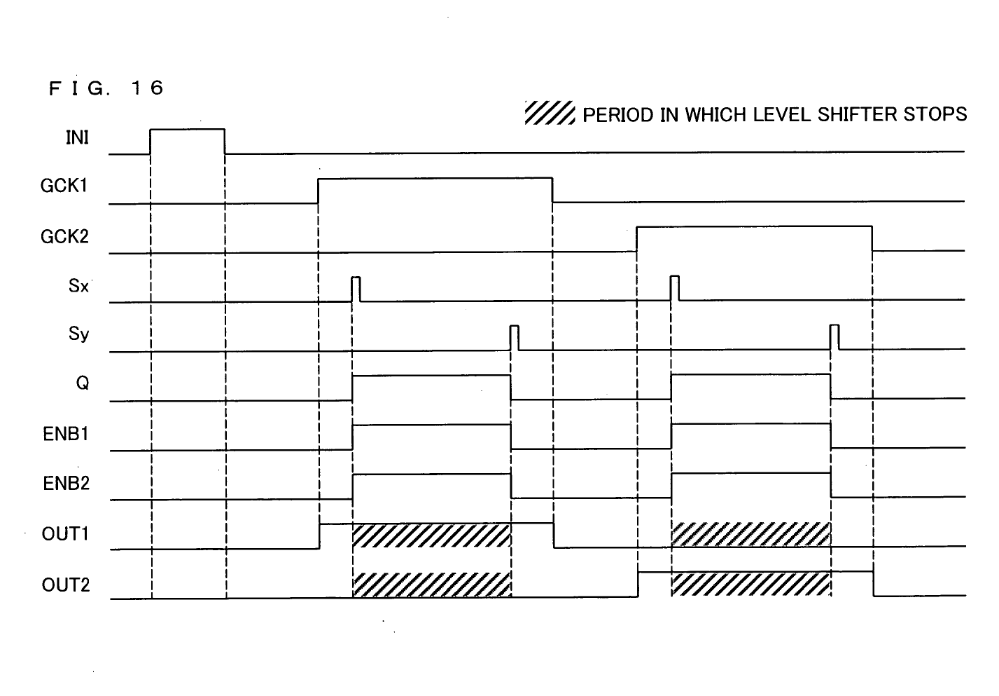

FIG. 14 is a block diagram illustrating an arrangement of the level shifter control circuit 10b. As illustrated in FIG. 14, the level shifter control circuit 10b includes a set-reset flip flop (SR-FF) 11, a NOR circuit 12a, an inverter 13a, a NOR circuit 12b, and an inverter 13b. Note that, the SR-FF11 is arranged in the same manner as in Embodiment 1.

An output signal Q of the SR-FF11 is inputted to one of input terminals of the NOR circuit 12a and one of input terminals of the NOR circuit 12b as illustrated in FIG. 14.

Further, an output signal OUT2 of the level shifter LS2 is inputted to the other of the input terminals of the NOR circuit 12a, and an output signal OUT1 of the level shifter LS1 is inputted to the other of the input terminals of the NOR circuit 12b.

The output of the NOR circuit 12a is inputted to the inverter 13a and is then inverted, and the inverted output is outputted to the level shifter LS1 as a control signal ENB1. Further, the output of the NOR circuit 12b is inputted to the inverter 13b and is then inverted, and the inverted output is outputted to the level shifter LS2 as a control signal ENB2.

As a result, during a period in which one of the level shifter LS1 and the level shifter LS2 is active (period in which one of the output signal OUT1 and the output signal OUT2 is high), a high level signal is inputted to the NOR circuit for generating a control signal of the other level shifter, so that the control signal ENB1 or the control signal ENB2 of the other level shifter becomes a high level as illustrated in FIG. 13. That is, the NOR circuit 12a serves as active period detection means for detecting an active period of the one level shifter (period in which the output signal is a high level), and the NOR circuit 12b serves as active period detection means for detecting an active period of the other level shifter (period in which the output signal is a high level).

Further, the output signal Q of the SR-FF11 is a high level during a period after the output signal Sx of the source shift register 20 is inputted and until the output signal Sy of the source shift register 20 is inputted, so that both the control signals ENB1 and ENB2 are high levels. That is, not only the level shifter receiving the non-active clock signal but also the level shifter receiving the active clock signal has a high level control signal.

The level shifter LS2 is arranged in the same manner as in the level shifter LS1, and also an operation of the level shifter LS2 is the same as in the level shifter LS1. However, not the control signal ENB1 but the control signal ENB2 is inputted to gates of the transistors PT31, PT32, and NT32, an input terminal of the inverter I31, and one of input terminals of the NAND circuit 31. Further, not the clock signal GCK1 but the clock signal GCK2 is inputted to a source of the transistor NT33. Further, the level shifter LS2 outputs the output signal OUT2.

As described above, when one of the level shifters LS1 and LS2 outputs a high level signal, the level shifter circuit 1b stops the level shift operation of the other level shifter. Thus, during a non-active period of the other level shifter required to carry out no level shift operation for converting an inputted clock signal into other level, it is possible to reduce power consumption in a channel resistance and a wiring resistance of the MOS transistor which occupy an extremely large part of power consumption and which are caused by a through current of the offsetter section and the level shift section. As a result, power consumption of the level shifter circuit 1b is greatly reduced.

Further, also in the level shifter receiving the clock signal which is in an active period, the level shift operation is stopped after the output signal Sx of the source shift register 20 becomes a high level and until the output signal Sy of the source shift register 20 becomes a high level.

As a result, it is possible to further reduce power consumption of the level shifter circuit 1b.

Further, in the level shifter circuit 1b, each of the level shifters LS1 and LS2 includes an output control section 30 for keeping each of the output signals OUT1 and OUT2 of the level shifters LS1 and LS2 at a state before stoppage of the level shift operation in case of stopping the level shift operation. That is, in case of stopping the level shift operation, each of the output signals OUT1 and OUT2 of the level shifters LS1 and LS2 is kept at state before stoppage of the level shift operation regardless of whether each of the clock signals inputted to the level shifters LS1 and LS2 is a low level or a high level.

As a result, in the level shifter circuit 1b, it is possible to greatly reduce power consumption and it is possible to appropriately and stably drive the circuit connected to the stage following to the level shifter LS1 and drive the circuit connected to the stage following to the level shifter LS2.

Note that, the present embodiment described the case where two kinds of signals such as the clock signals GCK1 and GCK2 are used so as to have phases whose high level periods do not overlap each other. However, the present invention is not limited to this. The technical concept of the present invention is applicable to two clock signals having phases whose low level periods do not overlap each other and to two clock signals having both phases whose high level periods do not overlap each other and phases whose low level periods do not overlap each other.

Further, in the present embodiment, the clock signals GCK1 and GCK2 are not inverted but subjected to level shift so as to be outputted from the level shifters LS1 and LS2. However, there is a case where the clock signals are inverted and subjected to level shift so as to be outputted from the level shifters.

Of course, the technique of the present invention is applicable also to this case since the foregoing arrangement corresponds to the state in which a high level or a low level of each clock signal is level-shifted to a high level or a low level of the power source voltage.

Thus, generally, the level shifter is arranged in any manner as long as: the level shifter is provided for each clock signal, and carries out a level shift operation by converting a high level of the clock signal into one of a high level and a low level of the power source voltage and converting a low level of the clock signal into the other of the high level and the low level of the power source voltage. This is applicable also to the following embodiment.

Further, according to the level shifter circuit 1b, each of the level shifters LS1 and LS2 uses an alternative voltage generated by actively pulling down the output voltage into the power source voltage Vss, instead of using a voltage generated by flowing a through current into the offsetter section and the level shift section, during a specific period corresponding to a non-active period of one of the clock signals GCK1 and GCK2 and an active period of the other clock signal, thereby generating and outputting a non-active level (power source voltage Vss) instead of the power source voltage Vss which is a converted level of each of the clock signals GCK1 and GCK2 as a result of the level shift operation.

The non-active level may have any value as long as the level does not allow the circuit at the stage following to the level shifter circuit 1b to operate. Further, even when the alternative voltage is generated by actively pulling up the output voltage into the driving voltage Vdd, it is possible to obtain the non-active level by changing the number of inverters accordingly.

With the arrangement, a charge/discharge current for charging/discharging a gate of an input stage MOS transistor of the inverter I32 flows through the transistor NT35 instead of the through current, and a charge/discharge current of each gate in switching each MOS transistor flows accordingly, so that it is possible to obtain a non-active period level all the time while reducing power consumption.

Further, an active element such as the transistor NT35 is used to actively pull up or actively pull down the output voltage, but the present invention is not limited to this. Instead of the active element, the output voltage is pulled up to the driving voltage Vdd or pulled down to the power source voltage Vss by using a resistor having a great resistance value, so that it is possible to obtain the same effect.

Further, according to the level shifter circuit 1b, a duty of the clock signals GCK1 and GCK2 whose high level periods do not overlap each other is less than (100×0.5) %, so that the high level periods of the two clock signals GCK1 and GCK2 never overlap each other. Thus, it is possible to freely set the active periods of the clock signals GCK1 and GCK2 as necessary so as to carry out the level shift operation. This is applicable also to a case where the two clock signals have low level periods which do not overlap each other and a duty thereof is less than (100×0.5) %.

Further, according to the level shifter circuit 1b, as a circuit in which a through current of the offsetter section and the level shift section flows, each of the level shifters LS1 and LS2 includes, as a switching MOS transistor, a boosting section having a transistor NT33 serving as a MOS transistor whose source receives each of the clock signals GCK1 and GCK2.

The boosting section is a current driving type which electrifies the level shifters LS1 and LS2 all the time during the level shift operations thereof, and boosts a high level of each of the clock signals CK1 and CK2 to the driving voltage Vdd which is a high level of a higher power source voltage.

Even though the MOS transistor has such unfavorable property that the threshold value of the transistor NT33 is higher than an amplitude of each of the inputted clock signals GCK1 and GCK2, the boosting section allows the MOS transistor to shift a level of each of the clock signals GCK1 and GCK2 whose amplitudes are lower than a potential difference between a high level (driving voltage Vdd) of the power source voltage and a low level (power source voltage Vss) of the power source voltage during only an active period of each of the clock signals GCK1 and GCK2.

Note that, this is applicable not only to the case of the boosting section, but also to a case where there is provided a dropping section for dropping a low level of the clock signal to a low level of lower power source voltage and a case where there are provided both the boosting section and the dropping section.

Further, according to the level shifter circuit 1b, the high level periods of the clock signals GCK1 and GCK2 which periods do not overlap each other respectively corresponds to active periods of the clock signals GCK1 and GCK2. Further, one of the level shifters LS1 and LS2 stops the level shift operation with respect to each of the clock signals GCK1 and GCK2 during an active period of each clock signal inputted to the other of the level shifters LS1 and LS2.

Thus, in this period, only the level shifter receiving a high level clock signal carries out the level shift operation before the output signal Sx of the source shift register 20 becomes a high level and after the output signal Sy of the source shift register 20 becomes a low level.

Further, the present embodiment described the level shifter circuit 1b arranged so that: when the clock signal inputted to one of the level shifters is active, the level shift operation of the other level shifter is stopped, and during a period after the output signal Sx of the source shift register is inputted and until the output signal Sy of the source shift register 20 is inputted, the level shift operation of the one level shifter is stopped. However, the arrangement of the level shifter circuit 1b is not limited to this.

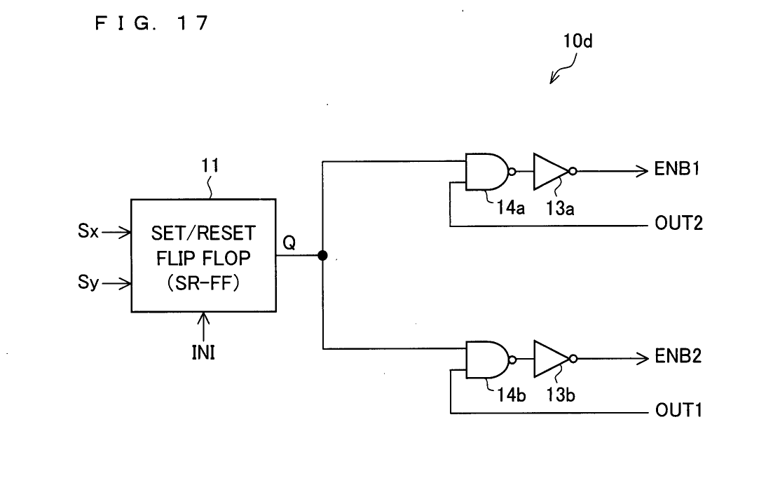

For example, the level shift operations of the level shifters LS1 and LS2 are controlled in accordance with only the output signals Sx and Sy of the source shift register 20. In this case, the arrangement of the level shifter control circuit 10b of the level shifter circuit 1b is changed into an arrangement of a level shifter control circuit 10c illustrated in FIG. 15 for example. That is, the output signal Q of the SR-FF11 is outputted to the level shifters LS1 and LS2 as the control signals ENB1 and ENB2 for respectively controlling the level shift operations of the level shifters LS1 and LS2.

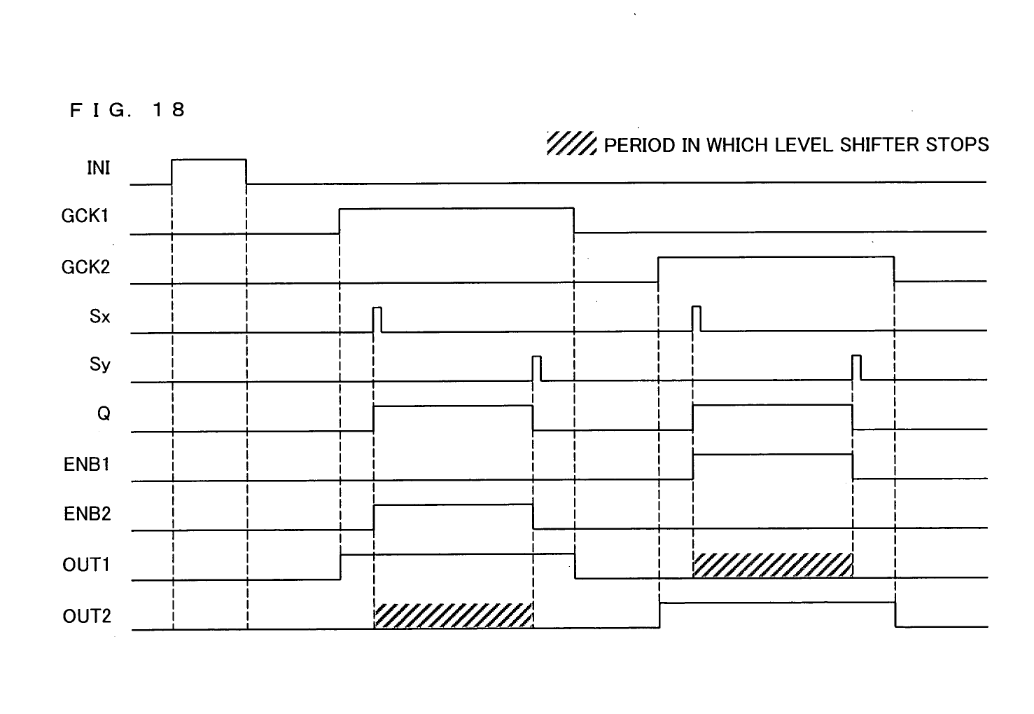

A timing chart in this case is illustrated in FIG. 16. As illustrated in FIG. 16, the level shifters LS1 and LS2 stop the level shift operations during a period after the output signal Sx of the source shift register 20 becomes a high level and until the output signal Sy of the source shift register 20 becomes a high level regardless of whether the inputted clock signals GCK1 and GCK2 are active or non-active.

Further, it may be so arranged that: during a period in which an active clock signal is inputted to one of the level shifters LS1 and LS2 and after the output signal Sx of the source shift register 20 becomes a high level and until the output signal Sy of the source shift register 20 becomes a high level, the level shift operation of the other level shifter is stopped.

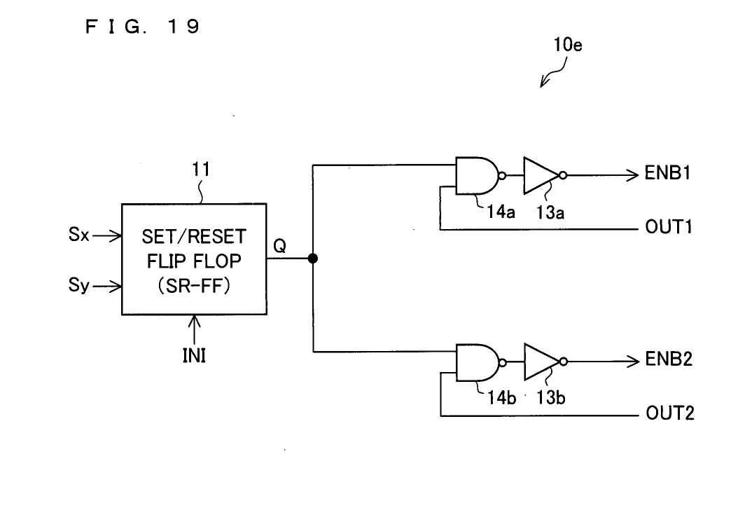

In this case, the arrangement of the level shifter control circuit 10b of the level shifter circuit 1b is changed into an arrangement of a level shifter control circuit 10d illustrated in FIG. 17. That is, a NAND circuit 14a is used instead of the NOR circuit 12a of the level shifter circuit 10b, and a NAND circuit 14b is used instead of the NOR circuit 12b of the level shifter circuit 10b for example.

With this arrangement, as illustrated in FIG. 18, when both the output signal Q of the SR-FF11 and the output signal OUT2 of the level shifter LS2 are high levels, the control signal ENB1 for controlling the level shift operation of the level shifter LS1 becomes a high level, so that the level shift operation of the level shifter LS1 is stopped. Further, when both the output signal Q of the SR-FF11 and the output signal OUT1 of the level shifter LS1 are high levels, the control signal ENB2 for controlling the level shift operation of the level shifter LS2 becomes a high level, so that the level shift operation of the level shifter LS2 is stopped.

Further, it may be so arranged that: the level shift operation of the level shifter receiving an active clock signal is stopped during a period after the output signal Sx of the source shift register 20 becomes a high level and until the output signal Sy of the source shift register 20 becomes a high level.

In this case, as illustrated in FIG. 19, the output signal Q of the SR-FF11 and the output signal OUT1 of the level shifter LS1 are respectively inputted to the input terminals of the NAND circuit 14a of the level shifter control circuit 10d of FIG. 17, and the output signal Q of the SR-FF11 and the output signal OUT2 of the level shifter LS2 are respectively inputted to the input terminals of the NAND circuit 14b of the level shifter control circuit 10d of FIG. 17.

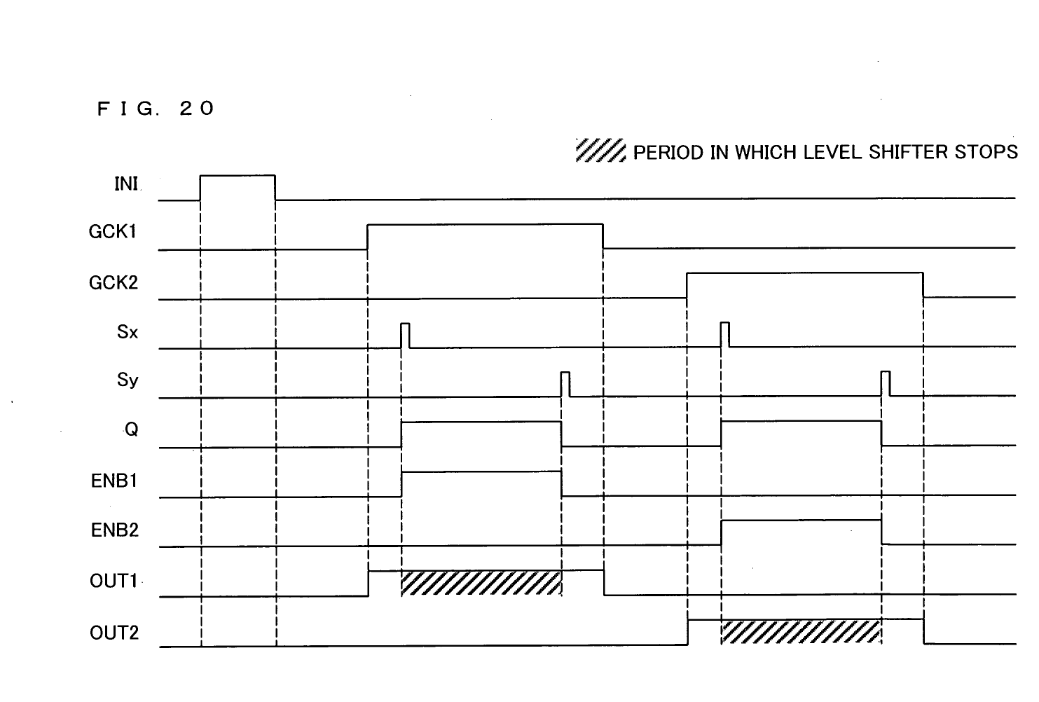

With this arrangement, as illustrated in FIG. 20, when both the output signal Q of the SR-FF11 and the output signal OUT1 of the level shifter LS1 are high levels, the control signal ENB1 for controlling the level shift operation of the level shifter LS1 becomes a high level, and the level shift operation of the level shifter LS1 is stopped. Further, when both the output signal Q of the SR-FF11 and the output signal OUT2 of the level shifter LS2 are high levels, the control signal ENB 2 for controlling the level shift operation of the level shifter LS2 becomes a high level, and the level shift operation of the level shifter LS2 is stopped.

Further, in the present embodiment, the level shift operation of the level shifter LS1 is stopped during a period after the output signal Sx of the source shift register 20 becomes a high level and until the output signal Sy of the source shift register 20 becomes a high level. However, the present invention is not limited to this. For example, the present invention is not limited to the arrangement in which the level shift operation is controlled in accordance with a timing at which the output signals Sx and Sy become high levels, and it may be so arranged that: the level shift operation is controlled in accordance with a timing at which one or both of the output signals become high levels.

Further, in the present embodiment, the control signals ENB1 and ENB2 for controlling the level shift operation of the level shifter LS1 are generated in accordance with the output signals Sx and Sy of the source shift register 20, but the present invention is not limited to this.

For example, it may be so arranged that: two kinds of signals which are inputted during an active period of the clock signal GCK1 in a determined order (two kinds of signals whose levels (low level and high level) are switched in a determined order) are used to generate the control signals ENB1 and ENB2. An example of the signals is a start pulse SSP inputted to the source shift register 20.

Alternatively, it is also possible to generate the control signal ENB1 by using one kind of signal which is inputted plural times (whose signal level is switched plural times) during an active period of the clock signal GCK1. In this case, the control signal ENB1 is generated in accordance with the number of times the one kind of signal is inputted (or the number of times the signal level is switched).

### Embodiment 3

The following description explains still another embodiment of the present invention. Note that, unless particularly mentioned, the same reference signs given to the same members and the same signals as in Embodiment 1 represent members and signs which have the same functions as in Embodiment 1 and can be modified in the same manner (same arrangement modification), and descriptions thereof are omitted.

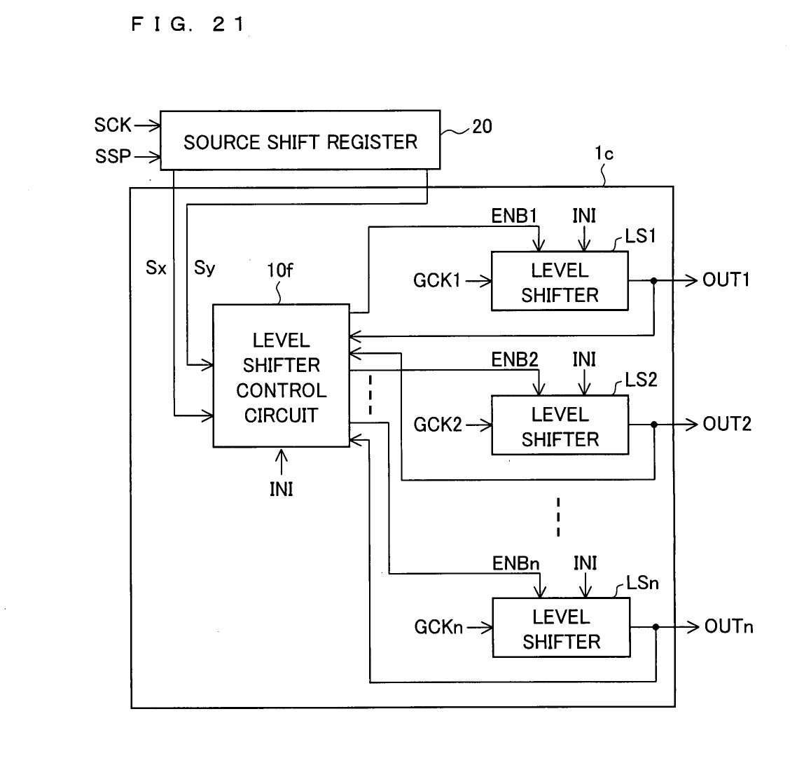

FIG. 21 is a circuit block diagram schematically illustrating an arrangement of a level shifter circuit 1c according to the present embodiment. The level shifter circuit c1 is provided on the level shifter group 2 of the display device 100 illustrated in FIG. 2 of Embodiment 1 for example, and shifts levels of clock signals GCK1, GCK2, . . . , GCKn (n is an integer not less than 2) inputted to the gate driver 4. That is, Embodiment 2 described the level shifter circuit 1b having the level shifters LS1 and LS2. The present embodiment will describe the level shifter circuit 1c including a large number (n-number) of level shifters LS1, LS2, . . . , LSn as illustrated in FIG. 21. Note that, the level shifters LS1, LS2, . . . , LSn are arranged in the same manner as in the level shifter LS1 described in Embodiment 1. Further, FIG. 2 illustrates only the clock signals GCK1 and GCK2, but the gate driver 4 receives n-number of clock signals GCK1, GCK2, . . . , GCKn.

Further, n is an integer not less than 2, and the level shifters LS1, LS2, . . . , LSn respectively carry out level shift with respect to high levels of the clock signals GCK1, GCK2, . . . , GCKn, and respectively boost, up to output signals OUT1, OUT2, . . . , OUTn, voltages which are lower than driving voltages Vdd of circuits connected to stages so that the stages respectively follow to the level shifters, so as to output the boosted clock signals.

Further, the clock signals GCK1, GCK2, . . . , GCKn are n kinds of clock signals having phases whose high level periods do not overlap each other, and a duty of the clock signals GCK1, GCK2, . . . , GCKn in terms of a high level period is less than (100×1/n) %. Further, the high level periods of the clock signals GCK1, GCK2, . . . , GCKn are active periods for operating the circuits connected to the stages so that the stages respectively follow to the level shifters LS1, LS2, . . . , LSn, and low level periods of the clock signals are non-active periods which do not allow any operation of the circuits connected to the stages so that the stages respectively follow to the level shifters.

Further, the level shifter circuit 1c may be provided outside the gate driver 4 or may be provided in the gate driver 4 as in the level shifter circuit 1 of Embodiment 1 and the level shifter circuit 1b of Embodiment 2.

A level shifter control circuit 10f generates control signals ENB1, ENB2, . . . , ENBn for controlling operations of the level shifters LS1, LS2, . . . , LSn, in accordance with (i) output signals Sx and Sy of the source shift register 20 provided in the source driver 3 and (ii) output signals OUT1, OUT2, . . . , OUT3 of the level shifters LS1, LS2, LSn.

Further, when the control signals ENB1, ENB2, ENBn are high levels, the level shifter circuit 1c stops level shift operations of the level shifters LS1, LS2, LSn, corresponding to the control signals, and when the control signals ENB1, ENB2, . . . , ENBn are low levels, the level shifter circuit 1c causes the level shifters corresponding to the control signals to carry out level shift operations.

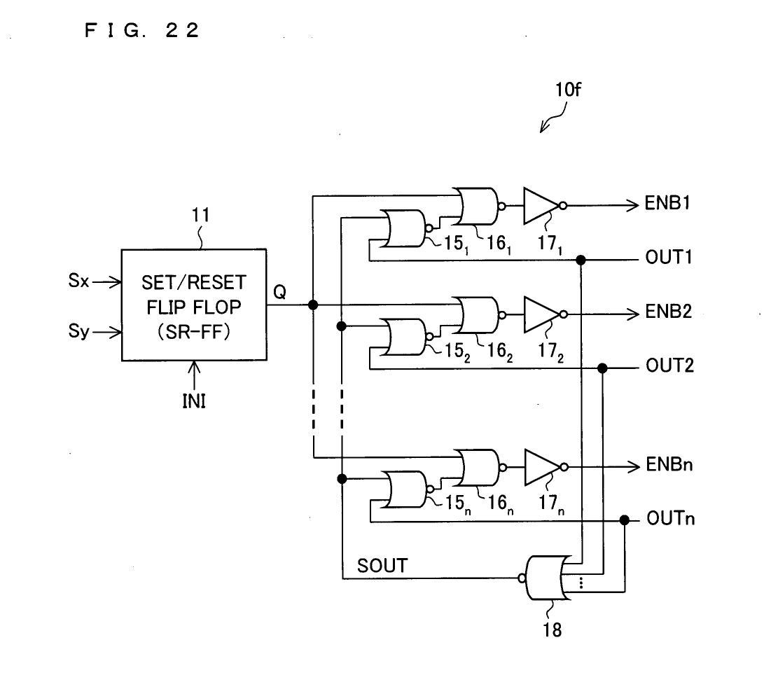

FIG. 22 is a block diagram illustrating an arrangement of the level shifter control circuit 10f. As illustrated in FIG. 22, the level shifter control circuit 10f includes a set/reset flip flop (SR-FF) 11, NOR circuits 15₁, 15₂, . . . , 15n, NOR circuits 16₁, 16₂, . . . , 16n, inverters 17₁, 17₂, . . . , 17n, and a NOR circuit 18.

The output signals OUT1, OUT2, . . . , OUTn of the level shifters LS1, LS2, . . . , LSn are respectively inputted to the NOR circuits 15₁, 15₂, . . . , 15n so that one of input terminals of each NOR circuit receives each output signal. As a result, the NOR circuits 15₁, 15₂, . . . , 15n serve as active period detection means for detecting active periods of the level shifters LS1, LS2, . . . , and LSn.

Further, the output signals OUT1, OUT2, . . . , OUTn of the level shifters LS1, LS2, . . . , LSn are inputted to input terminals of the NOR circuit 18. Further, an output signal SOUT of the NOR circuit 18 is inputted to the NOR circuits 15₁, 15₂, . . . , 15n so that the other input terminal of each NOR circuit receives the output signal SOUT.

Output terminals of the NOR circuits 15₁, 15₂, . . . , 15n are respectively connected to the NOR circuits 16₁, 16₂, . . . , 16n so that each output terminal is connected to one of input terminals of each of the NOR circuits 16₁, 16₂, . . . , and 16n. Further, an output signal Q of the SR-FF11 is inputted to the other input terminal of each of the NOR circuits 16₁, 16₂, . . . , and 16n.

Further, output terminals of the NOR circuits 16₁, 16₂, . . . , and 16n are respectively connected to input terminals of the inverters 17₁, 17₂, . . . , and 17n so that each output terminal is connected to one of input terminals of each of the inverters 17₁, 17₂, . . . , and 17n. Further, the control signals ENB1, ENB2, . . . , and ENBn outputted from the output terminals of the inverters 17₁, 17₂, . . . , and 17n are respectively inputted to the level shifters LS1, LS2, . . . , and LSn as illustrated in FIG. 21.

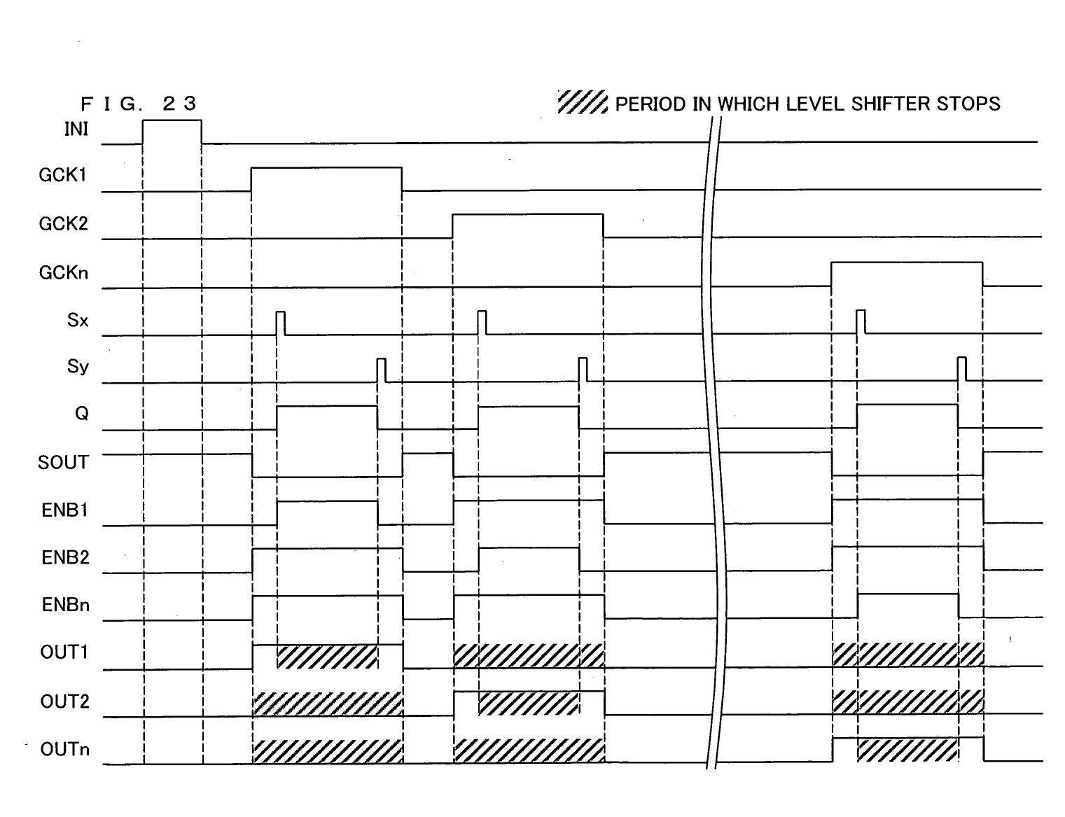

FIG. 23 is a timing chart of the level shifter circuit 1c. As illustrated in FIG. 23, with the foregoing arrangement, when a clock signal inputted to one of the level shifters is a high level (active), the level shifter circuit 1c stops level shift operations of other level shifters. Further, as to a level shifter receiving an active clock signal, its level shift operation is stopped during a period after the output signal Sx of the source shift register 20 becomes a high level and until the output signal Sy of the source shift register 20 becomes a high level.

Further, as in Embodiments 1 and 2, in case of stopping the level shift operations, the output signals of the level shifters LS1, LS2, . . . , and LSn are kept at a state before stoppage of the level shift operations. Thus, in the level shifter circuit 1c, it is possible to greatly reduce power consumption and it is possible to appropriately and stably drive the circuits connected to the stages so that the stages respectively follow to the level shifters LS1, LS2, . . . , and LSn.

Note that, in the present embodiment, when a clock signal inputted to one of the level shifters is a high level (active), the level shifter circuit 1c stops level shift operations of other level shifters. Further, as to a level shifter receiving an active clock signal, its level shift operation is stopped during a period after the output signal Sx of the source shift register 20 becomes a high level and until the output signal Sy of the source shift register 20 becomes a high level. However, the present invention is not limited to this.

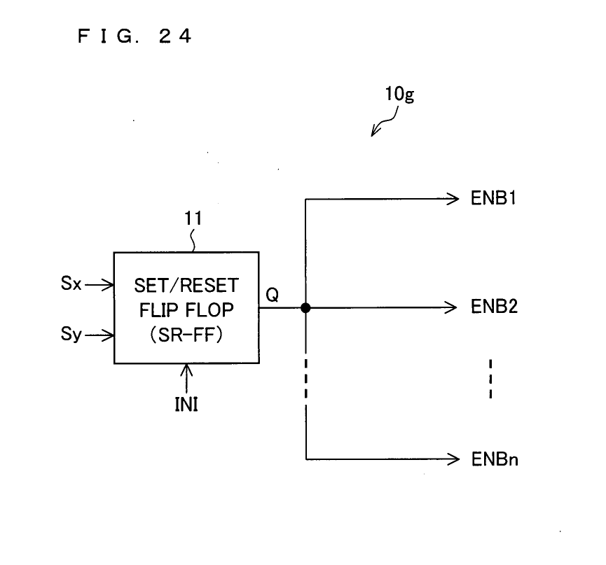

For example, the level shift operations of the level shifters LS1, LS2, . . . , and LSn may be controlled in accordance with only the output signals Sx and Sy of the source shift register 20. In this case, the arrangement of the level shifter control circuit 10f of the level shifter circuit 1c is changed into an arrangement of a level shifter control circuit 10g illustrated in FIG. 24.

That is, the output signal Q of the SR-FF11 is outputted to the level shifters LS1, LS2, . . . , LSn, as the control signals ENB1, ENB2, . . . , ENBn.

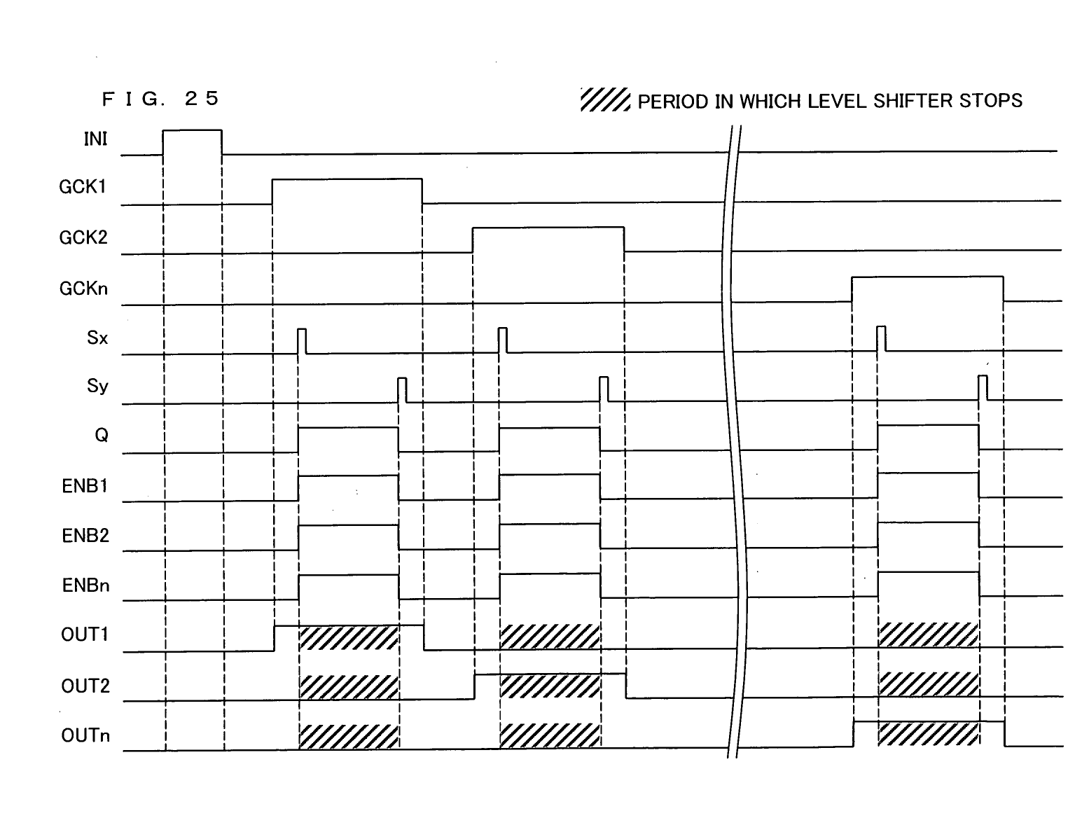

As a result, it is possible to stop the level shift operations of the level shifters LS1, LS2, . . . , LSn, during a period after the output signal Sx of the source shift register 20 becomes a high level and until the output signal Sy of the source shift register 20 becomes a high level, as illustrated in FIG. 25.

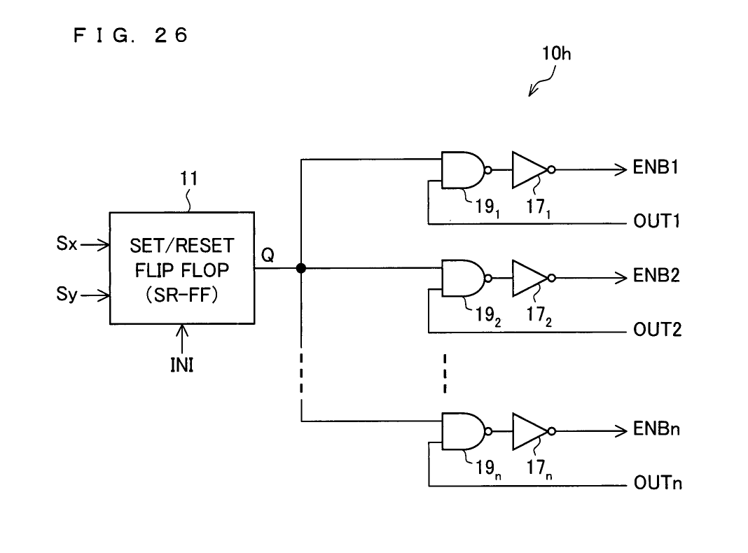

Further, the arrangement of the level shifter control circuit 10f of the level shifter circuit 1c may be changed into an arrangement of a level shifter control circuit 10h illustrated in FIG. 26.

As illustrated in FIG. 26, the level shifter control circuit 10h includes a SR-FF11, NAND circuits 19₁, 19₂, . . . , 19n, and inverters 17₁, 17₂, . . . , 17n.

An output signal Q of the SR-FF11 is inputted to one of input terminals of each of the NAND circuits 19₁, 19₂, . . . , and 19n. Further, the output signals OUT1, OUT2, . . . , OUTn of the level shifters LS1, LS2, . . . , LSn are respectively inputted to the NAND circuits 19₁, 19₂, . . . , and 19n so that the other input terminal of each NAND circuit receives each output signal.

Further, output terminals of the NAND circuits 19₁, 19₂, . . . , and 19n are respectively connected to input terminals of the inverters 17₁, 17₂, 17n.

Further, the control signals ENB1, ENB2, . . . , and ENBn outputted from the output terminals of the inverters 17₁, 17₂, . . . , and 17n are respectively inputted to the level shifters LS1, LS2, . . . , LSn.

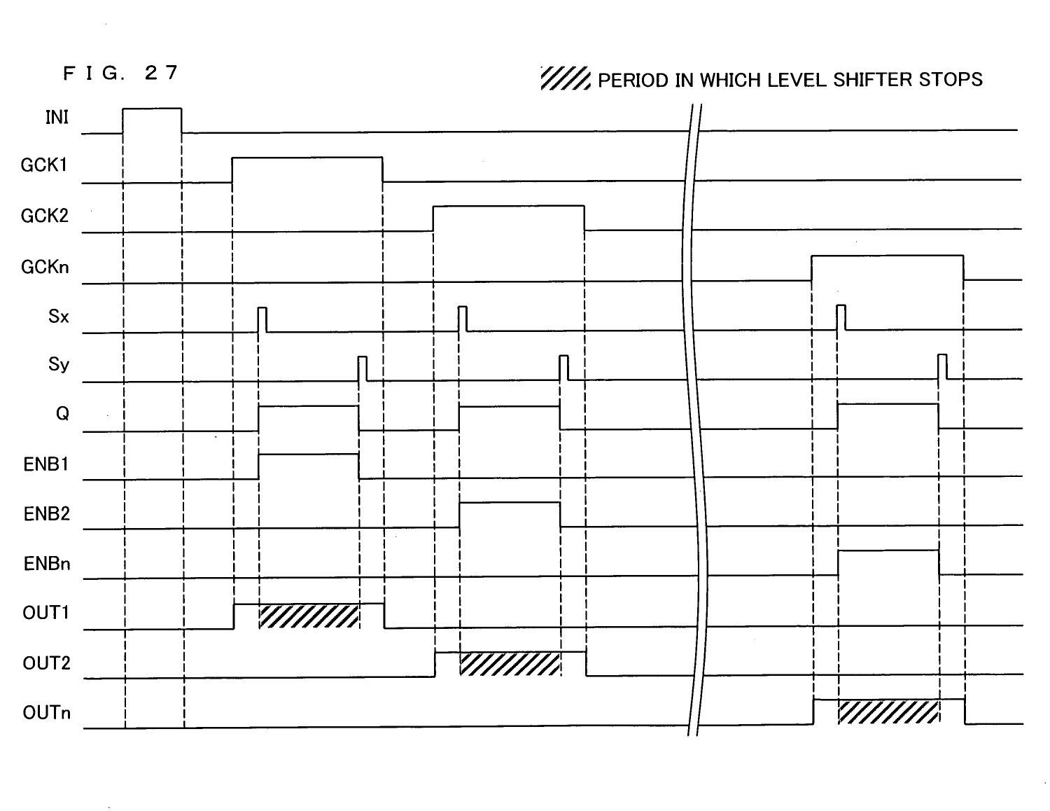

In the level shifter circuit arranged in this manner, as illustrated in the timing chart of FIG. 27, a level shift operation of a level shifter receiving an active clock signal is stopped during a period after a high level of the output signal Sx of the source shift register 20 is inputted to the level shifter control circuit 10h and until a high level of the output signal Sy of the source shift register 20 is inputted to the level shifter control circuit 10h.

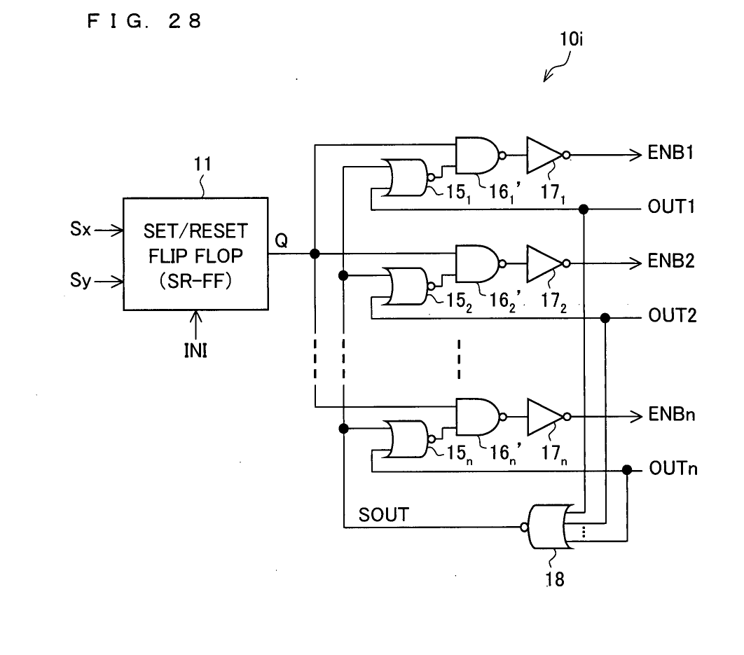

Further, the arrangement of the level shifter control circuit 10f of the level shifter circuit 1c may be changed into an arrangement of a level shifter control circuit 10i illustrated in FIG. 28.

As illustrated in FIG. 28, the level shifter control circuit 10i includes NAND circuits 16₁′, 16₂′, . . . , 16n′ instead of the NAND circuits 16₁, 16₂, . . . , 16n of the level shifter control circuit 10f. That is, the level shifter control circuit 10i includes an SR-FF11, NOR circuits 15₁, 15₂, . . . , 15n, NAND circuits 16₁′, 16₂′, . . . , 16n′, inverters 17₁, 17₂, . . . , 17n, and a NOR circuit 18.

The output signals OUT1, OUT2, . . . , OUTn of the level shifters LS1, LS2, . . . , LSn are respectively inputted to the NOR circuits 15₁, 15₂, . . . , 15n so that one of input terminals of each NOR circuit receives each output signal. As a result, the NOR circuits 15₁, 15₂, . . . , 15n serve as active period detection means for detecting active periods of the level shifters LS1, LS2, . . . , LSn.

Further, the output signals OUT1, OUT2, . . . , OUTn of the level shifters LS1, LS2, . . . , LSn are inputted to an input terminal of the NOR circuit 18. Further, an output signal SOUT of the NOR circuit 18 is inputted to the other input terminal of each of the NOR circuits 15₁, 15₂, . . . , 15n.

An output terminal of each of the NOR circuits 15₁, 15₂, . . . , 15n is connected to one of input terminals of each of the NAND circuits 16₁′, 16₂′, . . . , and 16n′. Further, an output signal Q of the SR-FF11 is inputted to the other input terminal of each of the NAND circuits 16₁′, 16₂′, . . . , and 16n′.

Further, output terminals of the NAND circuits 16₁′, 16₂′, . . . , and 16n′ are respectively connected to the input terminals of the inverters 17₁, 17₂, . . . , 17n. Further, output signals ENB1, ENB2, . . . , ENBn outputted from the output terminals of the inverters 17₁, 17₂, . . . , 17n are respectively inputted to the level shifters LS1, LS2, . . . , LSn.

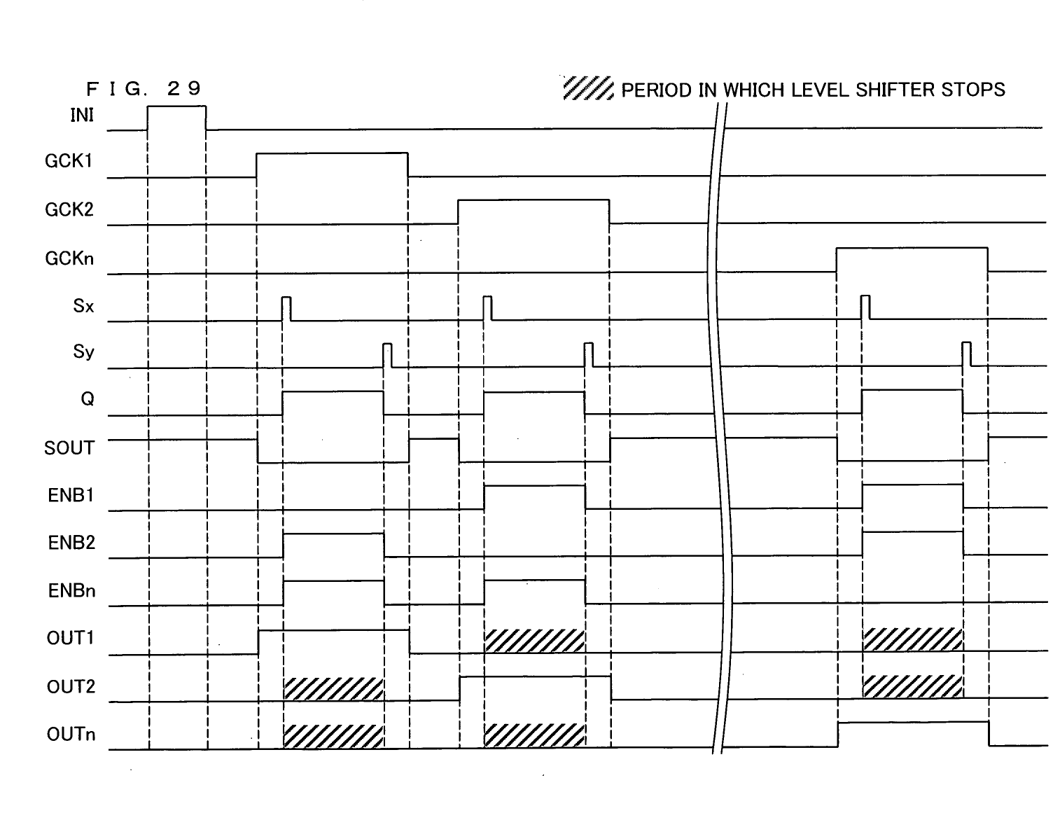

In the level shifter circuit arranged in this manner, as illustrated in the timing chart of FIG. 29, during a period in which one of the level shifters receives an active clock signal and after a high level of the output signal Sx of the source shift register 20 is inputted to the level shifter control circuit 10i and until the output signal Sy of the source shift register 20 is inputted to the level shifter control circuit 10i, level shift operations of other level shifters are stopped.

### Embodiment 4

The following description explains still further another embodiment of the present invention. Note that, unless particularly mentioned, the same reference signs given to the same members and the same signals as in Embodiments 1 to 3 represent members and signs which have the same functions as in Embodiments 1 to 3 and can be modified in the same manner (same arrangement modification), and descriptions thereof are omitted.

Each of the aforementioned embodiments described the arrangement in which the level shift operation of the level shifter circuit is controlled by using the output signals Sx and Sy of the source shift register 20 which allows specific one-way shift operation. However, the present embodiment will describe an arrangement using output signals Sx and Sy of a two-way source shift register which allows a shift direction to be switched forward and backward.

Note that, the present embodiment will describe a case where the two-way source shift register is applied to the arrangement using the level shifter circuit 1 described in Embodiment 1. However, the present invention is not limited to this. The two-way source shift register is applicable to the arrangement using any level shifter circuits described in the aforementioned embodiments.

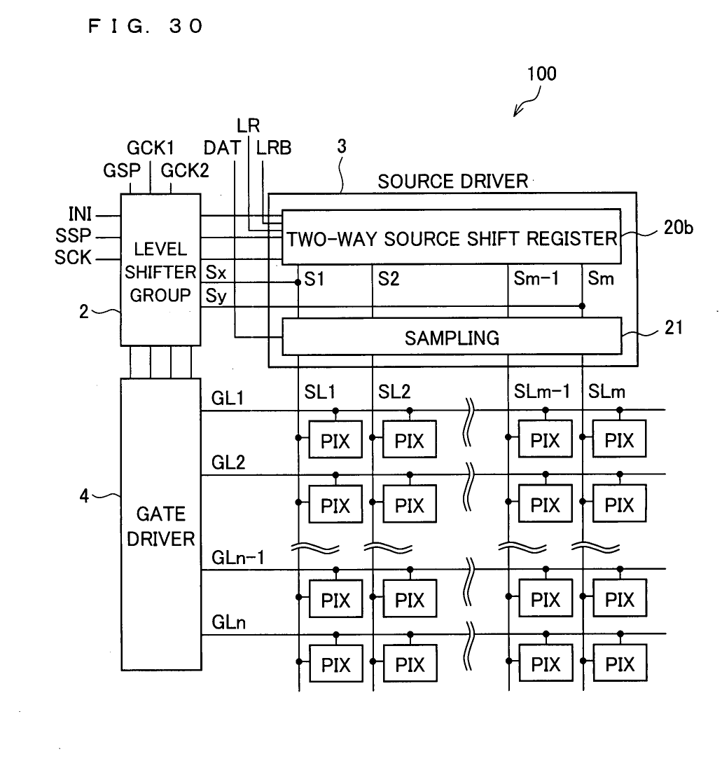

FIG. 30 is a block diagram of a two-way source shift register (source shift resister) 20b provided on the display device 100 as well as the level shifter circuit according to the present embodiment. As illustrated in FIG. 30, the two-way source shift register 20b receives not only the start pulse signal SSP and the clock signal SCK but also shift direction control signals LR and LRB from the control circuit 2. The shift direction control signal LRB is obtained by inverting the shift direction control signal LR.

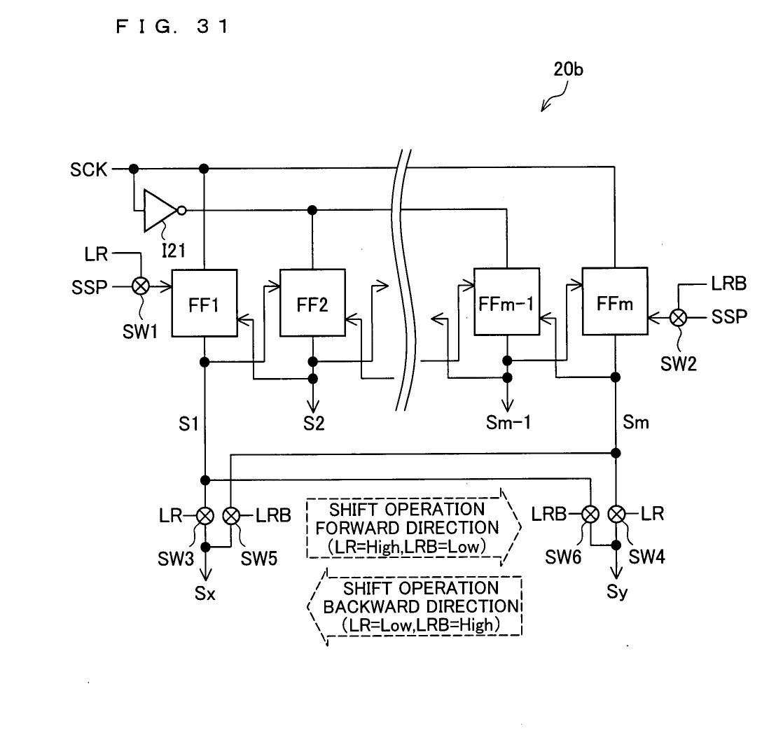

FIG. 31 is a block diagram of the two-way source shift register 20b. As illustrated in FIG. 31, the two-way source shift register 20b includes an inverter I21, plural flip flops FF1, FF2, . . . , FFm-1, FFm, and switches SW1 to SW6.

A standard clock signal SCK is inputted to each of odd-numbered flip flops, and a signal obtained by inverting the standard clock signal SCK by the inverter I21 is inputted to each of even-numbered flip flops.

Further, a start pulse signal SSP is inputted to the first flip flop FF1 via the switch SW1. The switch SW1 receives the shift direction control signal LR. When the shift direction control signal LR is a high level (High), the switch SW1 opens, so that the start pulse signal SSP is inputted to the first flip flop FF1.

Further, when the shift direction control signal LR is a high level, an output signal of a stage previous to the second or further flip flop (each of the flip flops FF2, FF3, . . . , FFm) is inputted to the second or further flip flop.

As a result, the standard clock signal SCK and the start pulse signal SSP cause the source shift register 20 to start a forward direction shift operation, so that output signals S1 to Sm are sequentially outputted from the respective flip flops FF1 to FFm.

While, the last flip flop FFm is connected to an input terminal receiving the start pulse signal SSP via the switch SW2. The switch SW2 receives the shift direction control signal LRB. When the shift direction control signal LRB is a high level (when the shift direction control signal LR is a low level), the switch SW2 opens, so that the start pulse signal SSP is inputted to the last flip flop FFm.

Further, when the shift direction control signal LRB is a high level, an output signal of the flip flop FFm is inputted to the flip flop FFm-1, and then output signals of the flip flops FFm-1, . . . , FF2 are respectively inputted to flip flops which respectively follow to the flip flops FFm-2, . . . , FF1.

As a result, the standard clock signal SCK and the start pulse signal SSP cause the source shift register 20 to start a backward direction shift operation, so that output signals Sm to S1 are sequentially outputted from the respective flip flops FFm to FF1.

Further, an output terminal of the first flip flop FF1 is connected to input terminals of the switches SW3 and SW4. Further, an output terminal of the switch SW3 is connected to an input terminal of the level shifter circuit 1 which input terminal receives the signal Sx, and an output terminal of the switch SW4 is connected to an input terminal of the level shifter circuit 1 which input terminal receives the signal Sy. Further, the switch SW3 receives the shift direction control signal LR, and the switch SW4 receives the shift direction control signal LRB.

Further, an output terminal of the last flip flop FFm is connected to input terminals of the switch SW5 and the switch SW6. Further, an output terminal of the switch SW5 is connected to an input terminal of the level shifter circuit 1 which input terminal receives the signal Sx, and an output terminal of the switch SW6 is connected to an input terminal of the level shifter circuit 1 which input terminal receives the signal Sy. Further, the switch SW5 receives the shift direction control signal LRB, and the switch SW6 receives the shift direction control signal LR.

Further, when the inputted shift direction control signal LR or LRB is a high level, the switches SW3 to SW6 open. When the shift direction control signal LR or LRB is a low level (Low), the switches SW3 to SW6 close.

Thus, when the two-way source shift register 20b carries out a forward direction shift operation (when the shift direction control signal LR is a high level and the shift direction control signal LRB is a low level), the switches SW3 and SW4 open and the switches SW6 and SW5 close. As a result, when the shift direction is a forward direction, an output signal S1 of the first flip flop FF1 is outputted as the output signal Sx to the level shifter circuit 1, and an output signal Sm of the last flip flop FFm is outputted as the output signal Sy to the level shifter circuit 1.

Meanwhile, when the two-way source shift register 20b carries out a backward direction shift operation (when the shift direction control signal LR is a low level and the shift direction control signal LRB is a high level), the switches SW6 and SW5 open and the switches SW3 and SW4 close. As a result, when the shift direction is a backward direction, the output signal Sm of the last flip flop FFm is outputted as the output signal Sx to the level shifter circuit 1, and the output signal S1 of the first flip flop FF1 is outputted as the output signal Sy to the level shifter circuit 1.

As a result, the output signal Sx always becomes a high level at an earlier timing than the output signal Sy. Thus, in the level shifter circuit 1, it is possible to appropriately and stably control the level shift operation.

Note that, the foregoing description explained the case of generating the output signals Sx and Sy to the level shifter circuit 1 by using the output signal S1 of the first flip flop FF1 and the output signal Sm of the last flip flop FFm, but the present invention is not limited to this. Out of the output signals S1 to Sm of the respective flip flops, it is possible to use output signals of any stages. However, it is necessary that the output signal Sx outputted to the level shifter circuit 1 is brought into a high level at an earlier timing than the output signal Sy.

Further, as described above, the output signals Sx and Sy to the level shifter circuit 1 are generated by using the output signal S1 of the first flip flop FF1 and the output signal Sm of the last flip flop FFm, so that an interval between the output signal Sx and the output signal Sy can be made greater. As a result, a period in which the level shift operation of the level shifter circuit 1 can be made longer, so that it is possible to more effectively reduce power consumption of the level shifter circuit 1.

### Embodiment 5

The following description explains still further another embodiment of the present invention. Note that, unless particularly mentioned, the same reference signs given to the same members and the same signals as in Embodiments 1 to 4 represent members and signs which have the same functions as in Embodiments 1 to 4 and can be modified in the same manner (same arrangement modification), and descriptions thereof are omitted.

Each of the aforementioned embodiments described the arrangement in which the level shifter circuit of the present invention is provided on the display device 100 having the source shift register. The present embodiment will describe a case where the level shifter circuit of the present invention is applied to a display device using an SSD (source shared driving) circuit.

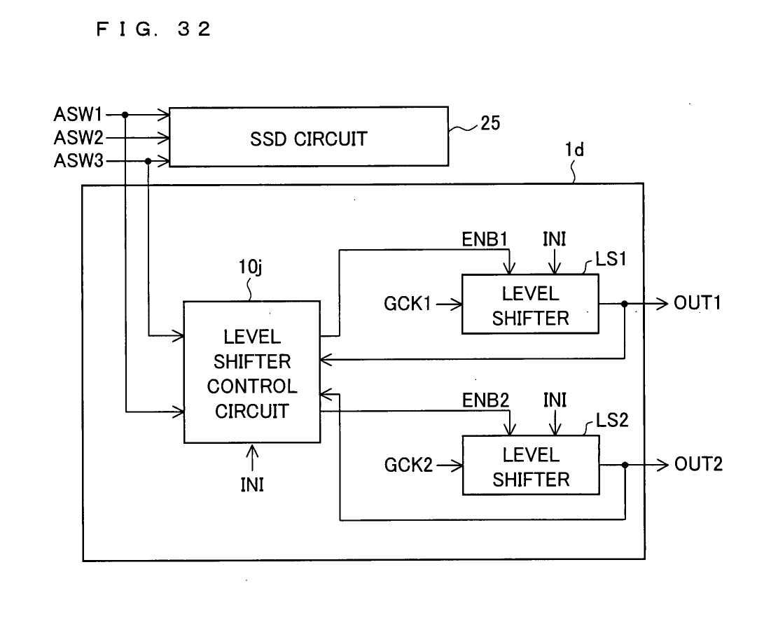

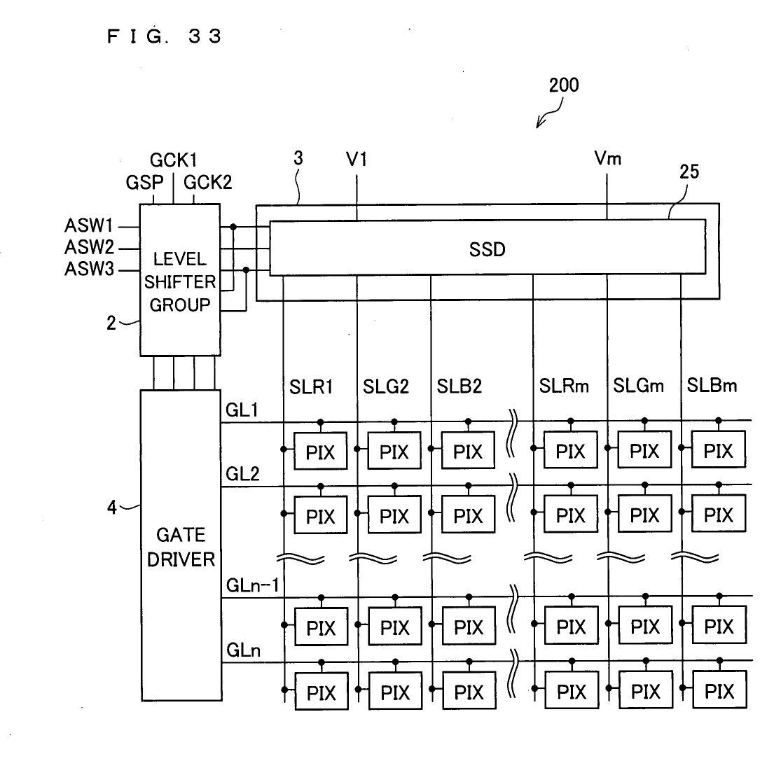

FIG. 32 is a block diagram of a level shifter circuit 1d according to the present embodiment. Further, FIG. 33 is a block diagram illustrating an arrangement of a matrix type liquid crystal display device (display device) 200 having the level shifter circuit 1d.

As illustrated in FIG. 33, the display device 200 includes: a large number of pixels PIX disposed in a matrix manner; a level shifter group 2; and a source driver (data signal line driving circuit) 3 and a gate driver (scanning signal line driving circuit) 4 each of which drives the pixels PIX. Note that, peripheral circuits such as the pixels PIX, the source driver 3, and the gate driver 4 are monolithic circuits formed on the same substrate in a monolithic manner so as to reduce trouble in manufacturing and a wiring capacitance.

The source driver 3 includes an SSD circuit 25. As in the aforementioned embodiments, the level shifter group 2 includes a plurality of level shifters for shifting levels of inputted signals.

The level shifter circuit 1d is provided on the level shifter group 2, and carries out level shift so as to boost high levels of the clock signals GCK1 and GCK2 to predetermined voltages, and outputs the boosted voltages. Note that, the level shifter circuit 1d is provided outside the gate driver 4 (provided in the level shifter group 2), but the present invention is not limited to this. As in the aforementioned embodiments, the level shifter circuit 1d may be provided in the gate driver 4. The level shifter circuit 1d will be detailed later.

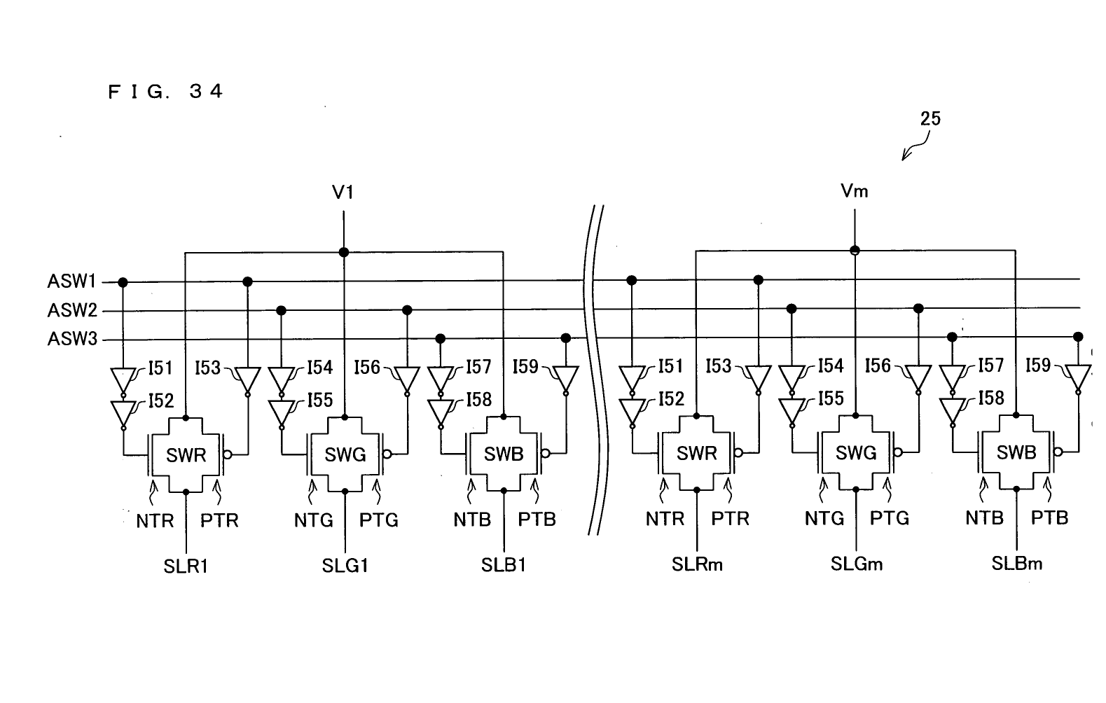

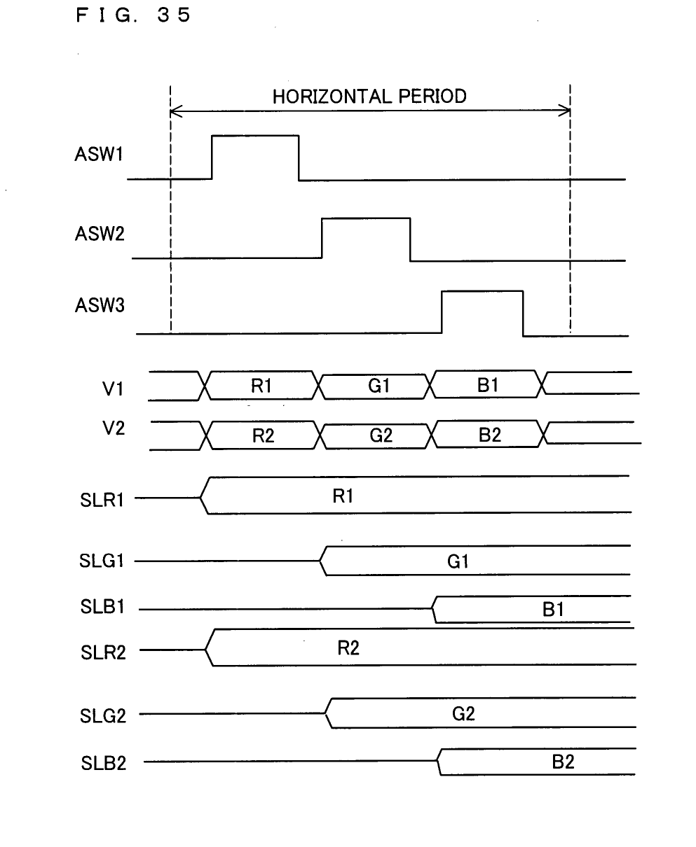

The SSD circuit 25 uses a switch during a horizontal period of image display so as to allocate signals (data signals) from plural video lines (input lines) to source bus lines (data signal lines) whose number is larger than the number of the video lines. The SSD circuit 25 will be described with reference to FIG. 34 and FIG. 35.

FIG. 34 is a block diagram of the SSD circuit 25. As illustrated in FIG. 34, the SSD circuit 25 includes switch groups (SW groups) each of which has switches (switching elements) SWR, SWG, and SWB so that the number (m-number) of the switch groups is equal to the number the video signal lines (video lines) V1 to Vm (m is an integer not less than 1). Further, each switch group receives any one of video signals (data signals) V1 to Vm.

The switch SWR of each switch group includes an N-channel MOS transistor (transistor) NTR and a P-channel MOS transistor (transistor) PTR. Each of sources of the transistor NTR and the transistor PTR receives a video signal (any one of the video signals V1 to Vm) corresponding to the switch group.

Further, a gate of the transistor NTR receives an input signal ASW1 from the outside via inverters I51 and I52. Further, a gate of the transistor PTR receives an input signal ASW1 from the outside via an inverter I53.

Further, drains of the transistor NTR and the transistor PTR are connected to a source bus line (any one of source bus lines SLR1 to SLRm) corresponding to the switch group.

Further, the switch SWG of each switch group includes an N-channel MOS transistor (transistor) NTG and a P-channel transistor (transistor) PTG. Each of sources of the transistor NTG and the transistor PTG receives a video signal (any one of video signals V1 to Vm) corresponding to the switch group.

Further, a gate of the transistor NTG receives an input signal ASW2 from the outside via inverters I54 and 155. Further, a gate of the transistor PTG receives an input signal ASW2 from the outside via an inverter I56.

Further, drains of the transistor NTG and the transistor PTG are connected to a source bus line (any one of source bus lines SLG1 to SLGm) corresponding to the switch group.

Further, the switch SWB of each switch group includes an N-channel MOS transistor (transistor) NTB and a P-channel MOS transistor (transistor) PTB. Each of sources of the transistor NTB and the transistor PTB receives a video signal (any one of video signals V1 to Vm) corresponding to the switch group.

Further, a gate of the transistor NTB receives an input signal ASW3 from the outside via inverters I57 and I58. Further, a gate of the transistor PTB receives an input signal. ASW3 from the outside via an inverter I59.

Further, drains of the transistor NTB and the transistor PTB are connected to a source bus line (any one of source bus lines SLB1 to SLBm) corresponding to the switch group.

As a result, in the SSD circuit 25, the switches SWR, SWG, and SWB are controlled in accordance with the input signals ASW1, ASW2, and ASW3 respectively. The switches SWR, SWG, and SWB are regarded as a single group, and a single video signal corresponds to the single group. The video signal is inputted to all the switches SWR, SWG, and SWB of the group, so that the single video signal is connected to three source bus lines via the switches SWR, SWG, and SWB. In case of FIG. 34, there are m-number of video signal lines V1 to Vm, so that the number of source bus lines is 3×m.

In accordance with the input signals ASW1, ASW2, and ASW3, m-number of switches SWR, m-number of switches SWG, and m-number of switches SWB are opened so as to supply video signals from the video signal lines V1 to Vm to the source bus lines SLR1 to SLRM, SLG1 to SLGm, and SLB1 to SLBM.

With reference to the timing chart of FIG. 35, a specific operation thereof is described as follows. However, when the input signals ASW1, ASW2, and ASW3 are high levels, this is regarded as an active period, e.g., as a state in which each switch opens.

As illustrated in FIG. 35, a horizontal period is divided into three in a time sharing manner, and the periods obtained by the division are assigned to the input signals ASW1, ASW2, and ASW3, respectively. As a result, the m-number of switches SWR, the m-number of switches SWG, and the m-number of switches SWB are sequentially opened, so that video signals are supplied from the m-number of video signals to the 3×m-number of source bus lines. In accordance with the signals ASW1, ASW2, and ASW3, the video signal lines and the source bus lines are sequentially connected. Also the video signal supplied to the video signal line is divided into three signals in a time sharing manner so as to correspond to the active periods of the input signals ASW1, ASW2, and ASW3, thereby supplying desired data corresponding to each source bus line. That is, the video signal is supplied to three source bus lines via a single video signal line in a single horizontal period.

Note that, the present embodiment described the case where the horizontal period is divided into three in a time sharing manner, the same concept is applicable also to a case where the horizontal period is divided into m-number periods (m is an integer not less than 2).

As illustrated in FIG. 32, the level shifter circuit 1d includes a level shifter control circuit 10j and level shifters LS1 and LS2. Further, the level shifter control circuit 10j receives input signals ASW1 and ASW3 supplied to the SSD circuit 25.

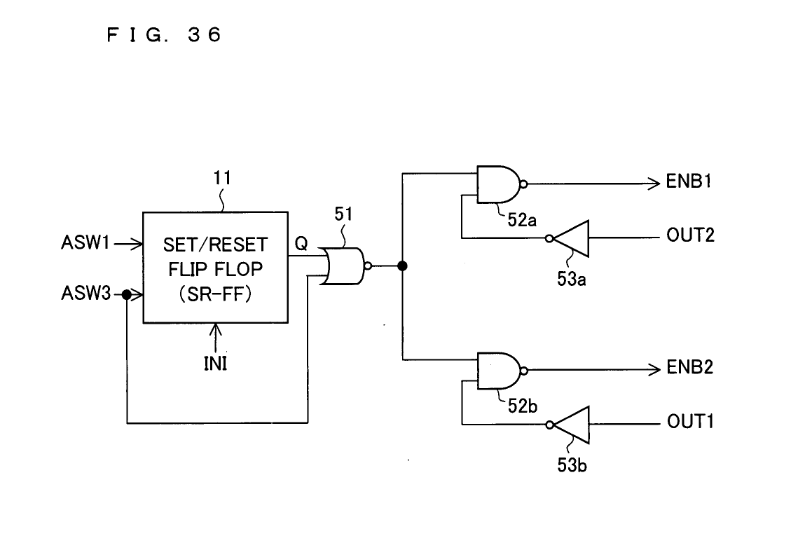

FIG. 36 is a block diagram of the level shifter control circuit 10j. As illustrated in FIG. 36, the level shifter control circuit 10j includes a set-reset flip flop (SR-FF) 11, a NOR circuit 51, NAND circuits 52a and 52b, and inverters 53a and 53b.

A set terminal of the SR-FF11 receives an input signal ASW1, and a reset terminal of the SR-FF11 receives an input signal ASW3. The input signal ASW3 is inputted also to one of input terminals of the NOR circuit 51. Further, an output signal Q of the SR-FF11 is inputted to the other input terminal of the NOR circuit 51.

Further, an output terminal of the NOR circuit 51 is connected to one of input terminals of each of the NAND circuits 52a and 52b. The other input terminal of the NAND circuit 52a receives an output signal OUT2 of the level shifter LS2 via the inverter 53a. Further, the other input terminal of the NAND circuit 52b receives an output signal OUT1 of the level shifter LS1 via the inverter 53b. As a result, the NAND circuit 52a and the inverter 53a serve as an active period detection circuit for detecting an active period of the level shifter LS2, and the NAND circuit 52b and the inverter 53b serve as an active period detection circuit for detecting an active period of the level shifter LS1.

Further, an output signal of the NAND circuit 52a is outputted to the level shifter LS1 as a control signal ENB1 for controlling a level shift operation of the level shifter LS1. Further, an output signal of the NAND circuit 52b is outputted to the level shifter LS2 as a control signal ENB2 for controlling a level shift operation of the level shifter LS2.

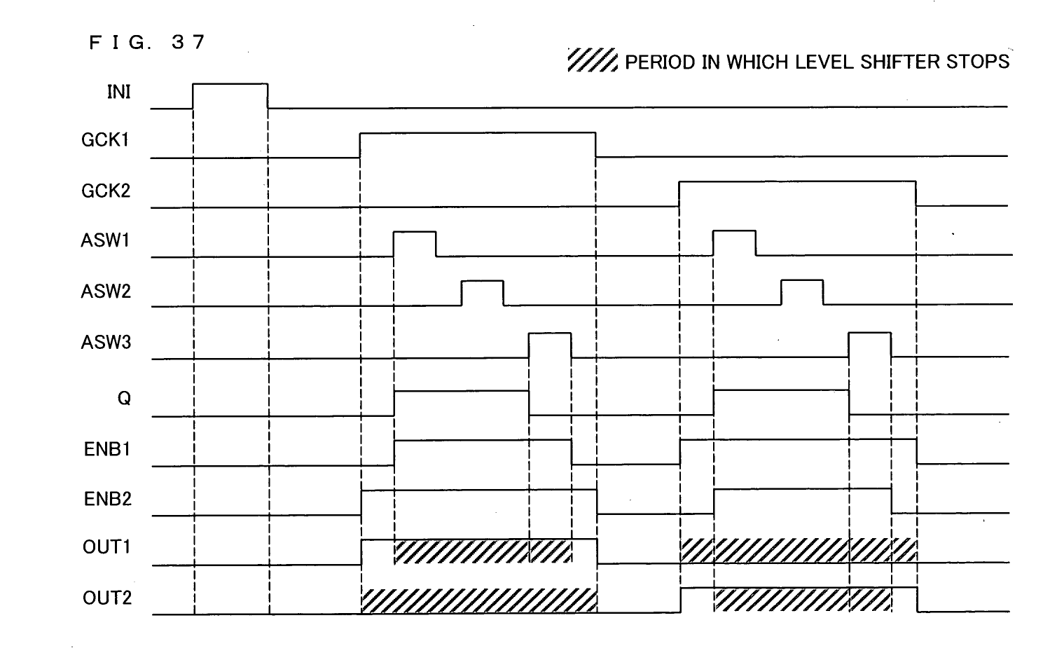

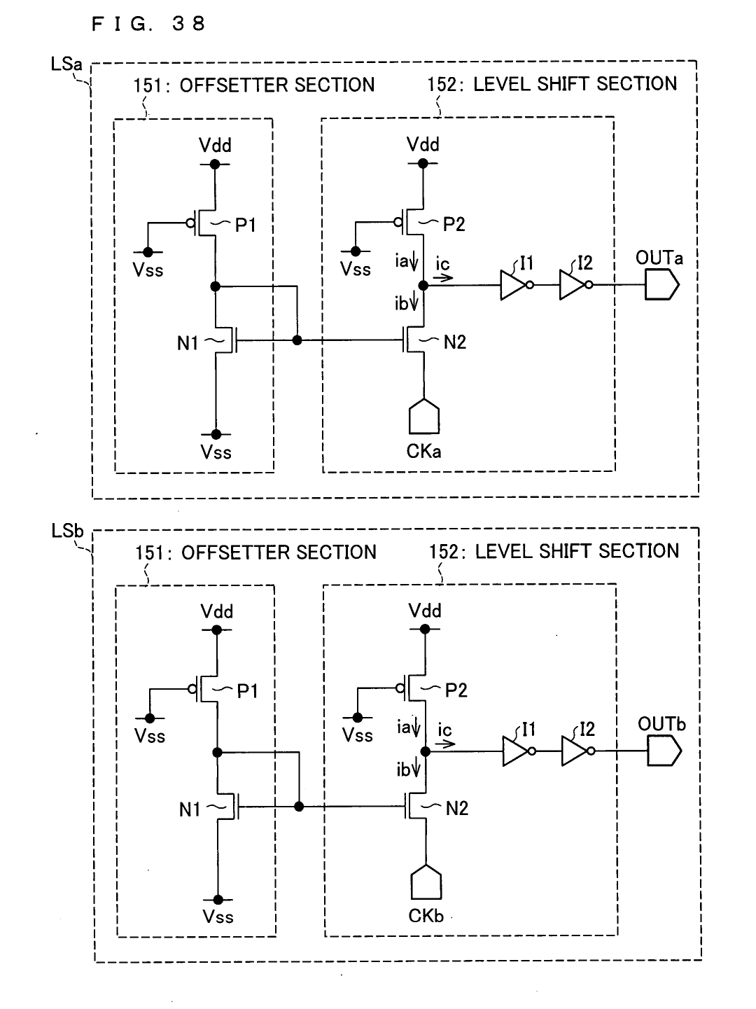

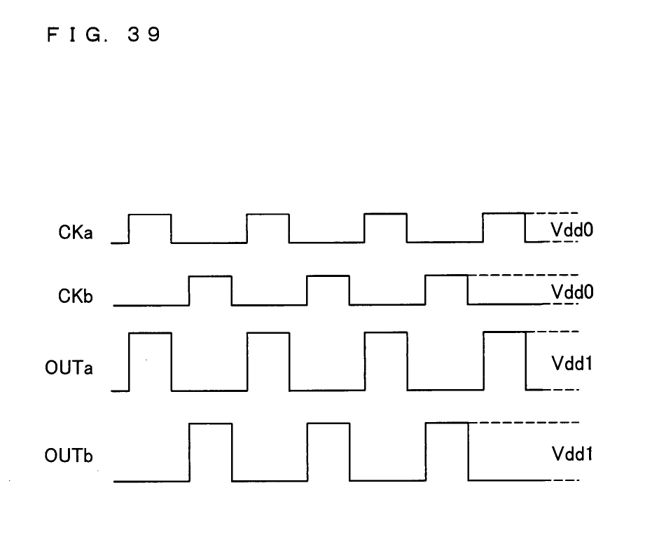

FIG. 37 is a timing chart of the level shifter circuit 1d.

When the output signal OUT1 of the level shifter LS1 is a high level (when the clock signal GCK1 is a high level), a signal inputted to one of input terminals of the NAND circuit 52a via the inverter 53b is a low level. Thus, the control signal ENB2 of the level shifter LS2 which is outputted from the NAND circuit 52b is a high level, so that the level shift operation of the level shifter LS2 is stopped.

Meanwhile, when the output signal OUT2 of the level shifter LS2 is a high level (when the clock signal GCK2 is a high level), a signal inputted to one of input terminals of the NAND circuit 52a via the inverter 53a is a low level. Thus, the control signal ENB1 of the level shifter LS1 which is outputted from the NAND circuit 52a is a high level, so that the level shift operation of the level shifter LS1 is stopped.

Further, when the input signal ASW1 becomes a high level, the output signal Q of the SR-FF11 becomes a high level. Thus, the output signal of the NOR circuit 51 becomes a low level, and the control signals ENB1 and ENB2 respectively outputted from the NAND circuits 52a and 52b become high levels. As a result, the level shift operations of the level shifters LS1 and LS2 are stopped.

Further, when the input signal ASW3 inputted to the SR-FF11 becomes a high level, the output signal Q of the SR-FF11 becomes a low level. However, the input signal ASW3 is inputted also to one of input terminals of the NOR circuit 51, so that the output signal of the NOR circuit 51 remains in a low level, and the control signal ENB1 outputted from the NAND circuit 52a and the control signal ENB2 outputted from the NAND circuit 52b are kept at high levels. Thus, when the input signal ASW3 is a high level, the level shift operations of the level shifters LS1 and LS2 are stopped.

Thereafter, when the input signal ASW3 changes from the high level to a low level, the input signals of both the input terminals are low levels, the output signal outputted from the NOR circuit 51 to the NAND circuits 52a and 52b becomes a high level. Here, in case where one of the level shifters LS1 and LS2 has a high level output signal, a low level signal is inputted to the NAND circuit 52a or 52b for generating a control signal of the other level shifter, so that the other level shifter stops the level shift operation. Further, in case where one of the level shifters LS1 and LS2 has a low level output signal, a high level signal is inputted to the NAND circuit 52a or 52b for generating a control signal of the other level shifter, so that the other level shifter becomes in a level shift operation state.

As described above, in the level shifter circuit 1d according to the present embodiment, the level shifter control circuit 10j stops the level shift operations of the level shifters LS1 and LS2 during a period after the input signal ASW1 to the SSD circuit 25 changes from a low level to a high level and the input signal ASW3 becomes a high level and until the input signal ASW3 further becomes a low level.

As a result, it is possible to reduce power consumption of a channel resistor and a wiring resistor of a MOS transistor which power consumption occupies an extremely large part of entire power consumption and which power consumption is caused by a through current in the offsetter section and the level shift section.

Further, this causes the level shifter circuit 1d to stop the level shift operations of the level shifters LS1 and LS2 during not only a period in which clock signals inputted to the level shifters LS1 and LS2 are low levels (non-active) but also a period in which these clock signals are high levels (active).

Further, in the level shifter circuit 1d, the output signals OUT1 and OUT2 of the level shifters LS1 and LS2 are kept at a state before stoppage of the level shift operations in case of stopping the level shift operations.

As a result, in the level shifter circuit 1, it is possible to greatly reduce power consumption and it is possible to appropriately and stably drive the circuit connected to the stage following to the level shifter LS1.

Further, in the level shifter circuit 1d, during not only a period after the input signal ASW1 supplied to the SSD circuit 25 changes from a low level to a high level and until the input signal ASW3 supplied to the SSD circuit 25 changes from a high level to a low level but also a period in which the output signal OUT1 of one of the level shifters is a high level, the level shift operation of the other level shifter is stopped. As a result, it is possible to further greatly reduce power consumption.

Note that, in the level shifter circuit 1d, the operations of the level shifters LS1 and LS2 are stopped during a period after the input signal ASW1 to the SSD circuit 25 changes from a low level to a high level and until the input signal ASW3 changes from a high level to a low level, but the present invention is not limited to this.

For example, the operations of the level shifters LS1 and LS2 may be stopped during a period after the input signal ASW1 supplied to the SSD circuit 25 changes from a low level to a high level and until the input signal ASW3 changes to a high level. In this case, for example, it may be so arranged that: the input signal ASW1 is inputted to the set terminal of the SR-FF11 and the input signal ASW3 is inputted to the reset terminal of the SR-FF11, and a signal obtained by inverting an output signal of the SR-FF11 with an inverter is inputted to each of the NAND circuits 52a and 52b instead of the output signal of the NOR circuit 51.

Further, instead of the input signal ASW3, the input signal ASW2 may be inputted to the reset terminal of the SR-FF11 and the input terminal of the NOR circuit 51.

Further, in the level shifter circuit 1d, during a period in which the output signal OUT1 of one of the level shifters is a high level, the level shift operation of the other level shifter is stopped, but the arrangement of the level shifter circuit 1d is not limited to this.

For example, the level shift operations of the level shifters LS1 and LS2 may be controlled in accordance with only the input signals ASW1 and ASW3 supplied to the SSD circuit 25. In this case, a signal obtained by inverting the output signal of the NOR circuit 51 of the level shifter control circuit 10j with an inverter is used instead of the control signals ENB1 and ENB2 for controlling the level shift operations of the level shifters LS1 and LS2.

Further, it may be so arranged that: during a period in which an active clock signal of one of the level shifters LS1 and LS2 is inputted and after the input signal ASW1 supplied to the SSD circuit 25 becomes a high level and until the input signal ASW3 supplied to the SSD circuit 25 changes from a high level to a low level, the level shift operation of the other level shifter is stopped.

Further, it may be so arranged that: in a level shifter receiving an active clock signal, during a period after the input signal ASW1 supplied to the SSD circuit 25 becomes a high level and until the input signal ASW3 supplied to the SSD circuit 25 changes from a high level to a low level, the level shift operation of the level shifter is stopped.

Further, the present embodiment described the arrangement in which the level shift operation is controlled by using the input signal of the SSD circuit 25 of the level shifter circuit 1d including two level shifters such as the level shifters LS1 and LS2, but the present invention is not limited to this arrangement. For example, as in each of the aforementioned embodiments, it may be so arranged that a level shifter circuit including a single level shifter or a level shifter circuit including n-number of level shifters control the level shift operation by using the input signal of the SSD circuit 25.

Further, in case of controlling the level shift operation by using the input signal of the SDD circuit 25 in the level shifter circuit including n-number of level shifters, the level shift operations of the level shifters may be controlled in accordance with only the input signals ASW1 and ASW3 supplied to the SSD circuit 25.

Further, it may be so arranged that: during a period in which an active clock signal is inputted to one of the level shifters and after the input signal ASW1 supplied to the SSD circuit 25 becomes a high level and until the input signal ASW3 supplied to the SSD circuit 25 changes from a high level to a low level, the level shift operation of the other level shifter is stopped.

Further, it may be so arranged that: in the level shifter receiving an active clock signal, during a period after the input signal ASW1 of the SSD circuit 25 becomes a high level and until the input signal ASW3 supplied to the SSD circuit 25 changes from a high level to a low level, the level shift operation of the level shifter is stopped.

Further, each of the aforementioned embodiments described the case where the level shifter circuit of the present invention is provided on a liquid crystal display device (liquid crystal image display device). Here, examples of the liquid crystal display device including the level shifter circuit of the present invention are television and a personal computer display each of which uses a household power supply or the like, or are portable devices such as a compact portable terminal, a mobile phone, a digital camera, and a digital video camera, each of which is driven by a dry buttery, a charging battery, or the like. Particularly, in case of applying the level shifter circuit of the present invention to a liquid crystal image display device provided on the portable device which is driven by a dry buttery, a charging buttery, or the like, it is possible to extend usable time of the portable device by reducing the power consumption, so that the present invention is favorably used.

Further, in each of the aforementioned embodiments, the level shifter circuit of the present invention is provided on the level shifter group 2 and serves as a part of the gate driver 4, but the present invention is not limited to this. For example, the level shifter circuit may be provided in the gate driver 4. Further, the level shifter circuit of the present invention can serve also as a part of the source driver 3. In this case, as a signal used to determine a period in which the level shift operation is stopped, a signal whose frequency is equal to or higher than a frequency of the clock signal and which signal allows the stopping period of the level shift operation to be appropriately set during an active period of the clock signal is suitably selected.

Further, each of the aforementioned embodiments described the case where the level shifter circuit of the present invention is applied to a matrix type liquid crystal display device including a monolithic circuit in which the pixels PIX and peripheral circuits are formed on the same substrate, but the present invention is not limited to this. The level shifter circuit of the present invention may be provided on a driving circuit which is not monolithic, or may be provided on a driving circuit of a liquid crystal display device other than the matrix type liquid crystal display device. Further, the level shifter circuit of the present invention is applicable not only to the driving circuit of the liquid crystal display device but also to any other circuit (device) which boosts and outputs a clock signal.

As described above, a level shifter circuit of the present invention includes a level shifter which carries out a level shift operation in which a high level of an inputted clock signal is converted into one of a high level and a low level of a predetermined power source voltage and a low level of the clock signal is converted into the other of the high level and the low level of the power source voltage and which outputs an output signal obtained by carrying out the level shift operation, said level shifter circuit being characterized by comprising: level shifter control means for stopping a level shift operation, during a specific period after carrying out a level shift operation, corresponding to an operation for switching the clock signal from a non-active state to an active state, and until the level shifter carries out a level shift operation, corresponding to an operation for switching the clock signal from the active state to the non-active state; and output control means for allowing a level of the output signal in stopping the level shift operation to be kept at a level before stoppage of the level shift operation. Note that, the active period of the clock signal may be a high level period or may be a low level period.

According to the arrangement, the level shifter control circuit stops a level shift operation, corresponding to an operation for switching the clock signal from a non-active state to an active state, during a specific period after carrying out the level shift operation and until the level shifter carries out a level shift operation, corresponding to an operation for switching the clock signal from the active state to the non-active state. Further, the output control means allows a level of the output signal in stopping the level shift operation to be kept at a level before stoppage of the level shift operation, that is, at a level of an output signal corresponding to the active of the clock signal.

As a result, it is possible to stop the level shift operation during a period in which the output signal of the level shifter is active, so that it is possible to reduce power consumption of the level shifter circuit. Further, the output signal of the level shifter can be kept at a state before stoppage of the level shift operation also during a period in which the level shift operation is stopped, so that it is possible to appropriately and stably drive a circuit connected to the stage following to the level shifter.

Further, the level shifter circuit may be arranged so that the level shifter control means stops the level shift operation during not only the specific period but also a predetermined period in which the clock signal is non-active.

According to the arrangement, the level shifter control means stops the level shift operation during not only the specific period but also a predetermined period in which the clock signal is non-active. As a result, the period in which the level shift operation is stopped can be made longer, so that it is possible to further reduce power consumption.

Also in this case, the output control means allows a level of the output signal in stopping the level shift operation to be kept at a level before stoppage of the level shift operation. That is, in case of stopping the level shift operation in the specific period, i.e., in the active period of the output signal of the clock signal, the output signal of the level shifter is kept at a level corresponding to the active of the clock signal. Further, in case of stopping the level shift operation in the predetermined period, i.e., in the non-active period of the clock signal, the output signal of the level shifter is kept at a level corresponding to the non-active of the clock signal. Thus, it is possible to effectively reduce power consumption and it is possible to appropriately and stably drive a circuit connected to the stage following to the level shifter.

Further, a level shifter circuit of the present invention includes level shifters each of which carries out a level shift operation in which a high level of each of clock signals having either phases whose high level periods do not overlap each other or phases whose low level periods do not overlap each other is converted into one of a high level and a low level of a predetermined power source voltage and a low level of the clock signal is converted into the other of the high level and the low level of the power source voltage and each of which level shifters outputs an output signal obtained by carrying out the level shift operation, said level shifters respectively corresponding to the clock signals, said level shifter circuit comprising: active period detection means for detecting whether the clock signal inputted to each of the level shifters is in an active period or in a non-active period; level shifter control means for controlling a level shifter receiving the clock signal which is in the active period so as to stop a level shift operation, during a specific period after carrying out a level shift operation, corresponding to an operation for switching the clock signal from a non-active state to an active state, and until the level shifter carries out a level shift operation, corresponding to an operation for switching the clock signal from the active state to the non-active state; and output control means for allowing a level of the output signal in stopping the level shift operation to be kept at a level before stoppage of the level shift operation. Note that, the active period of the clock signal may be a high level period or may be a low level period.

According to the arrangement, the level shifter control means controls a level shifter receiving the clock signal which is in the active period so as to stop a level shift operation, during a specific period after carrying out a level shift operation, corresponding to an operation for switching the clock signal from a non-active state to an active state, and until the level shifter carries out a level shift operation, corresponding to an operation for switching the clock signal from the active state to the non-active state. Further, the output control means allows a level of the output signal in stopping the level shift operation to be kept at a level before stoppage of the level shift operation, that is, at a level of an output signal corresponding to the active of the clock signal.

As a result, it is possible to stop the level shift operation during a period in which the output signal of the level shifter is active, so that it is possible to reduce power consumption of the level shifter circuit. Further, the output signal of the level shifter can be kept at a state before stoppage of the level shift operation also during a period in which the level shift operation is stopped, so that it is possible to appropriately and stably drive a circuit connected to the stage following to the level shifter.

Further, the level shifter circuit may be arranged so that the level shifter control means controls another level shifter different from the level shifter receiving the clock signal which is in the active period so as to stop the level shift operation of said another level shifter during the specific period.

According to the arrangement, during not only the specific period of the level shifter receiving the clock signal which is in the active period, the level shifter control means controls another level shifter different from that level shifter during the specific period. As a result, the period in which the level shift operation is stopped can be made longer, so that it is possible to further reduce power consumption.

Also in this case, the output control means allows a level of the output signal in stopping the level shift operation to be kept at a level before stoppage of the level shift operation. That is, in case of stopping the level shift operation of the level shifter receiving the clock signal which is in the active period, the output signal of the level shifter is kept at a level corresponding to the active of the clock signal. Further, the clock signals have either phases whose high level periods do not overlap each other or phases whose low level periods do not overlap each other, so that another level shifter different from the level shifter receiving the clock signal which is in the active period receives a clock signal which is in a non-active period. Thus, an output signal of said another level shifter is kept at a level corresponding to the non-active of the clock signal.

As a result, it is possible to effectively reduce power consumption and it is possible to appropriately and stably drive a circuit connected to the stage following to the level shifter.

Further, the level shifter circuit may be arranged so that: during a period in which one of the level shifters receives the clock signal which is in the active period, the level shift control means stops a level shift operation of other level shifter.

The output signal of the level shifter is kept at a level corresponding to the active of the clock signal.

Further, the clock signals have either phases whose high level periods do not overlap each other or phases whose low level periods do not overlap each other, so that another level shifter different from the level shifter receiving the clock signal which is in the active period receives a clock signal which is in a non-active period. Thus, in case of stopping the level shift operation, an output signal corresponding to the clock signal which is in the non-active period is kept.

According to the arrangement, the level shift operation of the level shifter receiving the clock signal which is in the active period is stopped during the specific period and the level shift operation of said another level shifter is stopped during an active period of the clock signal inputted to the level shifter so that the active period is longer than the specific period. Thus, it is possible to stop the level shift operation for a longer period, so that it is possible to more effectively reduce power consumption.

Further, the level shifter circuit may be arranged so that the level shift control means determines the specific period of the level shifter receiving the clock signal which is in the active period by using an output signal of said other level shifter. According to the arrangement, the level shift control means determines the specific period of the level shifter receiving the clock signal which is in the active period by using an output signal of said other level shifter. Thus, during a period in which the clock signal which is in the active period is inputted to one of the level shifters, it is possible to stop the level shift operation of other level shifter.

Further, the level shifter circuit may be arranged so that a duty of the clock signals in terms of the high level period and the low level period which do not overlap each other is less than (100×1/n) % where the number of kinds of the clock signals is n.

According to the arrangement, high level periods or low level periods of plural clock signals do not overlap each other, so that it is possible to freely set the active period as necessary so as to carry out the level shift operation.

Further, the level shifter circuit may be arranged so that: in stopping the level shift operation, the output control means uses an alternative voltage generated by pulling up or pulling down the output voltage into the power source voltage so that a level of the output signal in stopping the level shift operation is kept at a level before stoppage of the level shift operation.

According to the arrangement, in case of stopping the level shift operation, an output signal generated by using an alternative voltage is outputted instead of the output signal obtained by converting the level of the clock signal due to the level shift operation. As a result, power consumption can be reduced by stopping the level shift operation and the level of the output signal can be kept at a state before stoppage of the level shift operation, so that it is possible to appropriately and stably drive a circuit connected to the stage following to the level shifter.

Further, the level shifter circuit may be arranged so that: the level shifter uses a predetermined voltage generated by flowing a predetermined stationary current to a predetermined circuit of the level shifter so as to carry out the level shift operation, and the level shifter control means prevents the stationary current from flowing to the predetermined circuit so as to stop the level shift operation.

According to the arrangement, the level shift operation is stopped, so that it is possible to reduce power consumption caused by flow of the stationary current.

Further, the level shifter circuit may be arranged so that the level shifter includes, as the predetermined circuit, at least either (i) a boosting section for boosting one of a high level and a low level of the clock signal to a high level of the power source voltage higher than the high level of the clock signal or (ii) a dropping section for dropping the other of the high level and the low level of the clock signal to a low level of the power source voltage lower than the low level of the clock signal, one or both of said boosting section and said dropping section being arranged as a switching MOS transistor including a MOS transistor whose source receives the clock signal and as a current driving type which electrifies the level shifter all the time during the level shift operation.

According to the arrangement, even though the MOS transistor has such an unfavorable property that a threshold value of the MOS transistor is higher than an amplitude of the inputted clock signal, the MOS transistor includes at least either the boosting section or the dropping section which is a current driving type, so that it is possible to level-shift a clock signal whose amplitude is lower than a potential difference between a high level and a low level of the power source voltage only in the active period.

Further, the level shift circuit may be arranged so that the level shifter includes, as the predetermined circuit, at least either (I) a boosting section for boosting one of a high level and a low level of the clock signal to a high level of the power source voltage higher than the high level of the clock signal or (II) a dropping section for dropping the other of the high level and the low level of the clock signal to a low level of the power source voltage lower than the low level of the clock signal, one or both of said boosting section and said dropping section being arranged as a switching MOS transistor including a MOS transistor whose gate receives the clock signal and as a current driving type which electrifies the level shifter all the time during the level shift operation.

According to the arrangement, even though the MOS transistor has such an unfavorable property that a threshold value of the MOS transistor is higher than an amplitude of the inputted clock signal, the MOS transistor includes at least either the boosting section or the dropping section which is a current driving type, so that it is possible to level-shift a clock signal whose amplitude is lower than a potential difference between a high level and a low level of the power source voltage only in the active period.

Further, the input signal is inputted to the gate of the MOS transistor, so that it is possible to prevent an unnecessary current from flowing from or into a terminal section receiving the input signal.

Further, the level shifter circuit may be arranged so that the level shift control means determines the specific period by using a signal whose frequency is equal to or higher than a frequency of the clock signal.

According to the arrangement, the specific period can be appropriately set in a period after carrying out a level shift operation corresponding to an operation for switching the clock signal from a non-active state to an active state and until a level shift operation corresponding to an operation for switching the clock signal from the active state to the non-active state is carried out.

Further, in this case, the level shifter circuit may be arranged so that the level shift control means determines the specific period by using two kinds of signals whose signal levels vary in a specific order.

A driving circuit of the present invention is provided on a display device having a plurality of scanning signal lines, a plurality of data signal lines, and a plurality of pixels, said driving circuit serving as a scanning signal line driving circuit for outputting a scanning signal to each of the scanning signal lines in synchronization with a first clock signal having a predetermined cycle or serving as a data signal line driving circuit for extracting, from a video signal indicative of a display state of each pixel which is inputted in synchronization with a second clock signal having a predetermined cycle, a data signal applied to each pixel connected to the scanning signal line receiving the scanning signal, so as to output the data signal to each of the data signal lines, said driving circuit comprising any one of the aforementioned the level shifter circuits, wherein the level shifter circuit level-shifts the first clock signal or the second clock signal.

According to the arrangement, it is possible to reduce power consumption of the level shift circuit for level-shifting the first clock signal or the second clock signal, so that it is possible to reduce power consumption of the driving circuit.

Further, the driving circuit of the present invention may be arranged so that serves as the scanning signal line driving circuit for outputting the scanning signal to each of the scanning signal lines, wherein the level shifter control circuit determines the specific period in accordance with an output signal from the data signal line driving circuit.

According to the arrangement, in the scanning signal line driving circuit which includes any one of the aforementioned the level shifter circuits and outputs a scanning signal to each of the scanning signal lines in synchronization with a first clock signal having a predetermined cycle, the level shifter control circuit determines the specific period in accordance with an output signal from the data signal line driving circuit. As a result, it is possible to appropriately set a period in which the level shift operation of the level shifter circuit is stopped, so that it is possible to reduce power consumption of the level shifter circuit and the driving circuit.

Further, the driving circuit may be arranged so that the level shifter control circuit determines the specific period in accordance with (a) an output signal for selecting a first data signal line and (b) an output signal for selecting a last data signal line, said output signals being obtained from output signals of selection means which is provided on the data signal line driving circuit and sequentially selects each data signal line from the data signal lines so as to output the extracted data signal via the selected data signal line.

According to the arrangement, the period in which the level shift operation of the level shifter circuit is stopped can be made long. Thus, it is possible to more effectively reduce power consumption of the level shifter circuit and the driving circuit.

Further, the driving circuit may be arranged so that the level shifter circuit determines the specific period in accordance with (A) an output signal for selecting a first data signal line and (B) an output signal for selecting a last data signal line, said output signal being obtained from output signals of two-way selection means which is provided on the data signal line driving circuit and sequentially selects each data signal line from the data signal lines so as to output the extracted data signal via the selected data signal line, said two-way selection means switching the sequential selection between two directions.

According to the arrangement, also in case of the two-way selection means for switching the data signal line selection of the selection means between two directions, it is possible to appropriately set the period in which the level shift operation of the level shifter circuit is stopped, so that it is possible to effectively reduce power consumption of the level shifter circuit and the driving circuit.

Further, the driving circuit may be arranged so that the level shifter circuit determines the specific period in accordance with (1) an output signal outputted to a first data signal line to which each data signal is allocated and (2) an output signal outputted to a last data signal line to which each data is allocated, said output signals being obtained from output signals of allocation means which is provided on the data signal line driving circuit and sequentially allocates plural data signals to the data signal lines whose number is larger than the number of input lines of the data signals.

According to the arrangement, the period in which the level shift operation of the level shifter circuit can be made longer. Thus, it is possible to more effectively reduce power consumption of the level shifter circuit and the driving circuit.

A display device of the present invention includes any one of the aforementioned driving circuits. As a result, it is possible to realize a display device which less consumes power.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

### INDUSTRIAL APPLICABILITY

The present invention is applicable to a level shifter circuit for boosting a voltage of a clock signal. Further, the level shifter circuit of the present invention can reduce power consumption, so that the level shifter circuit can be favorably applied to a driving circuit of a display device, particularly to a driving circuit of a display device provided on a portable device such as a compact portable terminal, a mobile phone, and the like.

1. A level shifter circuit, including a level shifter which carries out a level shift operation in which a high level of an inputted clock signal is converted into one of a high level and a low level of a predetermined power source voltage and a low level of the clock signal is converted into the other of the high level and the low level of the power source voltage and which outputs an output signal obtained by carrying out the level shift operation,
said level shifter circuit being characterized by comprising:
level shifter control means for stopping a level shift operation, during a specific period after carrying out a level shift operation, corresponding to an operation for switching the clock signal from a non-active state to an active state, and until the level shifter carries out a level shift operation, corresponding to an operation for switching the clock signal from the active state to the non-active state; and
output control means for allowing a level of the output signal in stopping the level shift operation to be kept at a level before stoppage of the level shift operation.

2. The level shifter circuit as set forth in claim 1, wherein the level shifter control means stops the level shift operation during not only the specific period but also a predetermined period in which the clock signal is non-active.

3. A level shifter circuit, including level shifters each of which carries out a level shift operation in which a high level of each of clock signals having either phases whose high level periods do not overlap each other or phases whose low level periods do not overlap each other is converted into one of a high level and a low level of a predetermined power source voltage and a low level of the clock signal is converted into the other of the high level and the low level of the power source voltage and each of which level shifters outputs an output signal obtained by carrying out the level shift operation, said level shifters respectively corresponding to the clock signals,
said level shifter circuit comprising:
active period detection means for detecting whether the clock signal inputted to each of the level shifters is in an active period or in a non-active period;
level shifter control means for controlling a level shifter receiving the clock signal which is in the active period so as to stop a level shift operation, during a specific period after carrying out a level shift operation, corresponding to an operation for switching the clock signal from a non-active state to an active state, and until the level shifter carries out a level shift operation, corresponding to an operation for switching the clock signal from the active state to the non-active state; and
output control means for allowing a level of the output signal in stopping the level shift operation to be kept at a level before stoppage of the level shift operation.

4. The level shifter circuit as set forth in claim 3, wherein
the level shifter control means controls another level shifter different from the level shifter receiving the clock signal which is in the active period so as to stop the level shift operation of said another level shifter during the specific period.

5. The level shifter circuit as set forth in claim 3, wherein:
during a period in which one of the level shifters receives the clock signal which is in the active period, the level shift control means stops a level shift operation of other level shifter.

6. The level shifter circuit as set forth in claim 5, wherein
the level shift control means determines the specific period of the level shifter receiving the clock signal which is in the active period by using an output signal of said other level shifter.

7. The level shifter circuit as set forth in claim 3, wherein
a duty of the clock signals in terms of the high level period and the low level period which do not overlap each other is less than (100×1/n) % where the number of kinds of the clock signals is n.

8. The level shifter circuit as set forth in claim 1, wherein:
in stopping the level shift operation, the output control means uses an alternative voltage generated by pulling up or pulling down the output voltage into the power source voltage so that a level of the output signal in stopping the level shift operation is kept at a level before stoppage of the level shift operation.

9. The level shifter circuit as set forth in claim 1, wherein:
the level shifter uses a predetermined voltage generated by flowing a predetermined stationary current to a predetermined circuit of the level shifter so as to carry out the level shift operation, and
the level shifter control means prevents the stationary current from flowing to the predetermined circuit so as to stop the level shift operation.

10. The level shifter circuit as set forth in claim 9, wherein
the level shifter includes, as the predetermined circuit, at least one of (i) a boosting section for boosting one of a high level and a low level of the clock signal to a high level of the power source voltage higher than the high level of the clock signal and (ii) a dropping section for dropping the other of the high level and the low level of the clock signal to a low level of the power source voltage lower than the low level of the clock signal,
one or both of said boosting section and said dropping section being arranged as a switching MOS transistor including a MOS transistor whose source receives the clock signal and as a current driving type which electrifies the level shifter all the time during the level shift operation.

11. The level shifter circuit as set forth in claim 9, wherein
the level shifter includes, as the predetermined circuit, at least one of (I) a boosting section for boosting one of a high level and a low level of the clock signal to a high level of the power source voltage higher than the high level of the clock signal and (II) a dropping section for dropping the other of the high level and the low level of the clock signal to a low level of the power source voltage lower than the low level of the clock signal,
one or both of said boosting section and said dropping section being arranged as a switching MOS transistor including a MOS transistor whose gate receives the clock signal and as a current driving type which electrifies the level shifter all the time during the level shift operation.

12. The level shifter circuit as set forth in claim 1, wherein
the level shift control means determines the specific period by using a signal whose frequency is equal to or higher than a frequency of the clock signal.

13. The level shifter circuit as set forth in claim 12, wherein
the level shift control means determines the specific period by using two kinds of signals whose signal levels vary in a specific order.

14. A driving circuit, being provided on a display device having a plurality of scanning signal lines, a plurality of data signal lines, and a plurality of pixels, said driving circuit serving as a scanning signal line driving circuit for outputting a scanning signal to each of the scanning signal lines in synchronization with a first clock signal having a predetermined cycle or serving as a data signal line driving circuit for extracting, from a video signal indicative of a display state of each pixel which is inputted in synchronization with a second clock signal having a predetermined cycle, a data signal applied to each pixel connected to the scanning signal line receiving the scanning signal, so as to output the data signal to each of the data signal lines,
said driving circuit comprising the level shifter circuit as set forth in claim 1, wherein
the level shifter circuit level-shifts the first clock signal or the second clock signal.

15. The driving circuit as set forth in claim 14, serving as the scanning signal line driving circuit for outputting the scanning signal to each of the scanning signal lines, wherein
the level shifter control circuit determines the specific period in accordance with an output signal from the data signal line driving circuit.

16. The driving circuit as set forth in claim 15, wherein
the level shifter control circuit determines the specific period in accordance with (a) an output signal for selecting a first data signal line and (b) an output signal for selecting a last data signal line,
said output signals being obtained from output signals of selection means which is provided on the data signal line driving circuit and sequentially selects each data signal line from the data signal lines so as to output the extracted data signal via the selected data signal line.

17. The driving circuit as set forth in claim 16, wherein
the level shifter circuit determines the specific period in accordance with (A) an output signal for selecting a first data signal line and (B) an output signal for selecting a last data signal line,
said output signal being obtained from output signals of two-way selection means which is provided on the data signal line driving circuit and sequentially selects each data signal line from the data signal lines so as to output the extracted data signal via the selected data signal line, said two-way selection means switching the sequential selection between two directions.

18. The driving circuit as set forth in claim 15, wherein
the level shifter circuit determines the specific period in accordance with (1) an output signal outputted to a first data signal line to which each data signal is allocated and (2) an output signal outputted to a last data signal line to which each data is allocated,
said output signals being obtained from output signals of allocation means which is provided on the data signal line driving circuit and sequentially allocates plural data signals to the data signal lines whose number is larger than the number of input lines of the data signals.

19. A display device, comprising the driving circuit as set forth in claim 14.

20. The level shifter circuit as set forth in claim 1, wherein:
in stopping the level shift operation, the output control means uses an alternative voltage generated by pulling up or pulling down the output voltage into the power source voltage so that a level of the output signal in stopping the level shift operation is kept at a level before stoppage of the level shift operation.

21. The level shifter circuit as set forth in claim 3, wherein:
the level shifter uses a predetermined voltage generated by flowing a predetermined stationary current to a predetermined circuit of the level shifter so as to carry out the level shift operation, and
the level shifter control means prevents the stationary current from flowing to the predetermined circuit so as to stop the level shift operation.

22. The level shifter circuit as set forth in claim 21, wherein
the level shifter includes, as the predetermined circuit, at least one of (i) a boosting section for boosting one of a high level and a low level of the clock signal to a high level of the power source voltage higher than the high level of the clock signal and (ii) a dropping section for dropping the other of the high level and the low level of the clock signal to a low level of the power source voltage lower than the low level of the clock signal,
one or both of said boosting section and said dropping section being arranged as a switching MOS transistor including a MOS transistor whose source receives the clock signal and as a current driving type which electrifies the level shifter all the time during the level shift operation.

23. The level shifter circuit as set forth in claim 21, wherein
the level shifter includes, as the predetermined circuit, at least one of (I) a boosting section for boosting one of a high level and a low level of the clock signal to a high level of the power source voltage higher than the high level of the clock signal and (II) a dropping section for dropping the other of the high level and the low level of the clock signal to a low level of the power source voltage lower than the low level of the clock signal,

24. The level shifter circuit as set forth in claim 3, wherein
the level shift control means determines the specific period by using a signal whose frequency is equal to or higher than a frequency of the clock signal.

25. The level shifter circuit as set forth in claim 24, wherein
the level shift control means determines the specific period by using two kinds of signals whose signal levels vary in a specific order.

26. A driving circuit, being provided on a display device having a plurality of scanning signal lines, a plurality of data signal lines, and a plurality of pixels, said driving circuit serving as a scanning signal line driving circuit for outputting a scanning signal to each of the scanning signal lines in synchronization with a first clock signal having a predetermined cycle or serving as a data signal line driving circuit for extracting, from a video signal indicative of a display state of each pixel which is inputted in synchronization with a second clock signal having a predetermined cycle, a data signal applied to each pixel connected to the scanning signal line receiving the scanning signal, so as to output the data signal to each of the data signal lines,
said driving circuit comprising the level shifter circuit as set forth in claim 3, wherein
the level shifter circuit level-shifts the first clock signal or the second clock signal.

27. The driving circuit as set forth in claim 26, serving as the scanning signal line driving circuit for outputting the scanning signal to each of the scanning signal lines, wherein
the level shifter control circuit determines the specific period in accordance with an output signal from the data signal line driving circuit.

28. The driving circuit as set forth in claim 27, wherein
the level shifter control circuit determines the specific period in accordance with (a) an output signal for selecting a first data signal line and (b) an output signal for selecting a last data signal line,
said output signals being obtained from output signals of selection means which is provided on the data signal line driving circuit and sequentially selects each data signal line from the data signal lines so as to output the extracted data signal via the selected data signal line.

29. The driving circuit as set forth in claim 28, wherein
the level shifter control circuit determines the specific period in accordance with (a) an output signal for selecting a first data signal line and (b) an output signal for selecting a last data signal line,
said output signals being obtained from output signals of selection means which is provided on the data signal line driving circuit and sequentially selects each data signal line from the data signal lines so as to output the extracted data signal via the selected data signal line.

30. The driving circuit as set forth in claim 29, wherein
the level shifter circuit determines the specific period in accordance with (A) an output signal for selecting a first data signal line and (B) an output signal for selecting a last data signal line,
said output signal being obtained from output signals of two-way selection means which is provided on the data signal line driving circuit and sequentially selects each data signal line from the data signal lines so as to output the extracted data signal via the selected data signal line, said two-way selection means switching the sequential selection between two directions.

31. The driving circuit as set forth in claim 30, wherein
the level shifter circuit determines the specific period in accordance with (A) an output signal for selecting a first data signal line and (B) an output signal for selecting a last data signal line,
said output signal being obtained from output signals of two-way selection means which is provided on the data signal line driving circuit and sequentially selects each data signal line from the data signal lines so as to output the extracted data signal via the selected data signal line, said two-way selection means switching the sequential selection between two directions.

32. The driving circuit as set forth in claim 27, wherein
the level shifter circuit determines the specific period in accordance with (1) an output signal outputted to a first data signal line to which each data signal is allocated and (2) an output signal outputted to a last data signal line to which each data is allocated,
said output signals being obtained from output signals of allocation means which is provided on the data signal line driving circuit and sequentially allocates plural data signals to the data signal lines whose number is larger than the number of input lines of the data signals.

33. A display device, comprising the driving circuit as set forth in claim 26.
